(19) United States
(12) Patent Application Publication
(10) Pub. No.: US 2026/0042957 A1
(43) Pub. Date: Feb. 12, 2026

(54) BORON-NITROGEN COMPOUND, ELECTROLUMINESCENT DEVICE AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Yaxun WU, Wuhan (CN); Changmei ZHENG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 19/026,209

(22) Filed: Jan. 16, 2025

Related U.S. Application Data
(63) Continuation of application No. PCT/CN2024/113196, filed on Aug. 19, 2024.

(30) Foreign Application Priority Data
Mar. 28, 2024 (CN) 202410370410.9

(51) Int. Cl. C09K 11/06; H10K 50/11; H10K 59/10; H10K 85/60

(52) U.S. Cl. CPC C09K 11/06; H10K 50/11; H10K 59/10; H10K 85/658; C09K 2211/1022

(57) ABSTRACT

The embodiments of the present application disclose a boron-nitrogen compound, an electroluminescent device, and a display device. The boron-nitrogen compound has a structural general formula represented by formula (I):

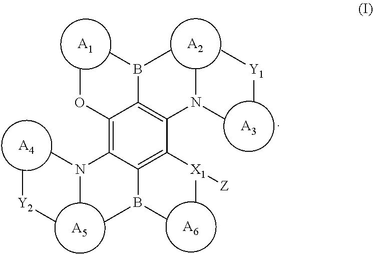

### CROSS REFERENCE TO RELATED APPLICATION

This application is a continuation of International Application No. PCT/CN2024/113196, filed on Aug. 19, 2024, which claims a priority of Chinese patent application No. 202410370410.9, filed on Mar. 28, 2024, and entitled with “BORON-NITROGEN COMPOUND, ELECTROLUMINESCENT DEVICE AND DISPLAY DEVICE”. The entire disclosures of the above application are incorporated herein by reference.

### TECHNICAL FIELD

The present application relates to the technical field of organic optoelectronic materials, and in particular to a boron-nitrogen compound, an electroluminescent device, and a display device.

### BACKGROUND

The luminescent material of a light-emitting layer of an organic light-emitting diode (OLED) device may be classified into a fluorescent and phosphorescent material based on the spin multiple states of the luminescent energy level. According to the laws of quantum statistics, the ratio of singlet excited excitons to triplet excited excitons generated in an electric field is 1:3. The traditional fluorescent material is affected by spin barrier, and an exciton utilization rate thereof is only up to 25%. In contrast, a phosphorescent material and a thermally activated delayed fluorescence (TADF) material may achieve a theoretical maximum exciton utilization rate of 100% due to the spin flip processes of intersystem crossing (ISC) and reverse intersystem crossing (RISC), see C Adachi, et. al., Nature, Vol 492, 234, (2012).

However, in a practical application, the singlet and triplet excitons are affected by various exciton quenching mechanisms, resulting in energy transfer and exciton dissipation that are unfavorable for a radiative transition. This may result in an adverse effect on the device performance of an OLED device, such as a device degradation, a short lifetime, a large roll off at high brightness, and a limited device current efficiency. The use of the phosphorescent or TADF material to sensitize the narrow emission fluorescent or phosphorescent material in the OLED device can improve the efficiency of spectral energy transfer between materials and potentially enhance the performance of OLED device. In order to develop the OLED device with narrow emission and high efficiency, it is necessary to select a material with suitable spectral and energy level characteristics for constructing the sensitization system of the light-emitting layer. The multi resonant fluorescent material containing boron (B) and nitrogen (N) atoms have attracted much attention due to a small stokes shift, a narrow spectrum, and a high luminescence efficiency caused by their rigid luminescent core. And, the boron-nitrogen material that emits light in the blue-green wavelength range have undergone a long period of development, while the development of red light material is slightly lagging behind. Especially the red light material is limited by the bandgap rule and is more prone to produce non-radiative transition after excitation, resulting in a certain gap compared to the blue-green boron-nitrogen material in their luminescence efficiency and lifetime.

### SUMMARY

The existing technology has a technical problem that the lifetime and luminescence efficiency of the red OLED device still need to be improved. Firstly, the embodiments of the present application provide a boron-nitrogen compound, the boron-nitrogen compound has structural general formula represented by formula (I):

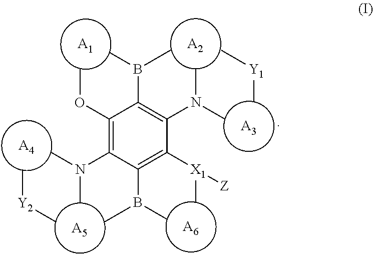

In which, X₁ is selected from O or N:

When X₁ is selected from O, Z is selected from non-bonding, and one of Y₁ and Y₂ is selected from —O—, —S—, —Se—, —Te—, —C—C—, —C═C—,

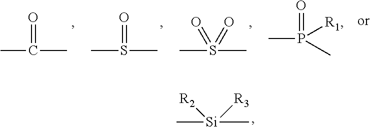

the other is selected from non-bonding, a single bond, —O—, —S—, —Se—, —Te—, —C—C—, —C═C—,

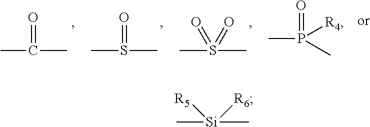

when X₁ is selected from N, Z is selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50, one of Y₁ and Y₂ is selected from —O—, —S—, —Se—, —Te—, —C—C—, —C═C—,

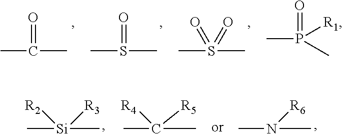

the other is selected from non-bonding, a single bond, —O—, —S—, —Se—, —Te—, —C—C—, —C═C—,

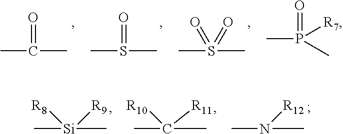

Z and A₆ form a ring or do not form a ring;

R₁ to R₁₂ are each independently selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50:

A₁ to A₆ are each independently selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50.

Secondly, the embodiments of the present application also provide an electroluminescent device including an anode and a cathode, and a light-emitting layer located between the anode and the cathode, in which the light-emitting layer comprises the boron-nitrogen compound mentioned above.

Thirdly, the embodiments of the present application also provide a display device including the aforementioned electroluminescent device.

### DESCRIPTION OF THE DRAWINGS

In order to provide a clearer explanation of the technical solutions in the embodiments or the existing art, a brief introduction will be given below to the accompanying drawings required for the description of the embodiments or the existing art. It is obvious that the accompanying drawings described below are only some of the embodiments of the present application. For one ordinary skilled in the art, other drawings can be obtained based on these drawings without creative labour.

FIG. 1 is a schematic diagram of the film stacking structure of the electroluminescent device provided in the embodiments of the present application.

### DESCRIPTION OF THE EMBODIMENTS

The present application provides a boron-nitrogen compound, an electroluminescent device, and a display device. In order to make the purpose, technical solution, and effect of the present application clearer and more specific, the following is a further detailed explanation of the present application. It should be understood that the specific embodiments described herein are only used to explain the present application and are not intended to limit the present application.

Unless otherwise defined, all technical and scientific terms used herein have the same meanings as those commonly understood by those skilled in the art who the present application pertains to. The terms used in the specification of the present application are only for the purpose of describing specific embodiments and are not intended to limit the scope of the present application. In the present application, “substitution” means that the hydrogen atom in the substituted group is replaced by the substituent: The term “non-bonding” in a certain functional group or structural unit means the absence of the functional group or structural unit.

In the present application, “unsubstituted or substituted” means that the hydrogen atom on the defined group may be substituted or may not be substituted. When the defined functional group is substituted, it should be understood as being substituted by deuterium, tritium, halogen, alkyl having a carbon atom number ranging from 1 to 50, or alkoxy having a carbon atom number ranging from 1 to 50.

The aromatic group refers to a hydrocarbonyl group that contains at least one aromatic ring. The heterocyclic group refers to a cyclic hydrocarbonyl group formed by replacing at least one carbon atom in the carbon ring with a heteroatom. The heterocyclic group mentioned in the embodiments of the present application may be either a fatty heterocyclic group or a heteroaromatic group. The heterocyclic group in the molecular skeleton that cannot reflect aromaticity is a fatty heterocyclic group, while the heterocyclic group with similar properties to benzene are a heteroaromatic group. The heteroaromatic group refers to an aromatic hydrocarbonyl group containing at least one heteroatom. The heteroatom is preferably selected from Si, N, P, O, S, and/or Ge, particularly preferably selected from Si, N, P, O, and/or S.

The hetero spiro-cyclic compound provided in the embodiments of the present application has a structural general formula represented by formula (I):

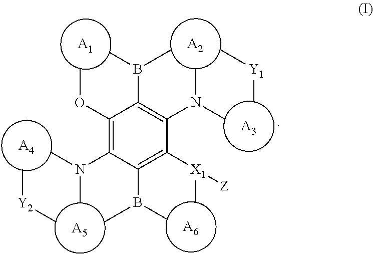

In which, X₁ is selected from O or N.

When X₁ is selected from O, Z is selected from non-bonding, and one of Y₁ and Y₂ is selected from —Se—, —Te—, —C—C—, —C═C—,

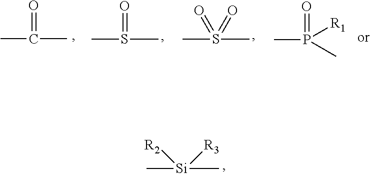

the other is selected from non-bonding, a single bond, —O—, —S—, —Se—, —Te—, —C—C—, —C═C—,

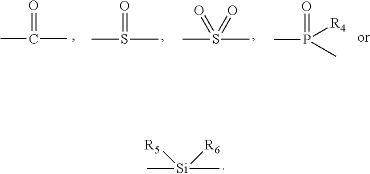

When X₁ is selected from N, Z is selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50, one of Y₁ and Y₂ is selected from —O—, —S—, —O—, —S—, —Se—, —Te—, —C—C—, —C═C—,

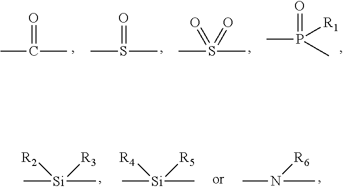

the other is selected from non-bonding, a single bond, —O—, —S—, —Se—, —Te—, —C—C—, —C═C—,

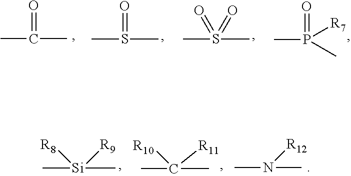

When X₁ is selected from N, Z may form a ring or may not form a ring with A₆. In some embodiments, Z may be connected with A₆ via a single bond to form a ring.

R₁ to R₁₂ are each independently selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50.

A₁ to A₆ are each independently selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50.

The boron-nitrogen compound has the advantages of narrow band emission and higher luminescence efficiency. Introducing a heteroatom may effectively enhance spin orbit coupling, accelerate intersystem crossing and reverse intersystem crossing, compete with the non-radiative transition rate, thus improving the luminescence efficiency. However, the existing boron nitrogen materials introduce fewer types of the heteroatoms and the heteroatom groups, which limits the improvement of the material performance and device performance. They cannot meet the requirements of high efficiency and long lifetime proposed by the commercial high-performance electroluminescent devices, nor can they meet the requirements of spectral matching and efficient energy transfer in a sensitization system.

The boron-nitrogen compound with the above structural formula (1) provided in the present application may be used as a red light emitting material. The luminescent core thereof has introduced different types of heteroatoms or heteroatom groups, which can improve the luminescence efficiency of the material and reduce exciton dissipation. Meanwhile, by modifying the luminescent core plane of the boron-nitrogen compound with a weak electron donating group or a weak electron withdrawing group, the charge transfer characteristics may be slightly adjusted to regulate the luminescence spectrum, which may in turn improve the luminescence efficiency and lifetime of the electroluminescent device.

Optionally, the number of carbon atoms in the aromatic group or the heterocyclic group mentioned in the embodiments of the present application may further range from 4 to 30. Furthermore, the number of carbon atoms may optionally range from 4 to 20. Furthermore, the number of carbon atoms may optionally range from 1 to 18 or 4 to 14, and may also be any numerical value between the two end values mentioned above.

Further, when the aromatic group or the heterocyclic group mentioned in the embodiments of the present application is substituted by an alkyl group or an alkoxy group, the number of carbon atoms in the alkyl or alkoxy group may be 1-30, 1-20, 3-20, 1-18, 1-15, 1-10, 1-8, or any numerical value between the two end values mentioned above.

In some embodiments, the aromatic group or the heterocyclic group, for an occurrence, is independently selected from any one of the following structural formulas 1-38:

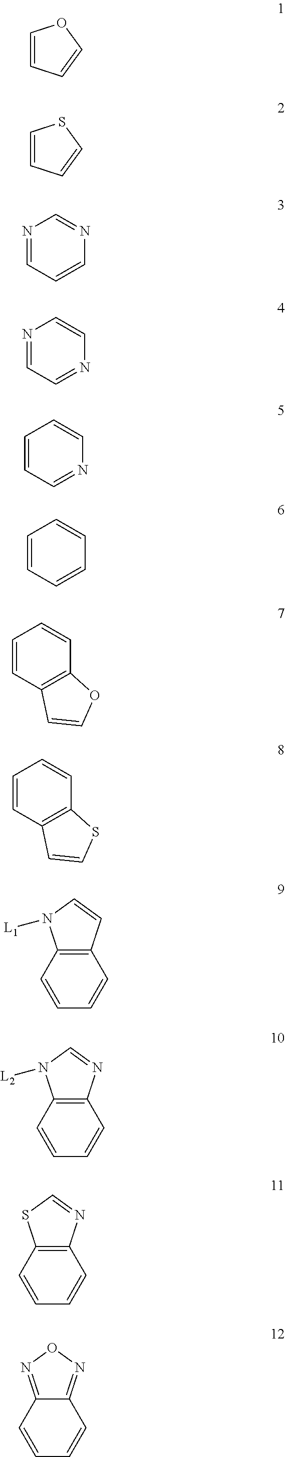

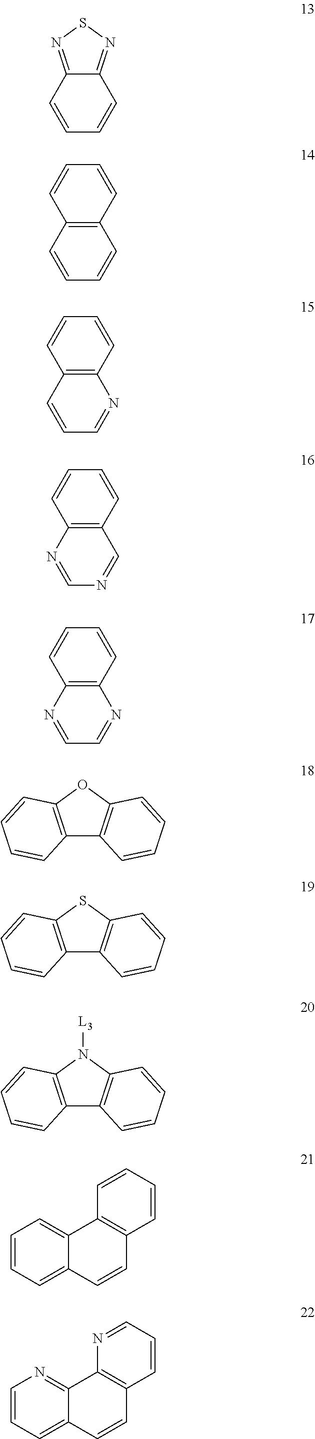

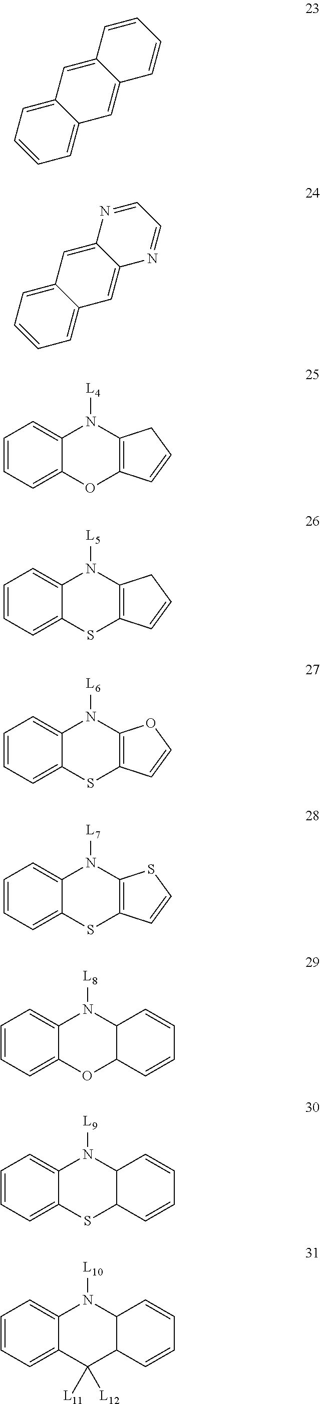

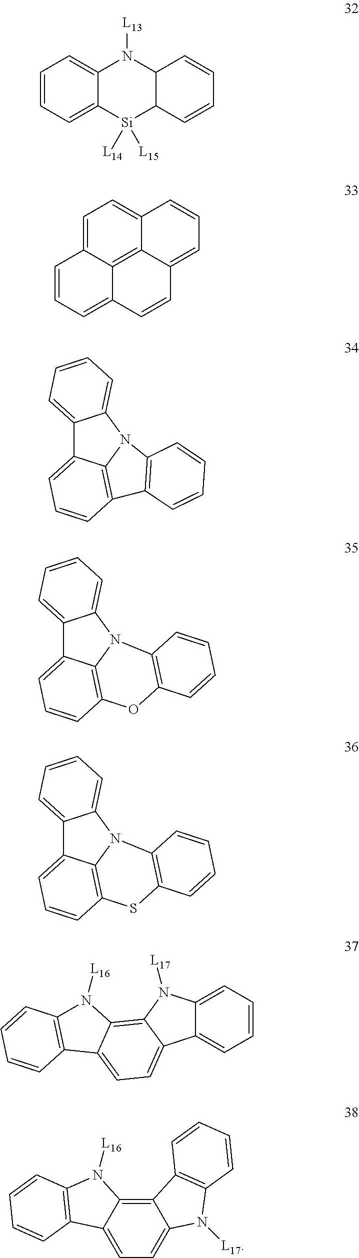

L₁ to L₁₉ are each independently selected from a linear or branched alkyl group having a carbon atom number ranging from 1 to 50, which is unsubstituted or substituted with deuterium, tritium, halogen, an alkyl group having a carbon atom number ranging from 1 to 50 or an alkoxy group having a carbon atom number ranging from 1 to 50, or an aromatic group or a heterocyclic group having a carbon atom number ranging from 4 to 50, which is unsubstituted or substituted with deuterium, tritium, halogen, an alkyl group having a carbon atom number ranging from 1 to 50 or an alkoxy group having a carbon atom number ranging from 1 to 50.

L₁ to L₁₉ may form a ring or may not form a ring between each other. In some embodiments, L₁-L₁₉ may be connected to each other through —O—, —S—, or a single bond.

In some embodiments, A₁-A₆ are independently selected from one of the following groups:

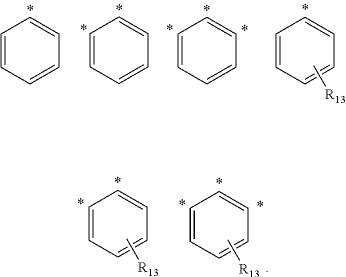

In which, R₁₃ is selected from tert-butyl. “*” represents a connection site.

In some embodiments, X₁ may be selected from O. Z may be selected from non-bonding. Y₁ may be selected from —O—, —S—, —Se—, —Te—, —C—C—, —C═C—,

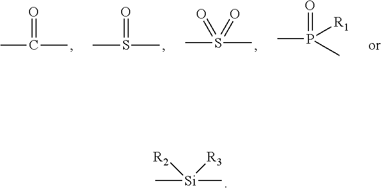

Y₂ may be selected from non-bonding, a single bond, —O—, —S—, —Se—, —Te—, —C—C—, —C═C—,

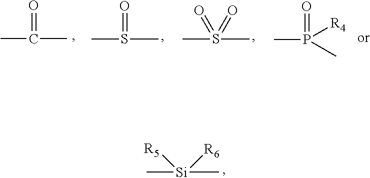

in which, R₁-R₆ may be selected from phenyl.

Further, in some embodiments, the boron-nitrogen compound is selected from one of the compounds represented by formulas 1-1-1 to 13-9-1:

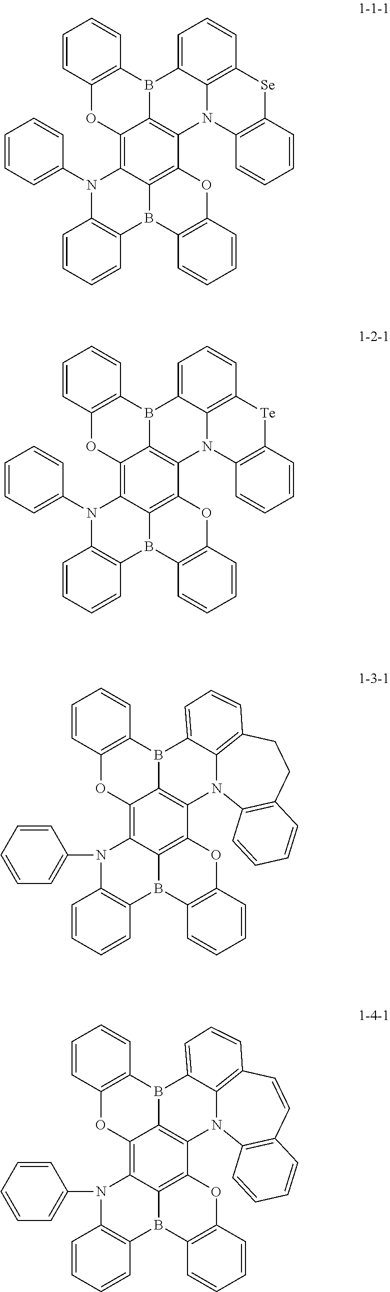

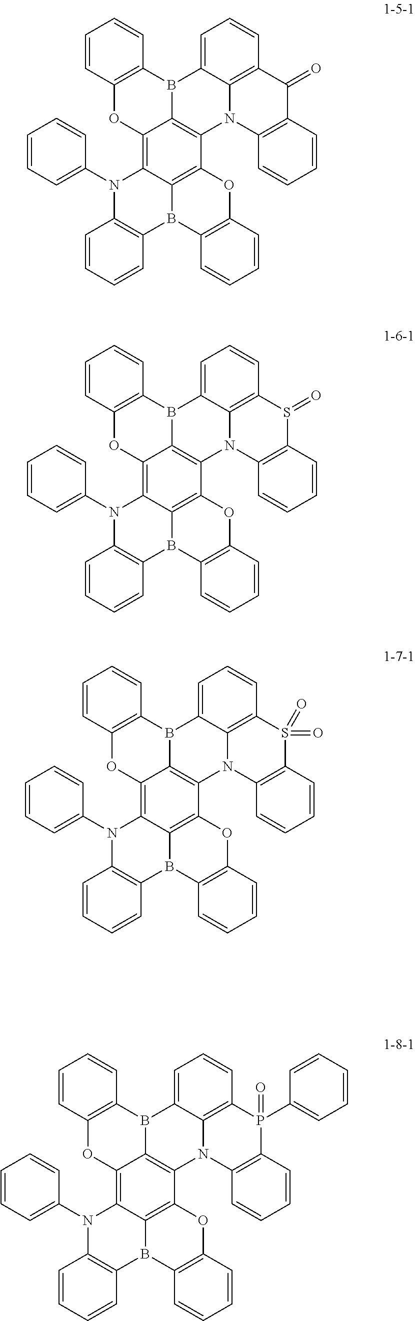 [SMILES: O=c1c2ccccc2n2c3c(cccc13)B1c3ccccc3Oc3c1c-2c1c2c3N(c3ccccc3)c3ccccc3B2c2ccccc2O1 ; O=S1c2ccccc2N2c3c(cccc31)B1c3ccccc3Oc3c1c2c1c2c3N(c3ccccc3)c3ccccc3B2c2ccccc2O1 ; O=S1(=O)c2ccccc2N2c3c(cccc31)B1c3ccccc3Oc3c1c2c1c2c3N(c3ccccc3)c3ccccc3B2c2ccccc2O1 ; O=P1(c2ccccc2)c2ccccc2N2c3c(cccc31)B1c3ccccc3Oc3c1c2c1c2c3N(c3ccccc3)c3ccccc3B2c2ccccc2O1]

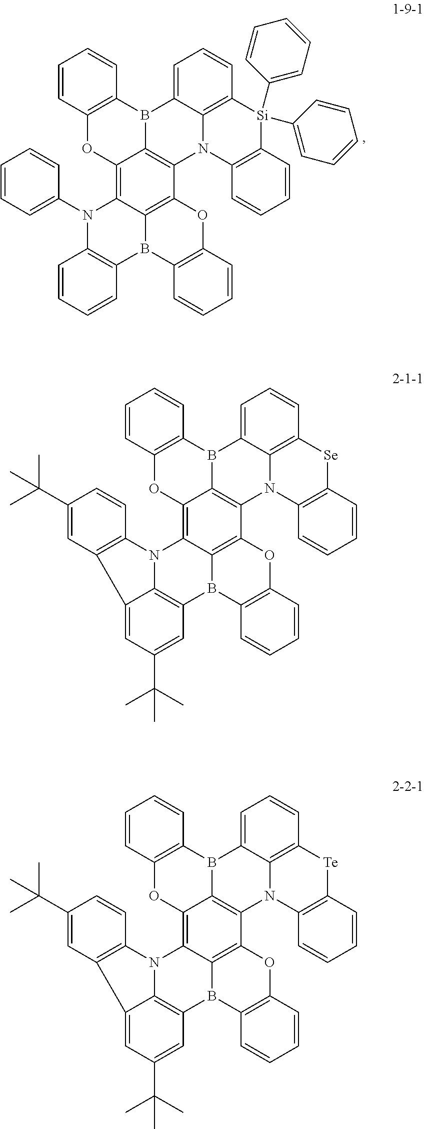

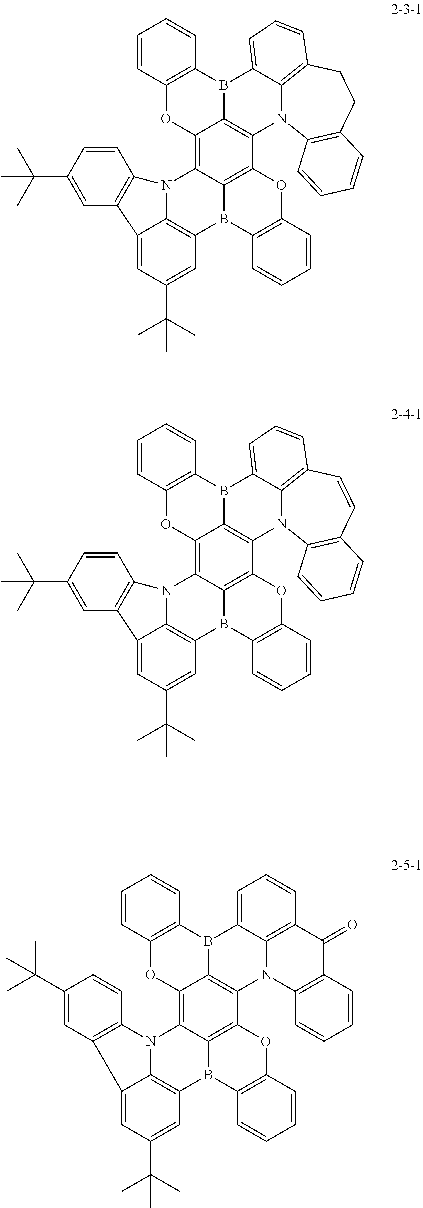 [SMILES: CC(C)(C)c1ccc2c(c1)c1cc(C(C)(C)C)cc3c1n2-c1c2c4c(c5c1B3c1ccccc1O5)N1c3ccccc3CCc3cccc(c31)B4c1ccccc1O2 ; CC(C)(C)c1ccc2c(c1)c1cc(C(C)(C)C)cc3c1n2-c1c2c4c(c5c1B3c1ccccc1O5)N1c3ccccc3C=Cc3cccc(c31)B4c1ccccc1O2 ; CC(C)(C)c1ccc2c(c1)c1cc(C(C)(C)C)cc3c1n2-c1c2c4c(c5c1B3c1ccccc1O5)-n1c3ccccc3c(=O)c3cccc(c31)B4c1ccccc1O2]

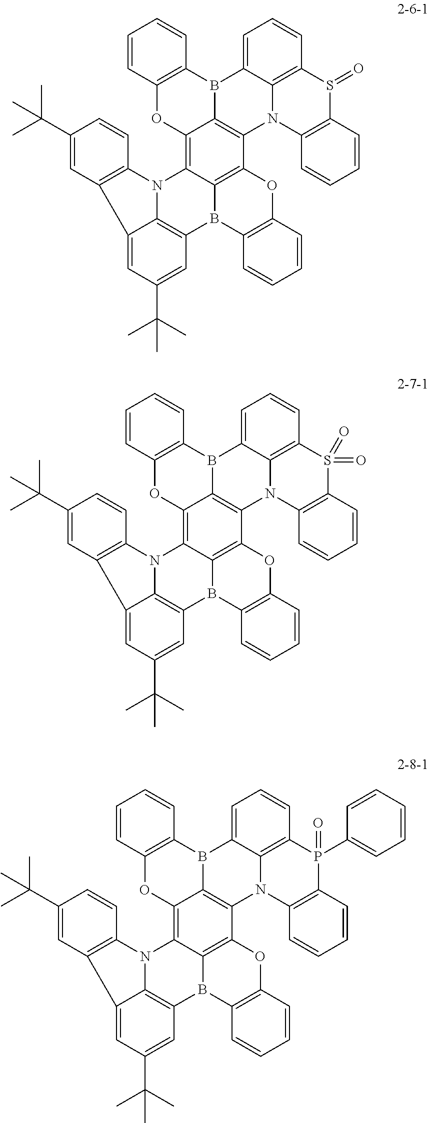

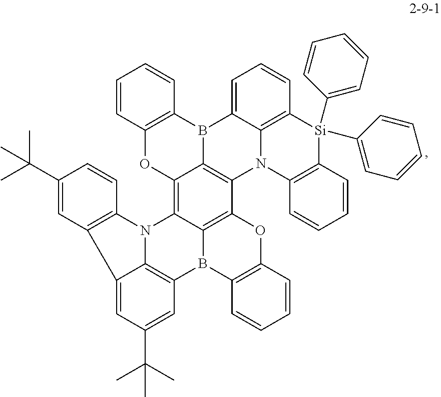 [SMILES: CC(C)(C)c1ccc2c(c1)c1cc(C(C)(C)C)cc3c1n2-c1c2c4c(c5c1B3c1ccccc1O5)N1c3ccccc3[Si](c3ccccc3)(c3ccccc3)c3cccc(c31)B4c1ccccc1O2]

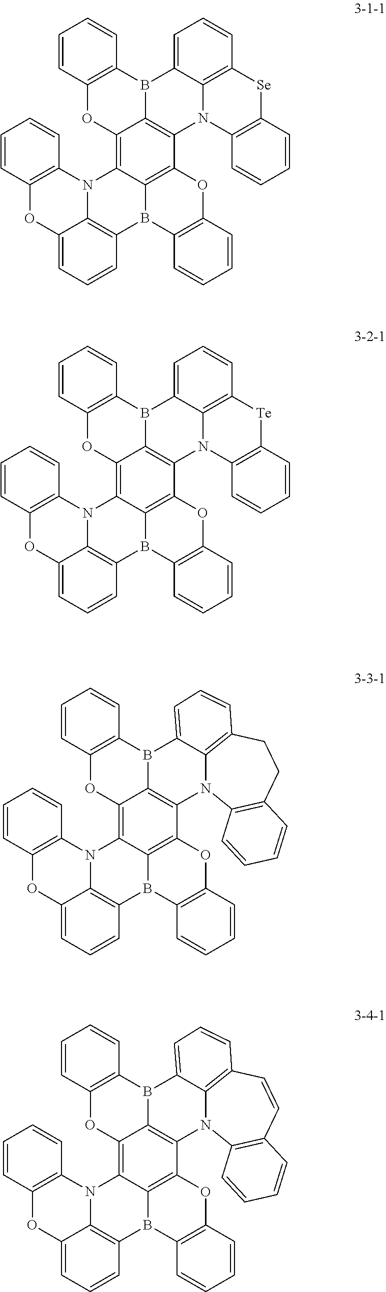

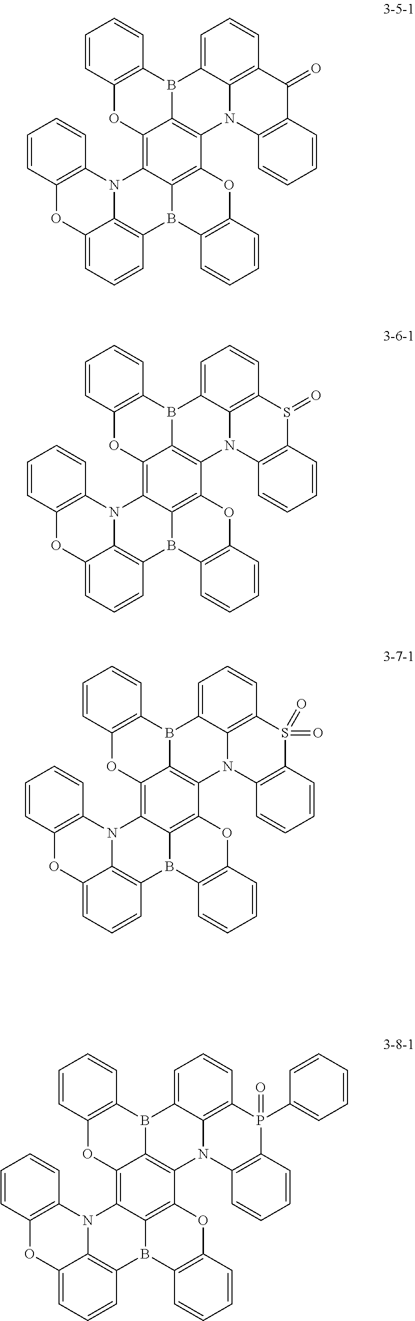 [SMILES: O=c1c2ccccc2n2c3c(cccc13)B1c3ccccc3Oc3c1c-2c1c2c3N3c4ccccc4Oc4cccc(c43)B2c2ccccc2O1 ; O=S1c2ccccc2N2c3c(cccc31)B1c3ccccc3Oc3c1c2c1c2c3N3c4ccccc4Oc4cccc(c43)B2c2ccccc2O1 ; O=S1(=O)c2ccccc2N2c3c(cccc31)B1c3ccccc3Oc3c1c2c1c2c3N3c4ccccc4Oc4cccc(c43)B2c2ccccc2O1 ; O=P1(c2ccccc2)c2ccccc2N2c3c(cccc31)B1c3ccccc3Oc3c1c2c1c2c3N3c4ccccc4Oc4cccc(c43)B2c2ccccc2O1]

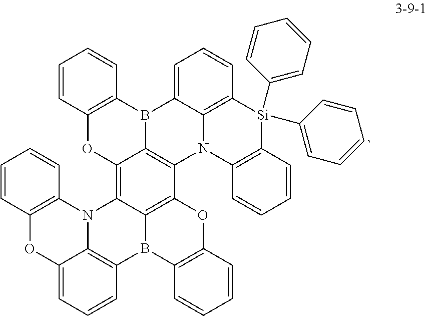 [SMILES: c1ccc([Si]2(c3ccccc3)c3ccccc3N3c4c(cccc42)B2c4ccccc4Oc4c2c3c2c3c4N4c5ccccc5Oc5cccc(c54)B3c3ccccc3O2)cc1]

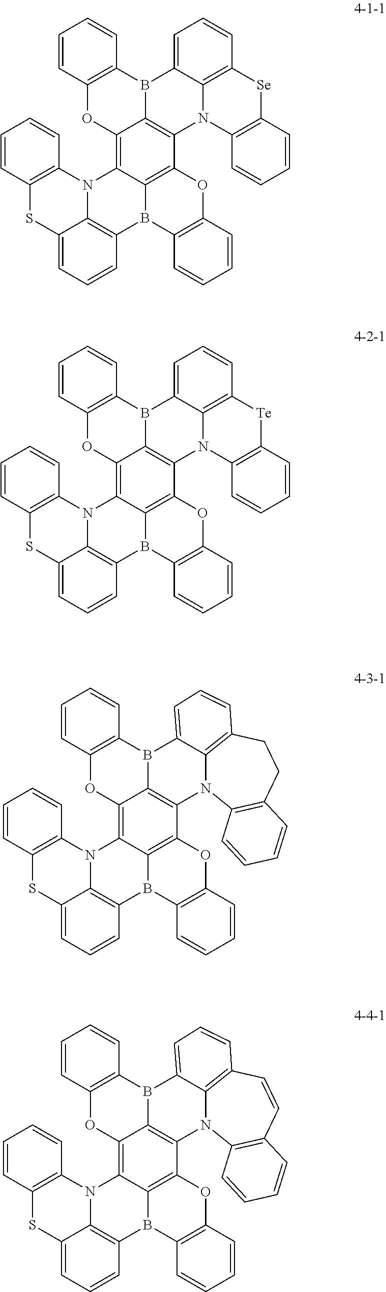

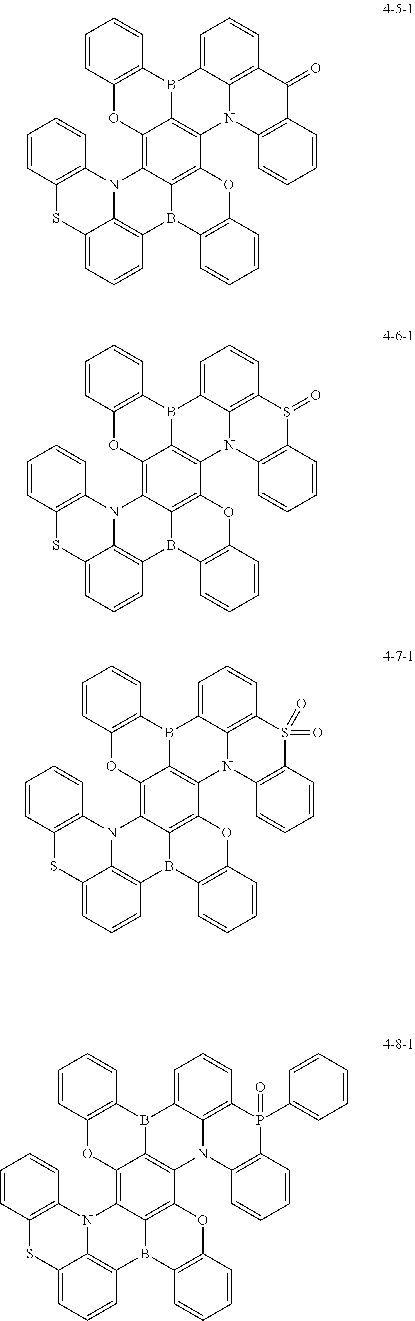 [SMILES: O=c1c2ccccc2n2c3c(cccc13)B1c3ccccc3Oc3c1c-2c1c2c3N3c4ccccc4Sc4cccc(c43)B2c2ccccc2O1 ; O=S1c2ccccc2N2c3c(cccc31)B1c3ccccc3Oc3c1c2c1c2c3N3c4ccccc4Sc4cccc(c43)B2c2ccccc2O1 ; O=S1(=O)c2ccccc2N2c3c(cccc31)B1c3ccccc3Oc3c1c2c1c2c3N3c4ccccc4Sc4cccc(c43)B2c2ccccc2O1 ; O=P1(c2ccccc2)c2ccccc2N2c3c(cccc31)B1c3ccccc3Oc3c1c2c1c2c3N3c4ccccc4Sc4cccc(c43)B2c2ccccc2O1]

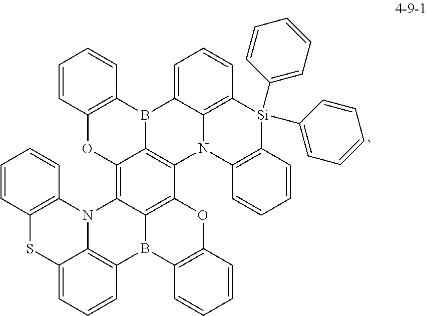 [SMILES: c1ccc([Si]2(c3ccccc3)c3ccccc3N3c4c(cccc42)B2c4ccccc4Oc4c2c3c2c3c4N4c5ccccc5Sc5cccc(c54)B3c3ccccc3O2)cc1]

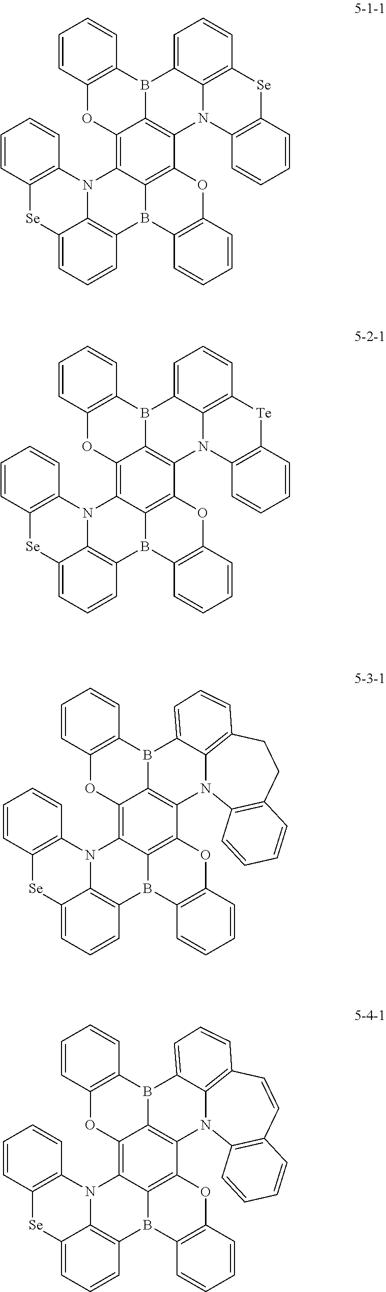

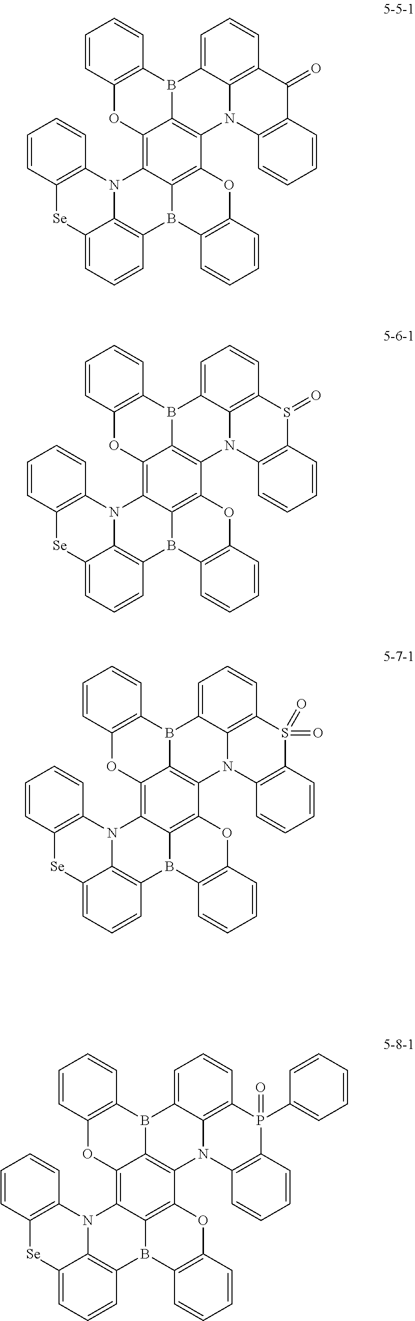 [SMILES: O=c1c2ccccc2n2c3c(cccc13)B1c3ccccc3Oc3c1c-2c1c2c3N3c4ccccc4[Se]c4cccc(c43)B2c2ccccc2O1 ; O=S1c2ccccc2N2c3c(cccc31)B1c3ccccc3Oc3c1c2c1c2c3N3c4ccccc4[Se]c4cccc(c43)B2c2ccccc2O1 ; O=S1(=O)c2ccccc2N2c3c(cccc31)B1c3ccccc3Oc3c1c2c1c2c3N3c4ccccc4[Se]c4cccc(c43)B2c2ccccc2O1 ; O=P1(c2ccccc2)c2ccccc2N2c3c(cccc31)B1c3ccccc3Oc3c1c2c1c2c3N3c4ccccc4[Se]c4cccc(c43)B2c2ccccc2O1]

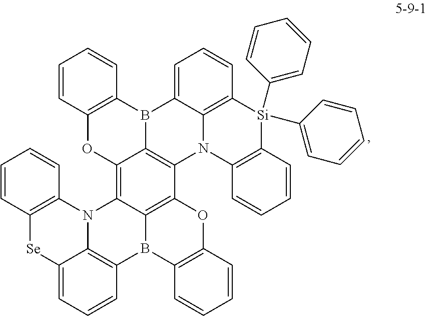 [SMILES: c1ccc([Si]2(c3ccccc3)c3ccccc3N3c4c(cccc42)B2c4ccccc4Oc4c2c3c2c3c4N4c5ccccc5[Se]c5cccc(c54)B3c3ccccc3O2)cc1]

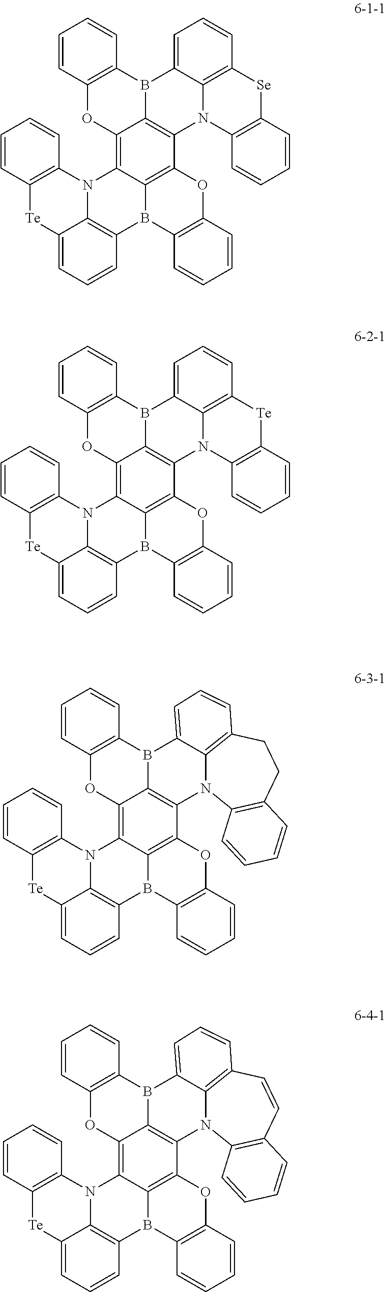

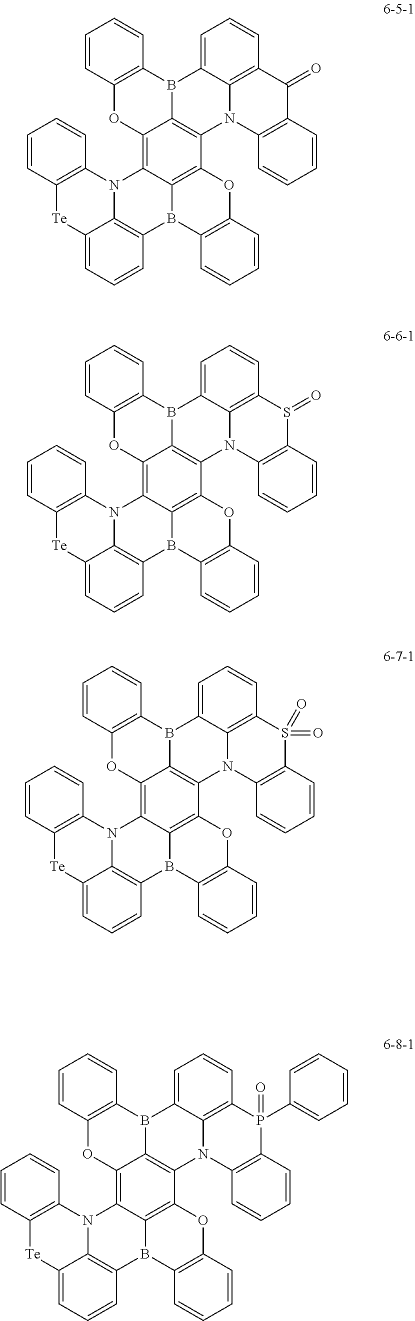

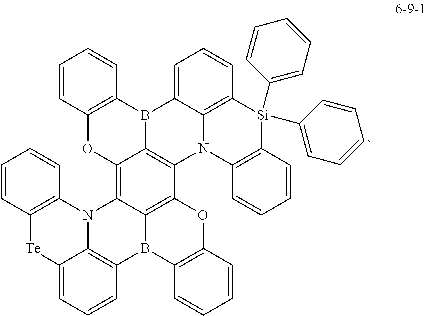

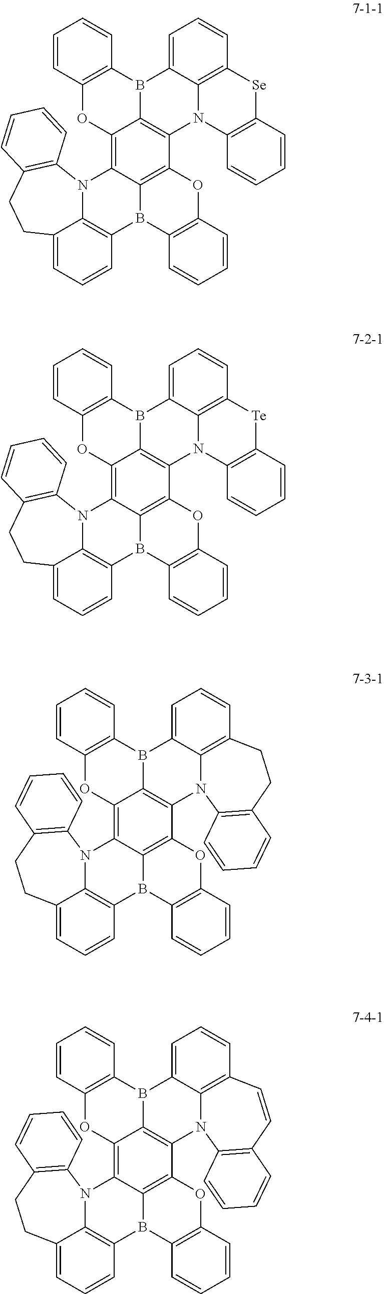

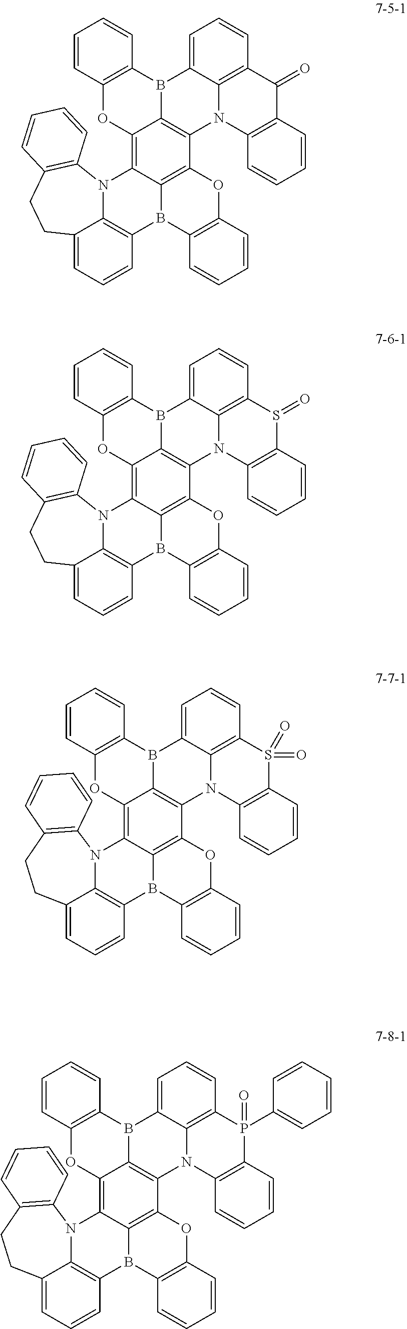 [SMILES: O=c1c2ccccc2n2c3c(cccc13)B1c3ccccc3Oc3c1c-2c1c2c3N3c4ccccc4CCc4cccc(c43)B2c2ccccc2O1 ; O=S1c2ccccc2N2c3c(cccc31)B1c3ccccc3Oc3c1c2c1c2c3N3c4ccccc4CCc4cccc(c43)B2c2ccccc2O1 ; O=S1(=O)c2ccccc2N2c3c(cccc31)B1c3ccccc3Oc3c1c2c1c2c3N3c4ccccc4CCc4cccc(c43)B2c2ccccc2O1 ; O=P1(c2ccccc2)c2ccccc2N2c3c(cccc31)B1c3ccccc3Oc3c1c2c1c2c3N3c4ccccc4CCc4cccc(c43)B2c2ccccc2O1]

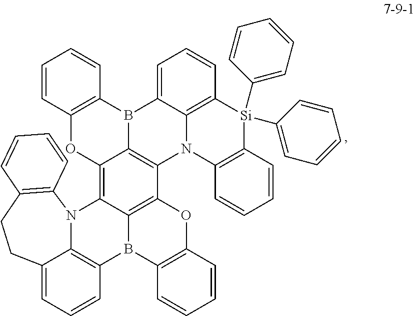 [SMILES: c1ccc([Si]2(c3ccccc3)c3ccccc3N3c4c(cccc42)B2c4ccccc4Oc4c2c3c2c3c4N4c5ccccc5CCc5cccc(c54)B3c3ccccc3O2)cc1]

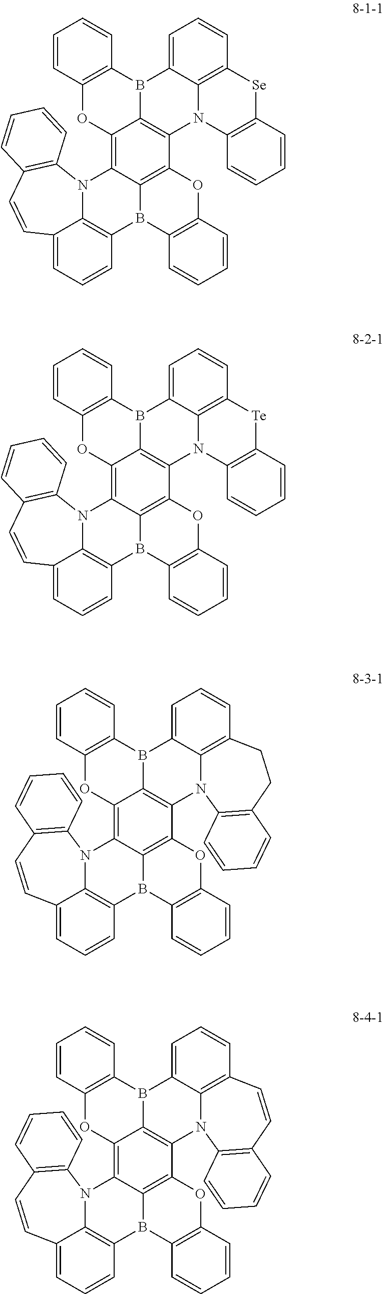

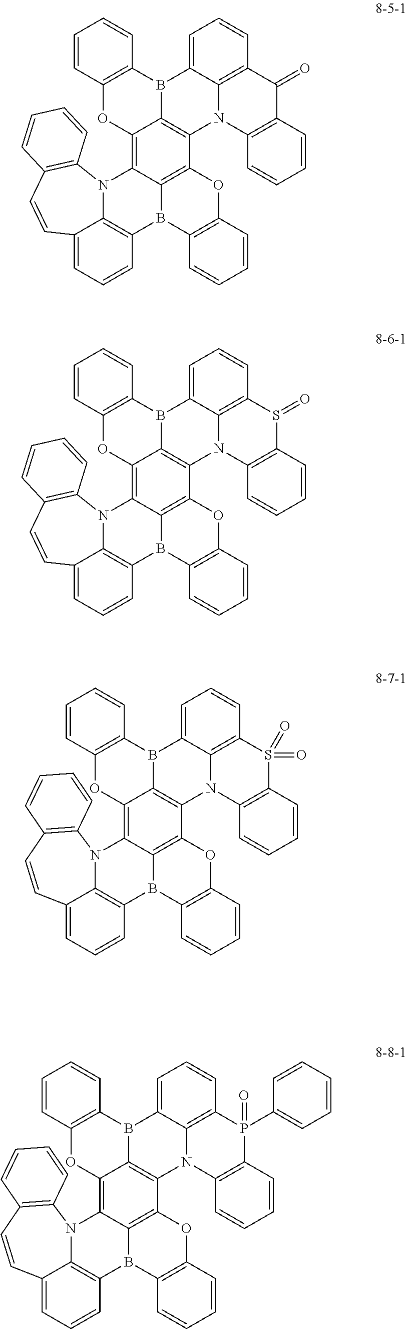 [SMILES: O=c1c2ccccc2n2c3c(cccc13)B1c3ccccc3Oc3c1c-2c1c2c3N3c4ccccc4C=Cc4cccc(c43)B2c2ccccc2O1 ; O=S1c2ccccc2N2c3c(cccc31)B1c3ccccc3Oc3c1c2c1c2c3N3c4ccccc4C=Cc4cccc(c43)B2c2ccccc2O1 ; O=S1(=O)c2ccccc2N2c3c(cccc31)B1c3ccccc3Oc3c1c2c1c2c3N3c4ccccc4C=Cc4cccc(c43)B2c2ccccc2O1 ; O=P1(c2ccccc2)c2ccccc2N2c3c(cccc31)B1c3ccccc3Oc3c1c2c1c2c3N3c4ccccc4C=Cc4cccc(c43)B2c2ccccc2O1]

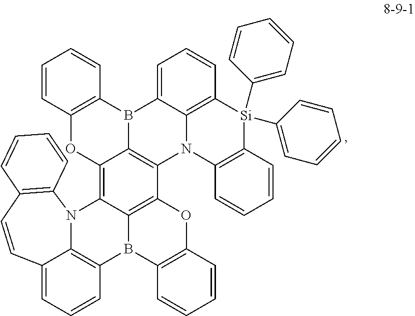 [SMILES: C1=Cc2cccc3c2N(c2ccccc21)c1c2c4c(c5c1B3c1ccccc1O5)N1c3ccccc3[Si](c3ccccc3)(c3ccccc3)c3cccc(c31)B4c1ccccc1O2]

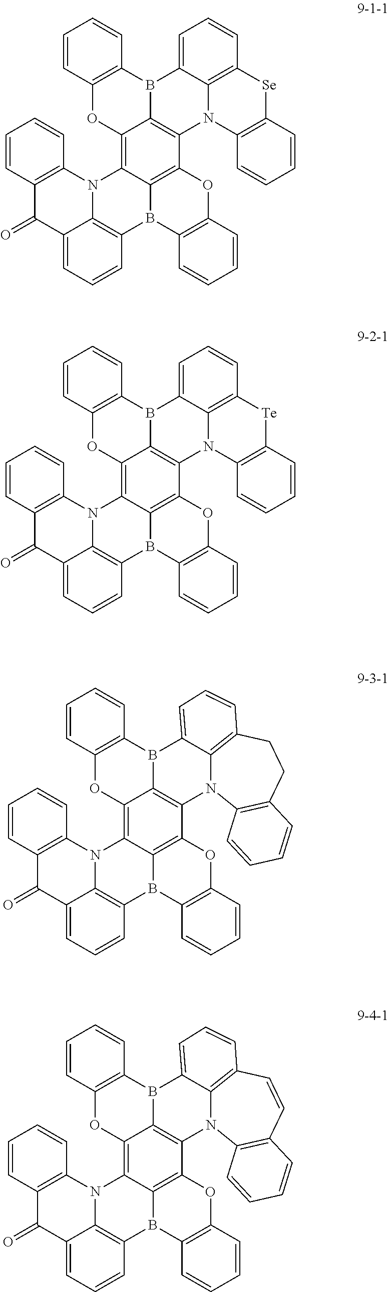

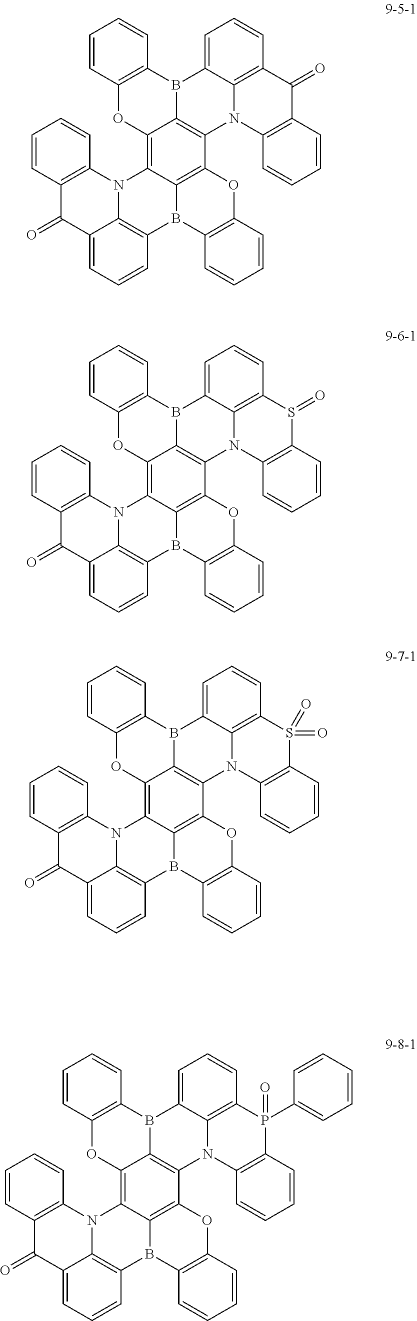 [SMILES: O=c1c2ccccc2n2c3c(cccc13)B1c3ccccc3Oc3c1c-2c1c2c3-n3c4ccccc4c(=O)c4cccc(c43)B2c2ccccc2O1 ; O=c1c2ccccc2n2c3c(cccc13)B1c3ccccc3Oc3c1c-2c1c2c3N3c4ccccc4S(=O)c4cccc(c43)B2c2ccccc2O1 ; O=c1c2ccccc2n2c3c(cccc13)B1c3ccccc3Oc3c1c-2c1c2c3N3c4ccccc4S(=O)(=O)c4cccc(c43)B2c2ccccc2O1 ; O=c1c2ccccc2n2c3c(cccc13)B1c3ccccc3Oc3c1c-2c1c2c3N3c4ccccc4P(=O)(c4ccccc4)c4cccc(c43)B2c2ccccc2O1]

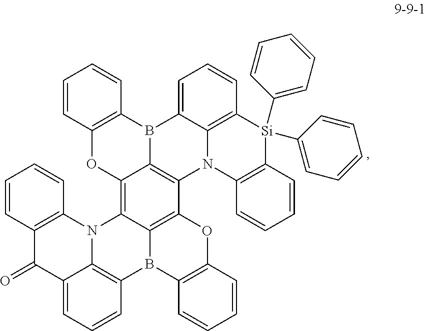 [SMILES: O=c1c2ccccc2n2c3c(cccc13)B1c3ccccc3Oc3c1c-2c1c2c3N3c4ccccc4[Si](c4ccccc4)(c4ccccc4)c4cccc(c43)B2c2ccccc2O1]

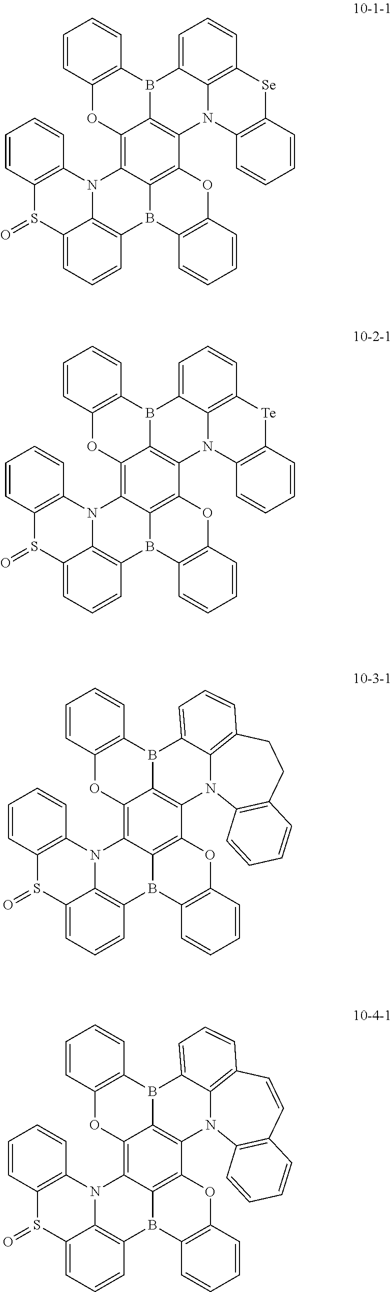

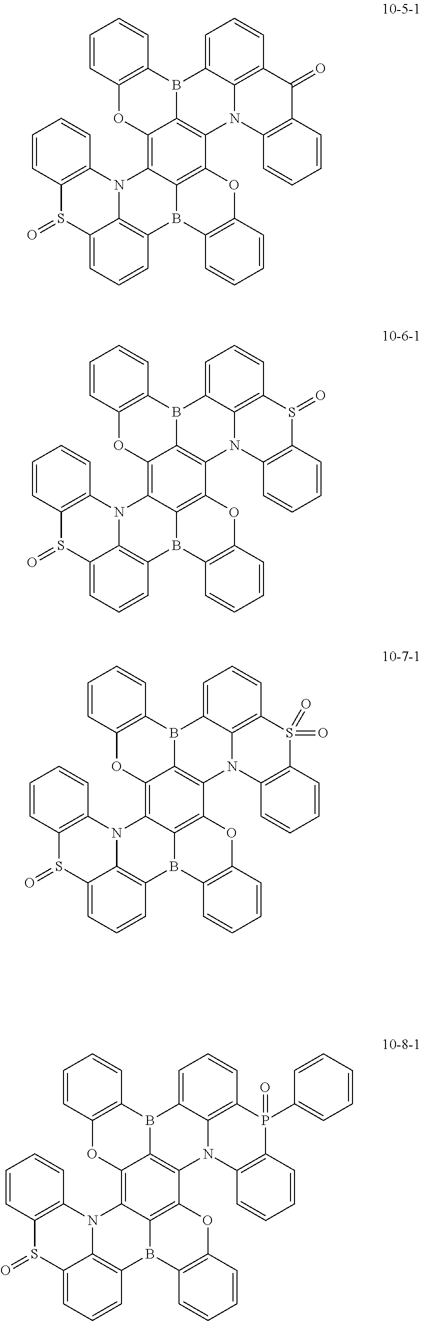 [SMILES: O=c1c2ccccc2n2c3c(cccc13)B1c3ccccc3Oc3c1c-2c1c2c3N3c4ccccc4S(=O)c4cccc(c43)B2c2ccccc2O1 ; O=S1c2ccccc2N2c3c(cccc31)B1c3ccccc3Oc3c1c2c1c2c3N3c4ccccc4S(=O)c4cccc(c43)B2c2ccccc2O1 ; O=S1c2ccccc2N2c3c(cccc31)B1c3ccccc3Oc3c1c2c1c2c3N3c4ccccc4S(=O)(=O)c4cccc(c43)B2c2ccccc2O1 ; O=S1c2ccccc2N2c3c(cccc31)B1c3ccccc3Oc3c1c2c1c2c3N3c4ccccc4P(=O)(c4ccccc4)c4cccc(c43)B2c2ccccc2O1]

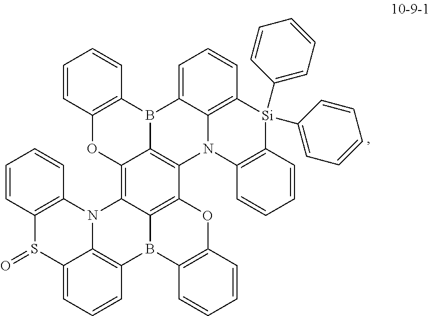 [SMILES: O=S1c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1]

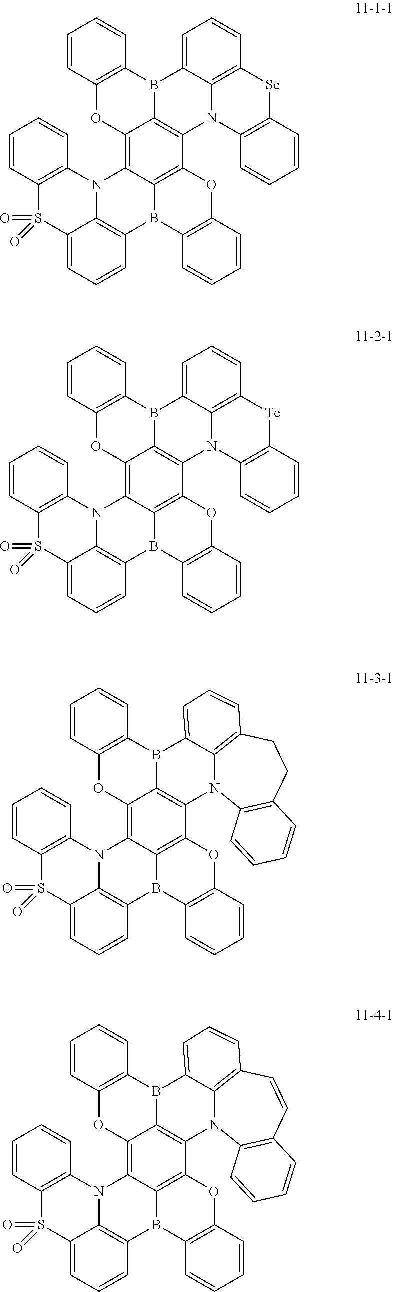

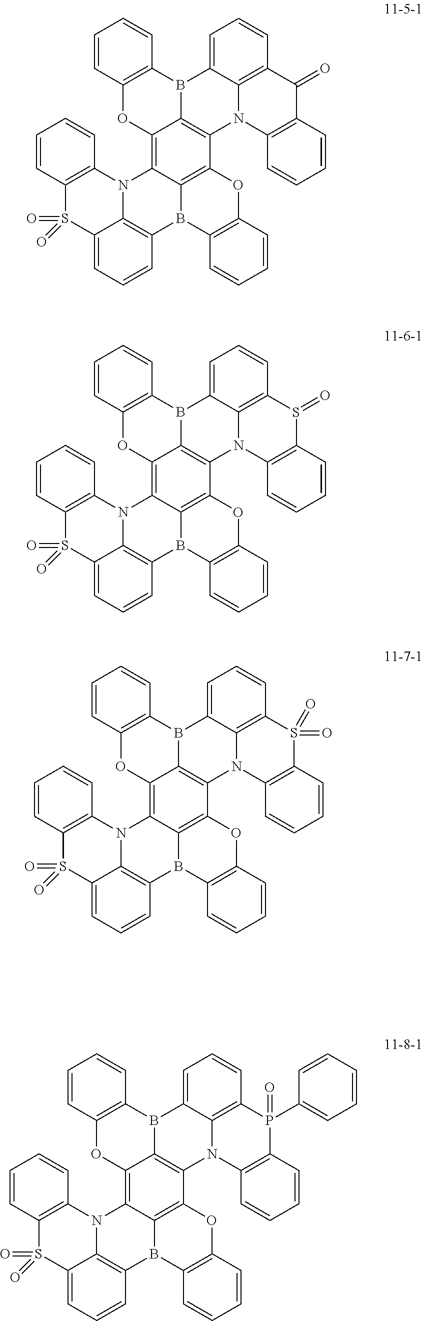 [SMILES: O=c1c2ccccc2n2c3c(cccc13)B1c3ccccc3Oc3c1c-2c1c2c3N3c4ccccc4S(=O)(=O)c4cccc(c43)B2c2ccccc2O1 ; O=S1c2ccccc2N2c3c(cccc31)B1c3ccccc3Oc3c1c2c1c2c3N3c4ccccc4S(=O)(=O)c4cccc(c43)B2c2ccccc2O1 ; O=S1(=O)c2ccccc2N2c3c(cccc31)B1c3ccccc3Oc3c1c2c1c2c3N3c4ccccc4S(=O)(=O)c4cccc(c43)B2c2ccccc2O1 ; O=P1(c2ccccc2)c2ccccc2N2c3c(cccc31)B1c3ccccc3Oc3c1c2c1c2c3N3c4ccccc4S(=O)(=O)c4cccc(c43)B2c2ccccc2O1]

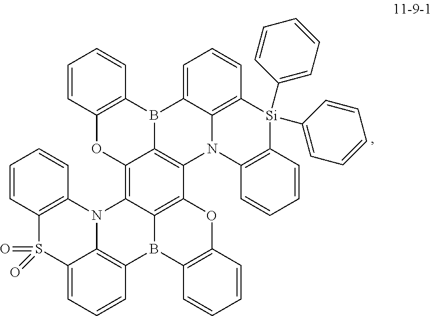 [SMILES: O=S1(=O)c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1]

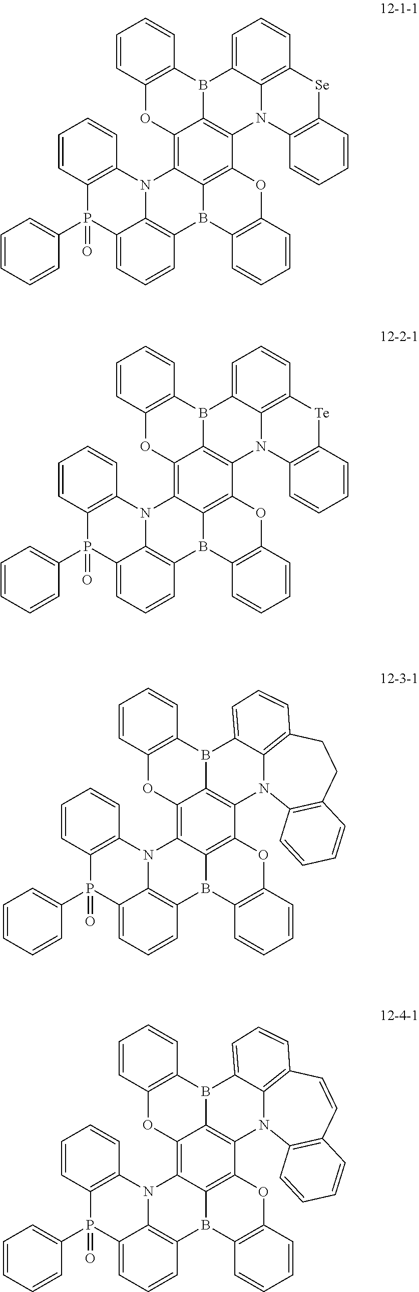

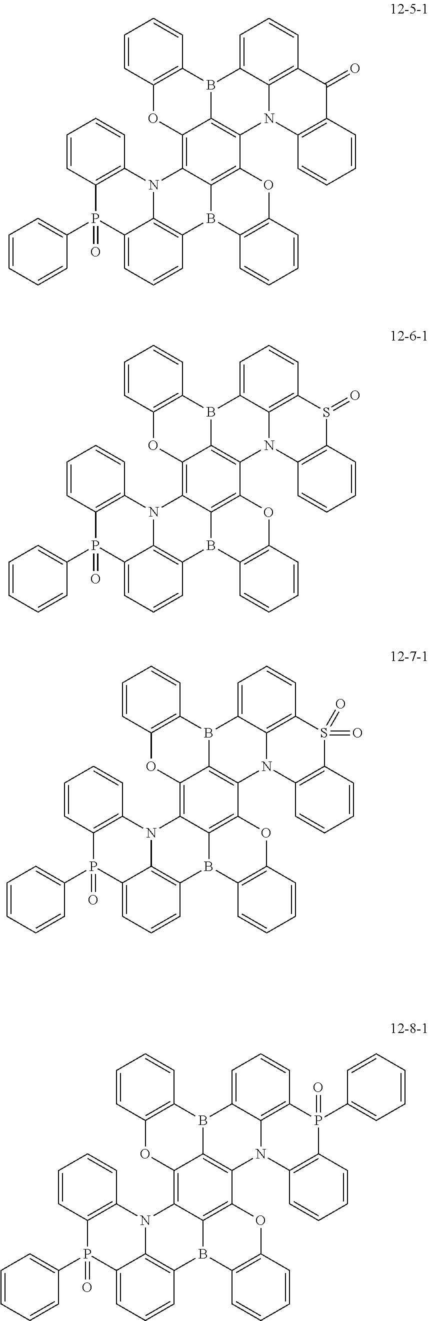 [SMILES: O=c1c2ccccc2n2c3c(cccc13)B1c3ccccc3Oc3c1c-2c1c2c3N3c4ccccc4P(=O)(c4ccccc4)c4cccc(c43)B2c2ccccc2O1 ; O=S1c2ccccc2N2c3c(cccc31)B1c3ccccc3Oc3c1c2c1c2c3N3c4ccccc4P(=O)(c4ccccc4)c4cccc(c43)B2c2ccccc2O1 ; O=P1(c2ccccc2)c2ccccc2N2c3c(cccc31)B1c3ccccc3Oc3c1c2c1c2c3N3c4ccccc4S(=O)(=O)c4cccc(c43)B2c2ccccc2O1 ; O=P1(c2ccccc2)c2ccccc2N2c3c(cccc31)B1c3ccccc3Oc3c1c2c1c2c3N3c4ccccc4P(=O)(c4ccccc4)c4cccc(c43)B2c2ccccc2O1]

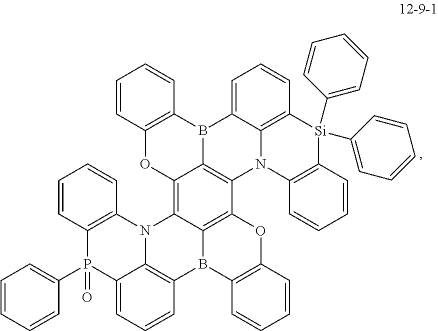 [SMILES: O=P1(c2ccccc2)c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1]

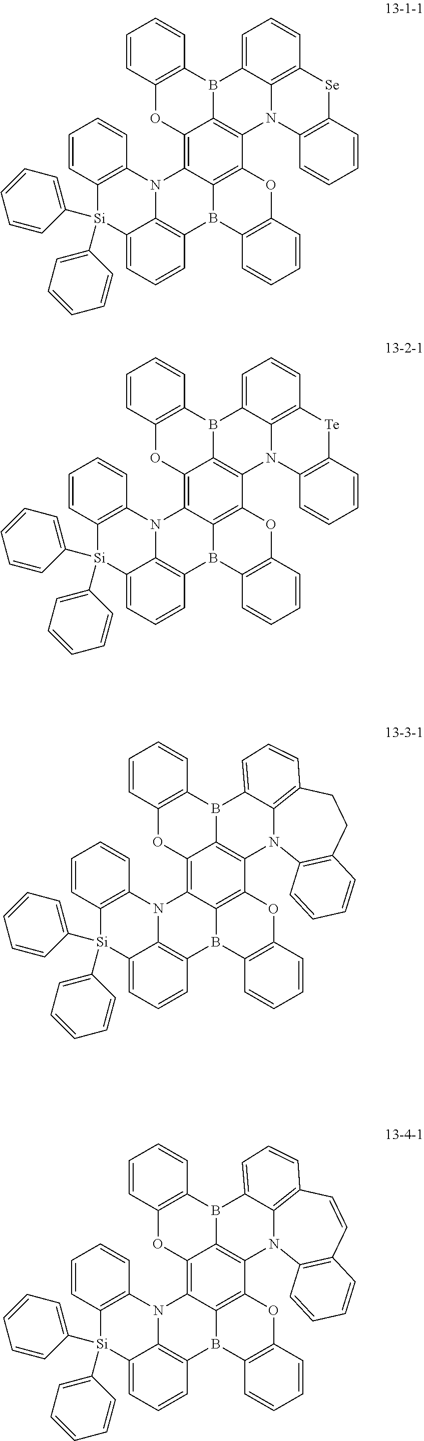

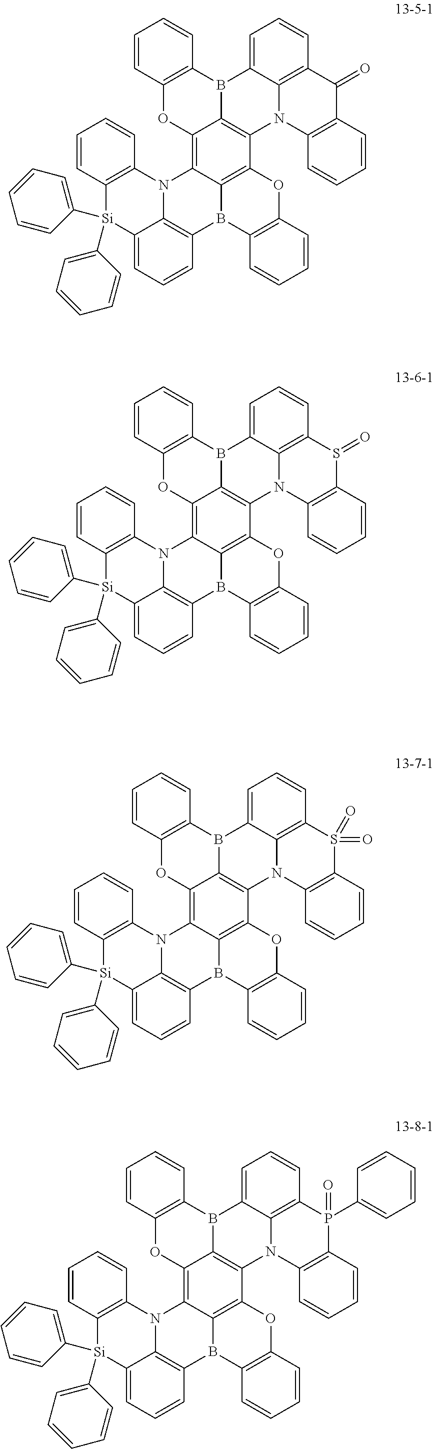 [SMILES: O=c1c2ccccc2n2c3c(cccc13)B1c3ccccc3Oc3c1c-2c1c2c3N3c4ccccc4[Si](c4ccccc4)(c4ccccc4)c4cccc(c43)B2c2ccccc2O1 ; O=S1c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1 ; O=S1(=O)c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1 ; O=P1(c2ccccc2)c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1]

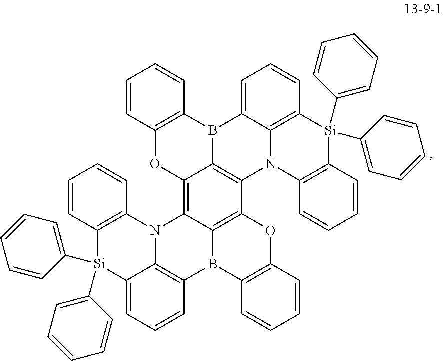 [SMILES: c1ccc([Si]2(c3ccccc3)c3ccccc3N3c4c(cccc42)B2c4ccccc4Oc4c2c3c2c3c4N4c5ccccc5[Si](c5ccccc5)(c5ccccc5)c5cccc(c54)B3c3ccccc3O2)cc1]

In some embodiments, X₁ may be selected from N. Z may be selected from p-tertiary phenyl. Y₁ and Y₂ may each independently be selected from —O—, —S—, —Se—, —Te—. Z and A₆ may form a ring or may not form a ring.

Furthermore, in some embodiments, the boron-nitrogen compound may be selected from one of the compounds represented by formulas 1-1-2 to 4-4-2 and 1-1-3 to 4-4-3:

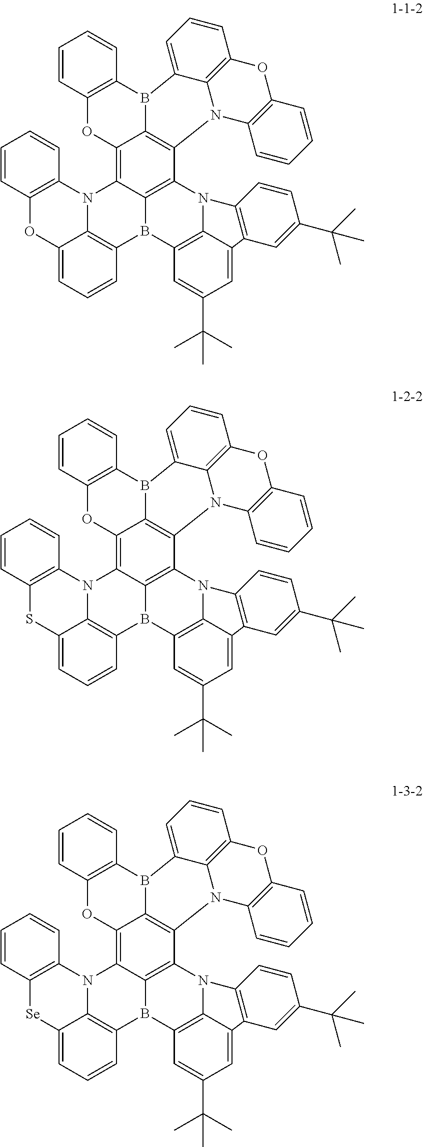

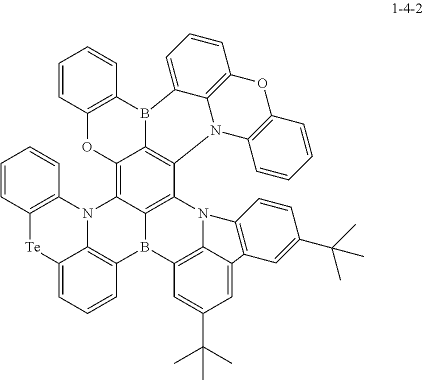

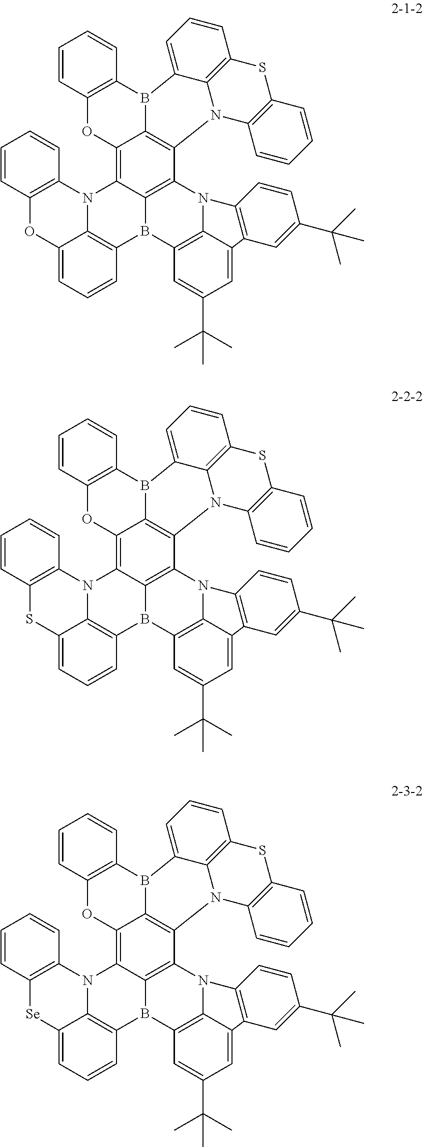

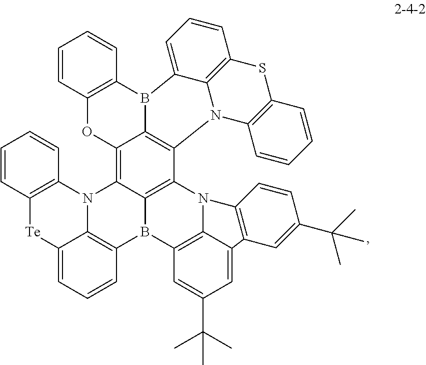

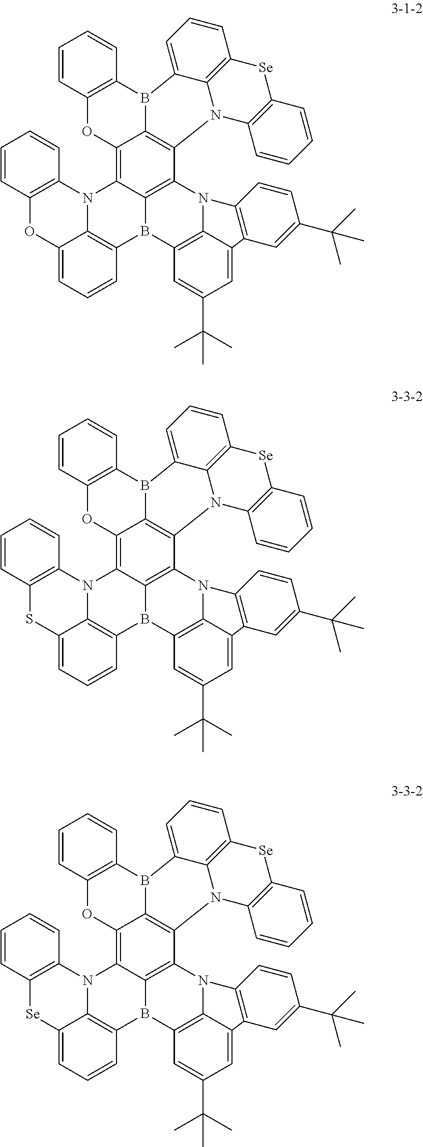

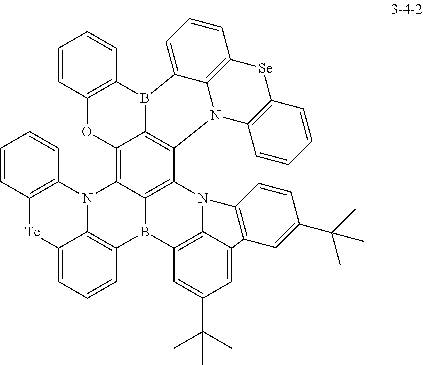

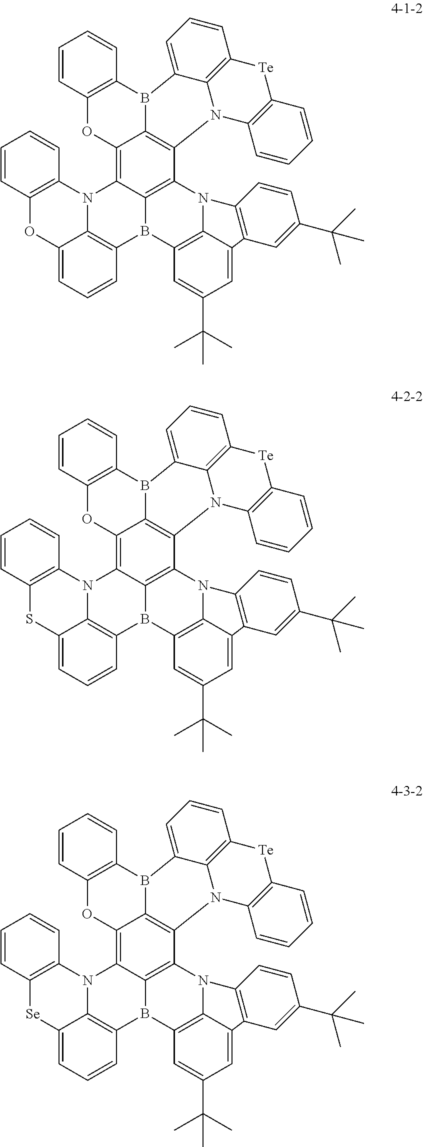

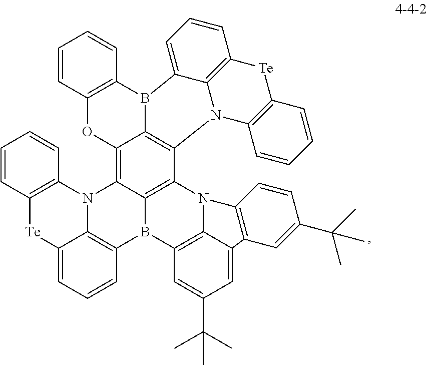

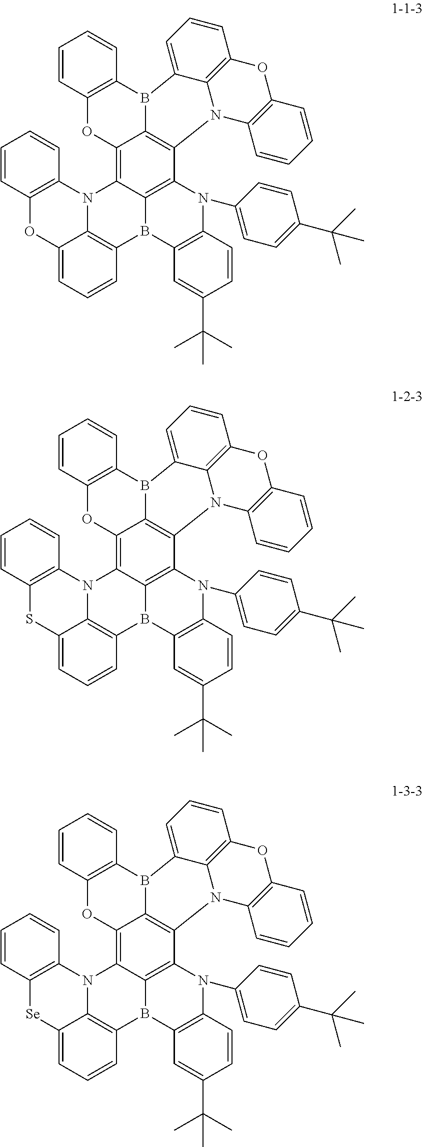

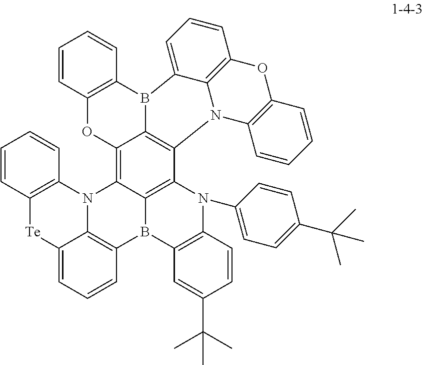

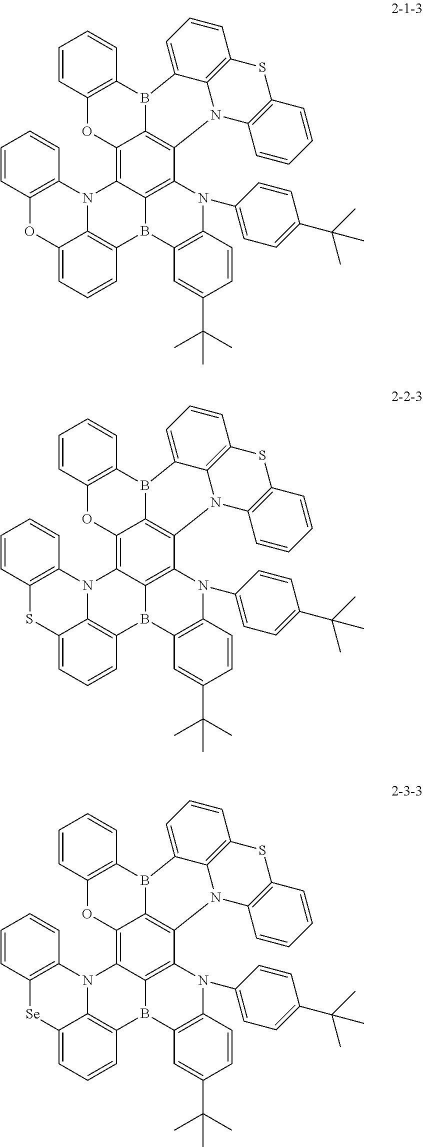

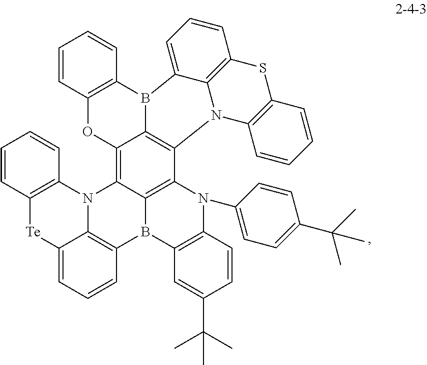

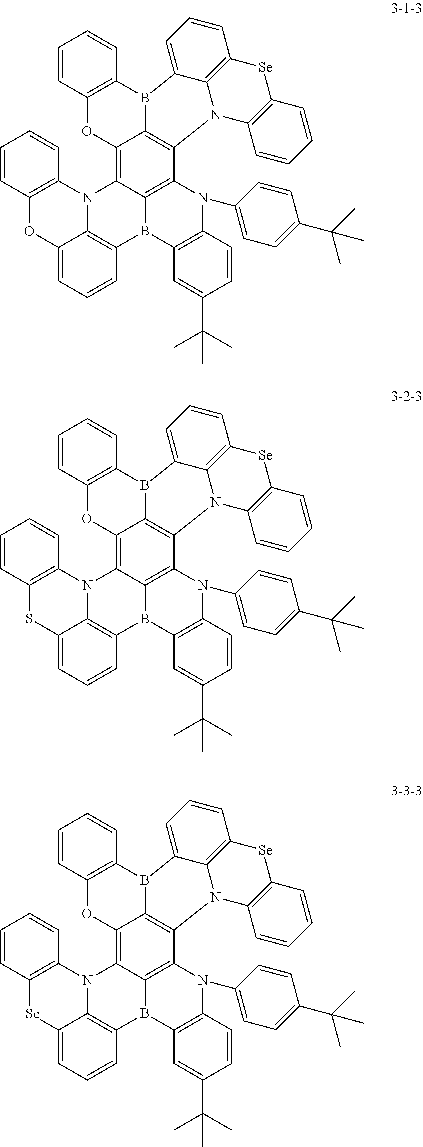

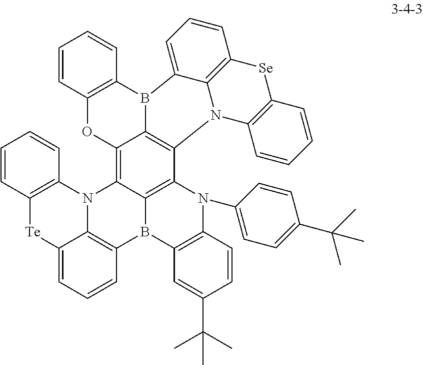

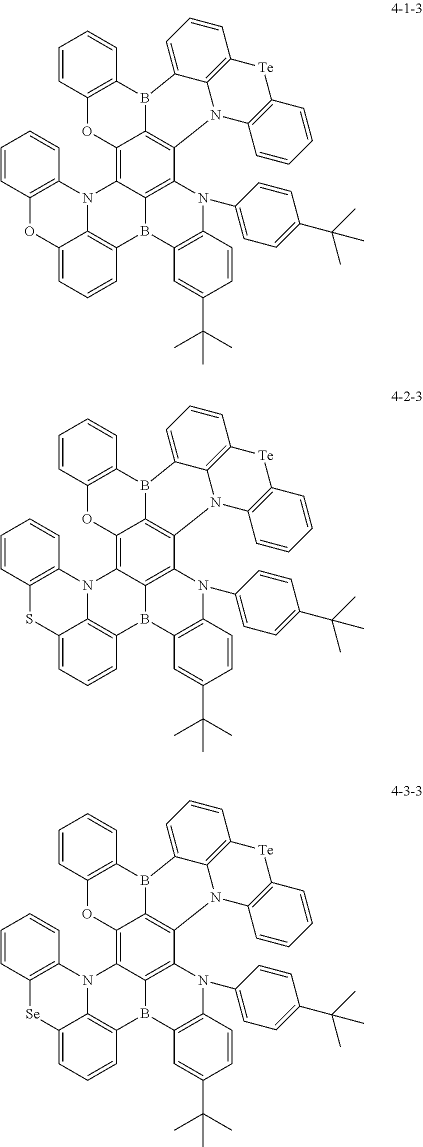

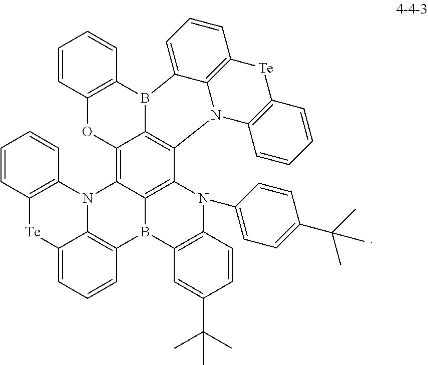

The embodiments of the present application also provide an electroluminescent device including an anode and a cathode, and a light-emitting layer located between the anode and the cathode.

The material of the light-emitting layer may include the boron-nitrogen compound as described in the above embodiments. The boron-nitrogen compound has the advantages of narrow spectral band emission and high luminescence efficiency. The boron-nitrogen compound in the embodiments of the present application may be used as the red light emitting material. By modifying the luminescent core plane of the boron-nitrogen compound with the weak electron donating groups or the weak electron withdrawing groups, the charge transfer characteristics may be slightly adjusted to regulate the luminescence spectrum, which may in turn improve the luminescence efficiency and lifetime of the electroluminescent device.

In some embodiments, the electroluminescent device further incudes a hole injection layer, a hole transport layer, and an electron blocking layer which are located between the anode and the light-emitting layer and sequentially stacked on the anode. The hole transport layer may be a multi-layer composite film layer, including a stacked first hole transport layer and second hole transport layer.

In some embodiments, the electroluminescent device further comprises an electron transport layer and an electron injection layer which are located between the light-emitting layer and the cathode, and sequentially stacked on the light-emitting layer. The electronic transport layer may be a multi-layer composite film layer, comprising a stacked first electronic transport layer and second electronic transport layer.

The electroluminescent device described in the present application may be selected from, but is not limited to, an organic light-emitting diode (OLED), an organic photovoltaic cell, an organic light-emitting cell, an organic field-effect transistor, an organic light-emitting field effect transistor, an organic laser, an organic spintronics device, an organic sensor, and an organic plasmon emission diode and so on, with OLED being particularly preferred.

In the embodiments of the present application, the anode may include a conductive metal, a metal oxide, or a conductive polymer. The anode may easily inject holes into the hole injection layer, the hole transport layer, or the light-emitting layer.

In some embodiments, examples of the anode materials include, but are not limited to: Al, Cu, Au, Ag, Mg, Fe, Co, Ni, Mn, Pd, Pt, ITO, aluminum doped zinc oxide (AZO), etc. Other anode materials are known and may be easily selected and used by those skilled in the art. The anode material may be deposited using any suitable technique, such as an appropriate physical vapor deposition method, including radio frequency magnetron sputtering, vacuum thermal evaporation, electron beam (e-beam), etc.

In some embodiments, the anode is patterned and structured. The patterned ITO conductive substrate is commercially available and may be used to prepare the electroluminescent device according to the present application.

In the present disclosure, the cathode may include a conductive metal or a metal oxide. The cathode may easily inject electrons into the electron injection layer or the electron transport layer, or directly into the light-emitting layer.

In principle, all materials that may be used as a cathode for OLED may be used as cathode materials for the devices in the present application. Examples of the cathode materials include but are not limited to: Al, Au, Ag, Ca, Ba, Mg, LiF/Al, MgAg alloy, BaF₂/Al, Cu, Fe, Co, Ni, Mn, Pd, Pt, ITO, etc. The cathode material may be deposited using any suitable technique, such as an appropriate physical vapor deposition method, including radio frequency magnetron sputtering, vacuum thermal evaporation, electron beam (e-beam), etc.

The hole injection material, the hole transport material, the electron blocking material, the electron transport material, and the electron injection material used in the electroluminescent device of the present application are not particularly limited, and any compound may be used as long as the compound is commonly used as the hole injection material, the hole transport material, the electron blocking material, the electron transport material, and the electron injection material.

The present application also relates to the use of the electroluminescent device according to the present application in various electronic devices, including but not limited to a display device, a lighting device, a light source, a sensor, and the like.

The embodiments of the present application also provide a display device, including but not limited to a mobile phone, a car display, a wearable device, an augmented reality (AR), a virtual reality (VR), a laptop, a television, etc.

### EXAMPLES

The following Examples will be used to illustrate the present application. The following examples are only part of the Examples of the present application and do not limit the present application. The raw materials used in the following examples, unless otherwise specified, are all commercially available products. Among them, Pd₂(dba)₃: tris(dibenzylideneacetone) dipalladium; (t-Bu)₃PHBF₄: tritert-butylphosphine tetrafluoroborate; t-BuONa: Sodium tert-butoxide; O-DCB: o-dichlorobenzene; Pd (OAc)₂: palladium acetate; Tolune: toluene; T-BuOK: potassium tert-butoxide; DMF: N,N-dimethylformamide; T-BuLi: tert-butyl lithium; BBr₃: Boron tribromide; DIPEA: N,N-diisopropylethylamine; CuI: cuprous iodide; K₂CO₃: Potassium carbonate; 1,4-dioxane: 1,4-dioxane; Pd (OAc)₂: palladium acetate; Cs₂CO₃: Cesium carbonate.

### Example 1

The synthesis route of the target compound 1-1-1 in the present Example is as follows:

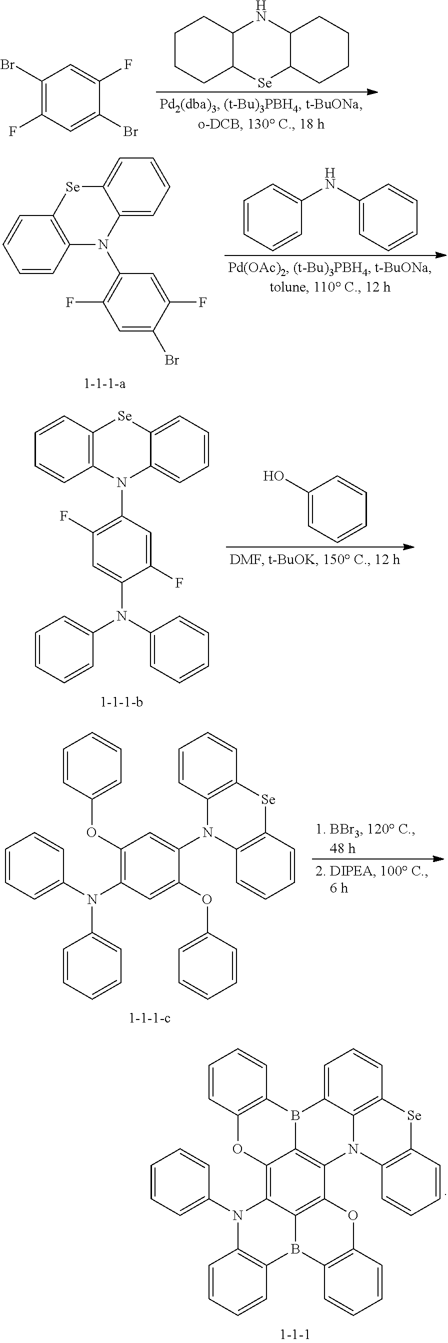

### Synthesis Steps:

1.1 Synthesis of Intermediate 1-1-1-a: 1,4-dibromo-2,5-difluorobenzene (16.3 g, 60 mmol), phenoselezine (12.3 g, 50 mmol), tris(dibenzylidene) acetone dipalladium (1.9 g, 2 mmol), tris(tert butylphosphine) tetrafluoroborate (1.2 g, 4 mmol), sodium tert-butoxide (5.8 g, 60 mmol), and o-dichlorobenzene (150 mL) were added to a 500 mL round bottom flask, and the steps of vacuum pumping and introducing an argon gas were cycled for three times. The mixture was stirred at 130° C. for 18 hours under argon atmosphere protection. After cooling to a room temperature, the mixture was poured into 150 mL of water and then extracted with dichloromethane (150 mL×3). The combined organic phases were washed twice with a saturated saline solution (100 mL×2). After removing the organic solvent by rotary evaporation, petroleum ether was used as the eluent to purify the crude product by silica gel column chromatography, and the intermediate 1-1-1-a was obtained in a total of 17.05 g with a yield of 78%.

1.2 Synthesis of Intermediate 1-1-1-b: The intermediate 1-1-1-a (17.05 g, 39 mmol), diphenylamine (6.6 g, 39 mmol), palladium acetate (0.2 g, 1 mmol), tritertbutylphosphine tetrafluoroborate (0.87 g, 3 mmol), sodium tert-butoxide (3.8 g, 40 mmol), and toluene (120 mL) were added to a 500 mL Schlenk flask, and the steps of vacuum pumping and introducing an argon gas were cycled for three times. The mixture was stirred for 12 hours at a temperature of 110° C. under argon protection. After cooling to a room temperature, the mixture was poured into 150 mL of water and extracted with dichloromethane (150 mL×3). The combined organic phases were washed twice with a saturated saline solution (100 mL×2). After removing the organic solvent by rotary evaporation, petroleum ether/dichloromethane (V/V=8/1) was used as the eluent, and the product was purified by silica gel column chromatography to obtain a total of 17.8 g of 1-1-1-b with a yield of 87%.

1.3 Synthesis of Intermediate 1-1-1-c: The intermediate 1-1-1-b (17.8 g, 34 mmol), phenol (7.5 g, 80 mmol), potassium tert-butoxide (9.0 g, 80 mmol), and N,N-dimethylformamide (100 mL) were added to a 250 mL round bottom flask, and the steps of vacuum pumping and introducing an argon gas were cycled for three times. The mixture was stirred for at 150° C. for 12 hours under argon atmosphere protection. After cooling to a room temperature, the mixture was poured into 150 mL of water and then extracted with dichloromethane (150 mL×3). The combined organic phases were washed twice with a saturated saline solution (100 mL×2). After removing the organic solvent by rotary evaporation, petroleum ether/dichloromethane (V/V=8/1) was used as the eluent to purify the crude product by silica gel column chromatography, yielding the intermediate 1-1-1-c in a total of 18.3 g with a yield of 80%.

1.4 Synthesis of target compound 1-1-1: The intermediate 1-1-1-c (13.5 g, 20 mmol) was added to a 500 mL Schlenk flask, and the steps of vacuum pumping and introducing an argon gas were cycled for three times. An ultra-dry o-dichlorobenzene (180 mL) was then added. Under argon protection, after cooling for 10 minutes under an ice bath condition, boron tribromide (3.9 mL, 40 mmol) was rapidly added and stirred under the ice bath condition until no more heat was released. The reaction was stirred for 48 hours upon raising a temperature to 120° C. After cooling to a room temperature, N,N-diisopropylethylamine (8 mL, 46 mmol) was added under the ice bath condition and stirred at room temperature until no more heat was released. The mixture was then heated to 100° C. under the dark condition and stirred at this temperature for 6 hours. After complete reaction, the resultant was cooled to a room temperature, the mixture was poured into 150 mL of water, and then extracted with dichloromethane (150 mL×3). The combined organic phases were washed twice with a saturated saline solution (100 mL×2). After removing the organic solvent by rotary evaporation, petroleum ether/dichloromethane (V/V=9/1) was used as the eluent, and the product was slowly purified by chromatography on a silica gel column to obtain the target compound 1-1-1 in a total of 4.83 g, with a reaction yield of 35%.

### Example 2

The synthesis route of the target compound 2-1-1 in the present Example is as follows:

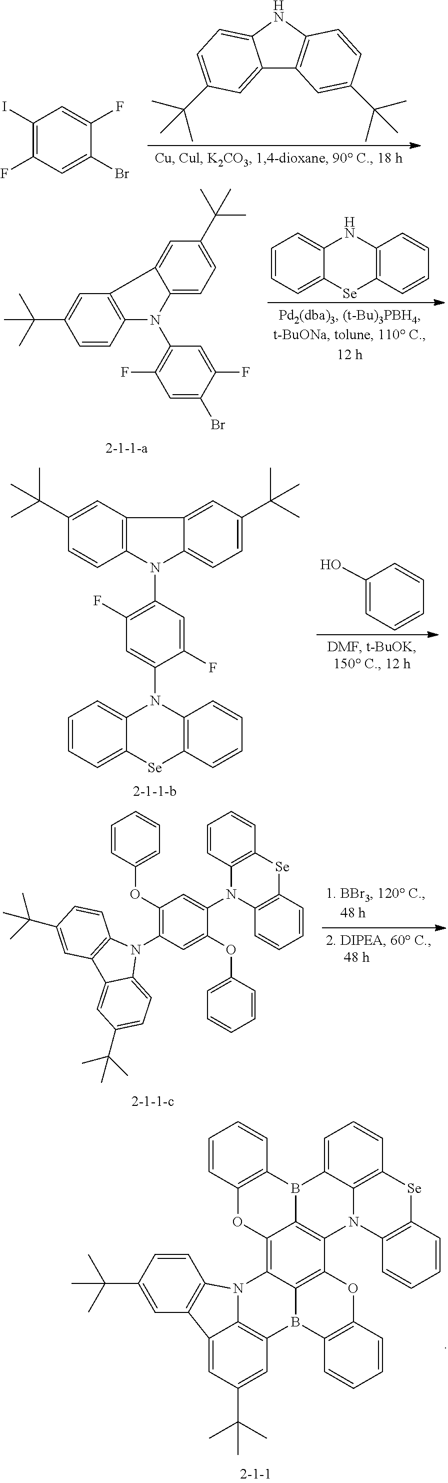

### Synthesis Steps:

2.1 Synthesis of Intermediate 2-1-1-a: 1-bromo-2,5-difluoro-4-iodobenzene (21.4 g, 55 mmol), 3,6-di-tert-butylcarbazole (14.0 g, 50 mmol), copper powder (0.32 g, 5 mmol), cuprous iodide (0.019 g, 1 mmol), potassium carbonate (8.3 g, 60 mmol), and 1,4-dioxane (150 mL) were added to a 500 mL round bottom flask, and the steps of vacuum pumping and introducing an argon gas were cycled for three times. The mixture was stirred at a temperature of 90° C. for 18 hours under argon atmosphere protection. After cooling to a room temperature, the mixture was poured into 150 ml of water and extracted with dichloromethane (150 mL×3). The combined organic phases were washed twice with a saturated saline solution (100 mL×2). After removing the organic solvent by rotary evaporation, petroleum ether was used as the eluent to purify the crude product by silica gel column chromatography, yielding a total of 20.5 g of the intermediate 2-1-1-a with a yield of 87%.

2.2 Synthesis of Intermediate 2-1-1-b: 2-1-1-a (20.5 g, 43.5 mmol), phenoselezine (10.8 g, 44 mmol), tris(dibenzylidene) acetone dipalladium (1.9 g, 2 mmol), tris(tertbutylphosphine) tetrafluoroborate (1.2 g, 4 mmol), sodium tert-butoxide (3.8 g, 40 mmol), and toluene (120 mL) were added to a 500 mL Schlenk flask, and the steps of vacuum pumping and introducing an argon gas were cycled for three times. The mixture was stirred for 12 hours at 110° C. under argon protection. After cooling to a room temperature, the mixture was poured into 150 ml of water and extracted with dichloromethane (150 mL×3). The combined organic phases were washed twice with a saturated saline solution (100 mL×2). After removing the organic solvent by rotary evaporation, petroleum ether/dichloromethane (V/V=10/1) was used as the eluent, and the product was purified by silica gel column chromatography to obtain intermediate 2-1-1-b with a total of 18.8 g with a yield of 68%.

2.3 Synthesis of Intermediate 2-1-1-c: The intermediate 2-1-1-b (18.4 g, 29 mmol), phenol (6.6 g, 70) mmol), potassium tert-butoxide (8.4 g, 75 mmol), and N,N-dimethylformamide (90) mL) were added to a 250 mL round bottom flask, and the steps of vacuum pumping and introducing an argon gas were cycled for three times, and then stirred at a temperature of 150° C. for 12 hours under argon atmosphere protection. After cooling to a room temperature, the mixture was poured into 150 mL of water and then extracted with dichloromethane (150 mL×3). The combined organic phases were washed twice with a saturated saline solution (100 mL×2). After removing the organic solvent by rotary evaporation, petroleum ether/dichloromethane (V/V=9/1) was used as the eluent to purify the crude product by silica gel column chromatography, obtaining the intermediate 2-1-1-c in a total of 17.3 g with a yield of 76%.

2.4 Synthesis of target compound 2-1-1: The intermediate 2-1-1-c (15.7 g, 20 mmol) was added to a 500 mL Schlenk flask, and the steps of vacuum pumping and introducing an argon gas were cycled for three times. An ultra-dry o-dichlorobenzene (180 mL) was then added. Under argon protection, after cooling in an ice bath for 10 minutes, boron tribromide (3.9 mL, 40 mmol) was rapidly add and stirred at 120° C. for 48 hours. After cooling to a room temperature, N,N-diisopropylethylamine (7 mL, 40 mmol) was added under an ice bath condition and stirred until no more heat was released. The mixture was heated to 60° C. under a dark condition and stirred at this temperature for 48 hours. After the reaction was completed, the resultant was cooled to a room temperature, the mixture was poured into 150 ml of water, and then extracted with dichloromethane (150 mL×3). The combined organic phases were washed twice with a saturated saline solution (100 mL×2). After removing the organic solvent by rotary evaporation, petroleum ether/dichloromethane (V/V=9/1) was used as the eluent, and the product was purified slowly by chromatography on a silica gel column to obtain a total of 4.3 g of the target compound 2-1-1, with a reaction yield of 27%.

### Example 3

The synthesis route of the target compound 1-1-2 in the present Example is as follows:

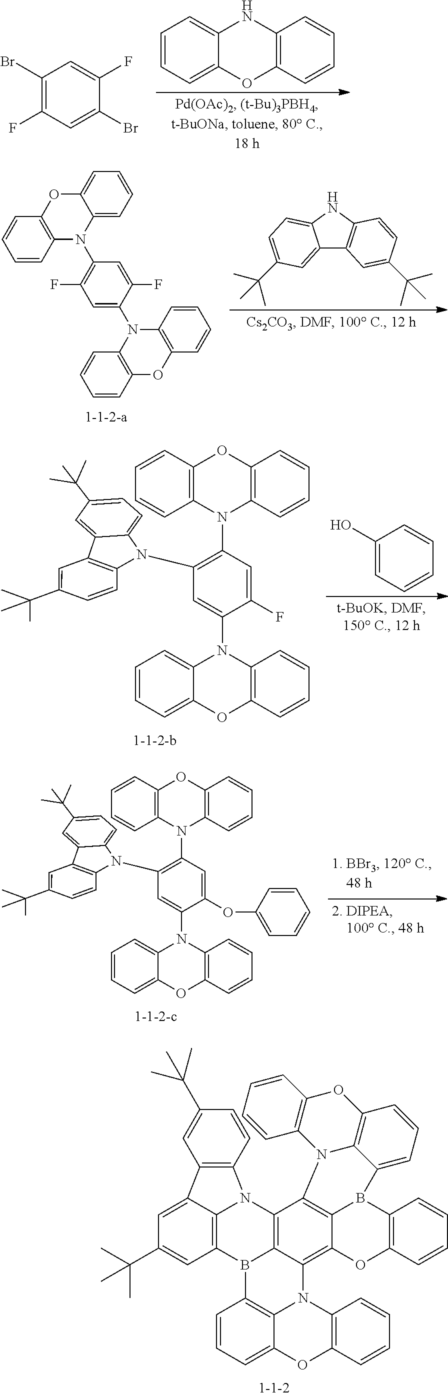

### a Synthesis Steps:

3.1 Synthesis of Intermediate 1-1-2-a: 1,4-dibromo-2,5-difluorobenzene (13.6 g, 50 mmol), phenoxazine (18.3 g, 100 mmol), palladium acetate (0.9 g, 4 mmol), tritertbutylphosphine tetrafluoroborate (3.5 g, 12 mmol), sodium tert-butoxide (14.4 g, 150 mmol), and toluene (150 mL) were added to a 500 mL round bottom flask, and the steps of vacuum pumping and introducing an argon gas were cycled for three times. The mixture was stirred at 80° C. for 18 hours under argon atmosphere protection. After cooling to a room temperature, the mixture was poured into 150 mL of water and then extracted with dichloromethane (150 mL×3). The combined organic phases were washed twice with a saturated saline solution (100 mL×2). After removing the organic solvent by rotary evaporation, petroleum ether was used as the eluent to purify the crude product by silica gel column chromatography. The intermediate 1-1-2-a was obtained in a total of 19.3 g with a yield of 81%.

3.2 Synthesis of Intermediate 1-1-2-b: 1-1-2-a (19.3 g, 40.5 mmol), 3,6-di-tert-butylcarbazole (11.5 g, 41 mmol), cesium carbonate (13.7 g, 42 mmol), and N,N-dimethylformamide (180) mL) were added to a 500 mL Schlenk flask, and the steps of vacuum pumping and introducing an argon gas were cycled for three times. The mixture was stirred for 12 hours at a temperature of 100° C. under argon protection. After cooling to a room temperature, the mixture was poured into 150 ml of water and then extracted with dichloromethane (150 mL×3). The combined organic phases were washed twice with a saturated saline solution (100 mL×2). After removing the organic solvent by rotary evaporation, petroleum ether/dichloromethane (V/V=6/1) was used as the eluent, and the product was purified by silica gel column chromatography to obtain the intermediate 1-1-2-b in a total of 24.4 g, with a yield of 82%.

3.3 Synthesis of Intermediate 1-1-2-c: The intermediate 1-1-2-b (24.3 g, 33 mmol), phenol (3.8 g, 40 mmol), potassium tert-butoxide (4.5 g, 40 mmol), and N,N-dimethylformamide (100 mL) were added to a 250 mL round bottom flask, the steps of vacuum pumping and introducing an argon gas were cycled for three times, and then stirred at 150° C. for 12 hours under argon atmosphere protection. After cooling to a room temperature, the mixture was poured into 150 mL of water and then extracted with dichloromethane (150 mL×3). The combined organic phases were washed twice with a saturated saline solution (100 mL×2). After removing the organic solvent by rotary evaporation, petroleum ether/dichloromethane (V/V=7/1) was used as the eluent to purify the crude product by silica gel column chromatography, obtaining the intermediate 1-1-2-c in a total of 20.8 g with a yield of 78%.

3.4 Synthesis of target compound 1-1-2: The intermediate 1-1-2-c (16.2 g, 20 mmol) was added to a 500 mL Schlenk flask, the steps of vacuum pumping and introducing an argon gas were cycled for three times, and an ultra-dry mesitylene (180 mL) was added. Under argon protection, the temperature of the mixture was deceased for 10 minutes under an ice bath condition, then boron tribromide (3.9 mL, 40 mmol) was rapidly added and stirred under an ice bath condition until no more heat was released. The reaction was stirred for 48 hours after raising a temperature to 120° C. After cooling to a room temperature, N,N-diisopropylethylamine (7 mL, 40 mmol) was added under an ice bath condition. The mixture was stirred at a room temperature for 3 hours until no more heat was released. The mixture was then heated to 100° C. under a dark condition and stirred at this temperature for 48 hours. After the reaction was completed, the resultant was cooled to a room temperature, the mixture was poured into 150 mL of water, and then extracted with dichloromethane (150 mL×3). The combined organic phases were washed twice with a saturated saline solution (100 mL×2). After removing the organic solvent by rotary evaporation, petroleum ether/dichloromethane (V/V=9/1) was used as the eluent, and the product was slowly purified by chromatography on a silica gel column to obtain the target compound 1-1-2 in a total of 4.1 g, with a yield of 25%.

### Example 4

The synthesis route of the target compound 3-3-2 in the present Example is as follows:

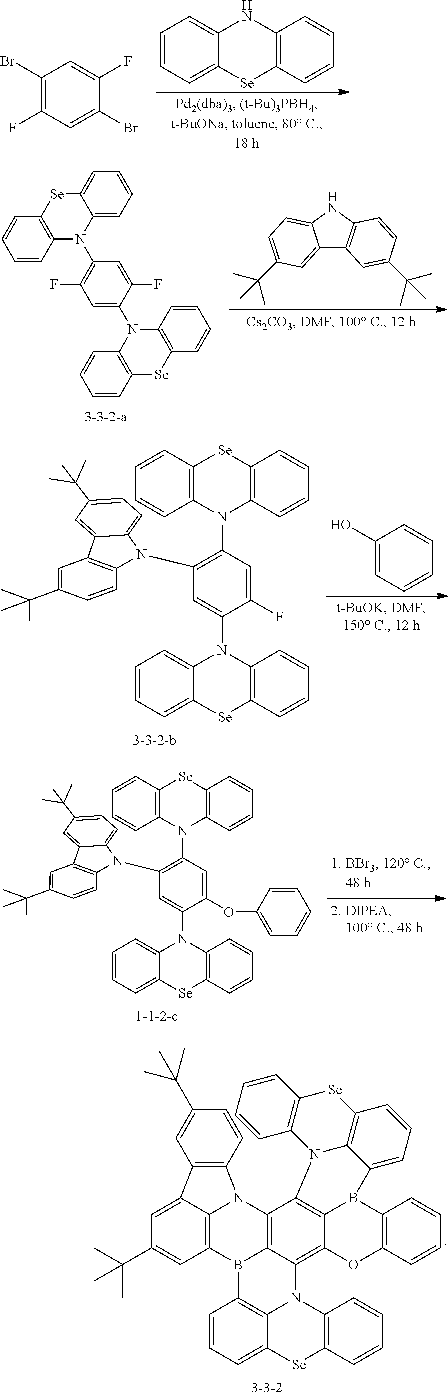

### Synthesis Steps:

In the synthesis process of the intermediate 1-1-2-a in Example 3, phenoxazine was replaced with phenoselezine (24.6 g, 100 mmol), and palladium acetate was replaced with tridiisopropylidene acetone dipalladium (3.8 g, 4 mmol). All other steps were the same as in Example 3, and the finally synthesized target compound 3-3-2 was 3.8 g in total with a yield of 8%.

### Example 5

The synthesis route of the target compound 1-1-3 in the present Example is as follows:

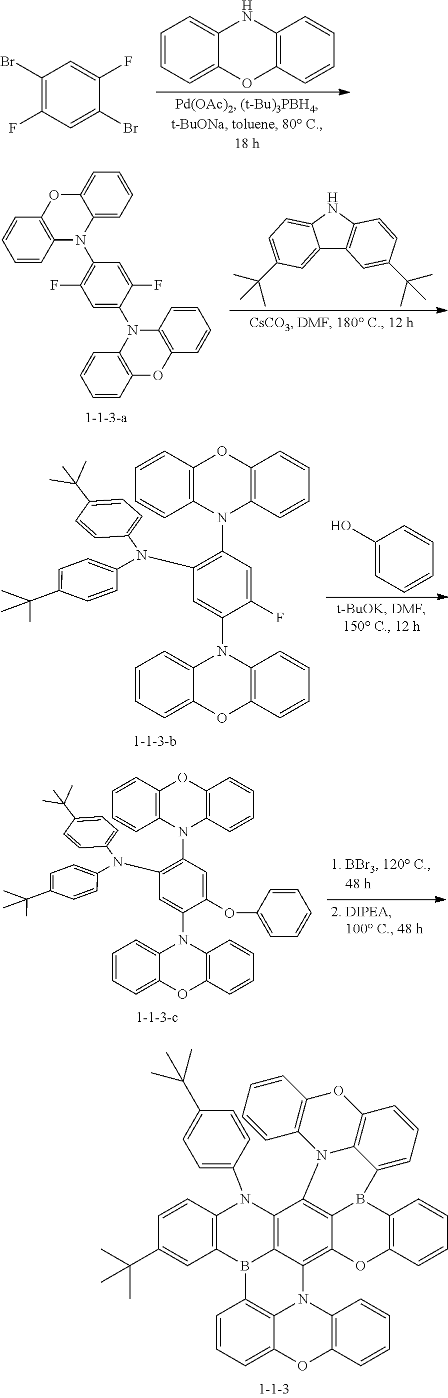

### Synthesis Steps:

In the synthesis process of intermediate 1-1-2-b in Example 3, tert-butylcarbazole was replaced with tert-butyldiphenylamine (25.1 g, 100 mmol) and the reaction temperature was raised to 180° C. All other steps were the same as in Example 3, and the finally synthesized target compound 1-1-3 was 2.0 g in total with a yield of 5%.

The mass spectrometry (MS) and elemental analysis (EA) results of the target compounds 1-1-1, 2-1-1, 1-1-2, 3-3-2, and 1-1-3 synthesized in Examples 1-7 are shown by Table 1.

TABLE 1

| | MS (EI) | | EA | |
|---|---|---|---|---|
| Target | Theoretical | Actual | Theoretical | Actual |
| Compound | Value | Value | Value (%) | Value (%) |
| 1-1-1 | 690.12 | 690.14 | C: 73.19, H: 3.51, | C: 73.15, H: 3.49, |
| | | | B: 3.14, N: 4.06, | B: 3.16, N: 4.08, |
| | | | O: 4.64, Se: 11.46 | O: 4.66, Se: 11.46 |
| 2-1-1 | 800.23 | 800.22 | C: 75.12, H: 4.79, | C: 75.09, H: 4.80, |
| | | | B: 2.70, N: 3.50, | B: 2.71, N: 3.51, |
| | | | O: 4.00, Se: 9.88 | O: 4.00, Se: 9.89 |
| 1-1-2 | 825.33 | 825.31 | C: 81.47, H: 5.01, | C: 81.47, H: 5.02, |
| | | | B: 2.62, N: 5.09, | B: 2.61, N: 5.11, |
| | | | O: 5.81 | O: 5.79 |
| 3-3-2 | 953.18 | 953.17 | C: 70.69, H: 4.34, | C: 70.65, H: 4.37, |
| | | | B: 2.27, N: 4.42, | B: 2.21, N: 4.40, |
| | | | O: 1.68, Se: 16.60 | O: 1.68, Se: 16.59 |
| 1-1-3 | 827.35 | 827.35 | C: 81.27, H: 5.24, | C: 81.26, H: 5.25, |
| | | | B: 2.61, N: 5.08, | B: 2.60, N: 5.09, |
| | | | O: 5.80 | O: 5.80 |

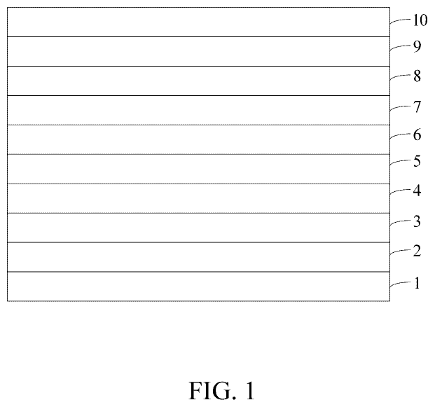

The performance of the electroluminescent device including the above-mentioned compounds will be tested through the specific Device Examples. And, the schematic diagram of the film stacking structure of the electroluminescent device is shown by FIG. 1, where 1-glass and conductive glass (ITO anode) substrate layer (commercially available); 2-Hole injection layer (HAT-CN, 5 nm); 3-First hole transport layer (TAPC, 30 nm); 4-Second hole transport layer (TCTA, 15 nm); 5-Electron blocking layer (mCBP, 10 nm); 6-Light-emitting layer (Compounds synthesized in the above Examples 1-5 of the present application or Compound A as represented by the following structure are deposited with DMIC-TRZ host and the phosphorescent sensitizer Ir (mphmq)₂ tmd at a ratio of 2:189:9, 20 nm); 7-First electron transport layer (POT2T, 20 nm); 8-Second electron transport layer (ANT-BIZ, 30 nm); 9-Electron injection layer (Liq, 2 nm); 10-Cathode (Al, 100 nm).

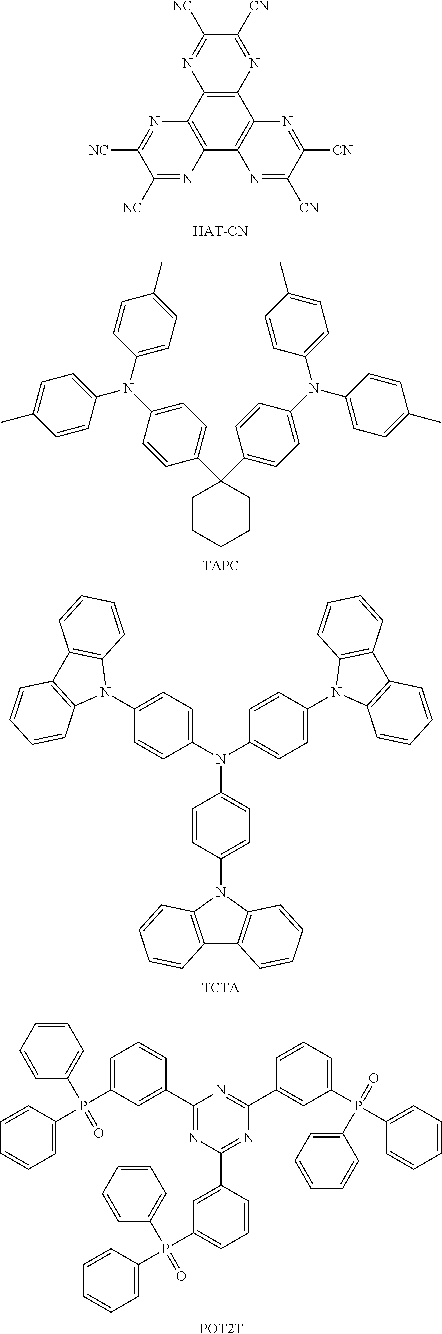

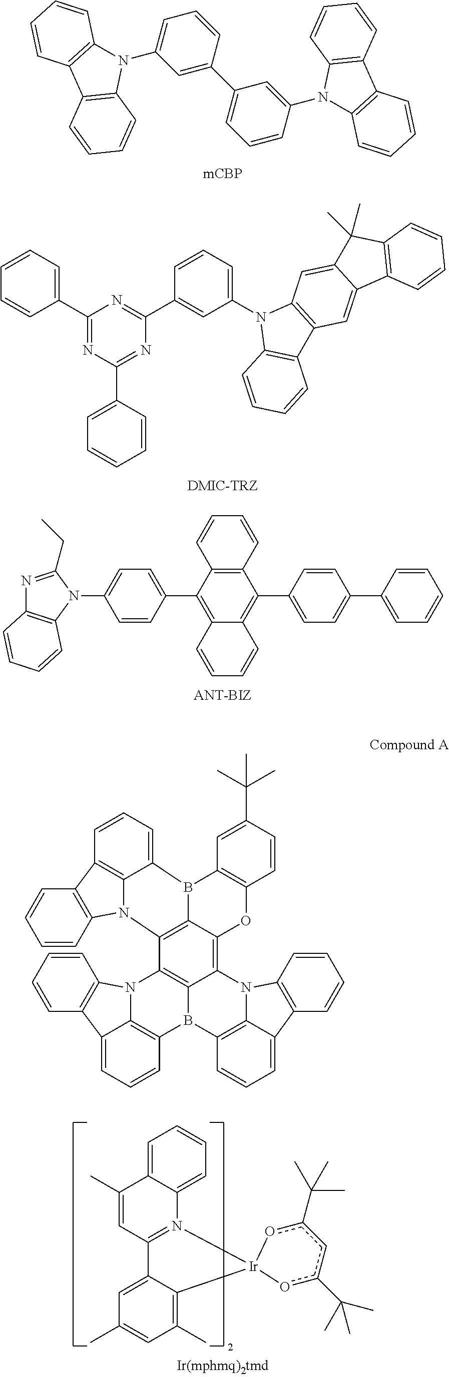

The above-mentioned electroluminescent devices may be fabricated using the known methods in the art, such as the method disclosed in reference (DOI: 10.1039/d3mh00800b). The specific method is to sequentially evaporate the hole injection layer, the hole transport layer, the light-emitting layer, the electron transport layer, the electron injection layer, and the cathode on a cleaned conductive glass (ITO) substrate under a high vacuum condition. The device shown by FIG. 1 was fabricated using this method. The luminescence characteristics of the prepared device was recorded at a current density of 10 mA/cm², as shown by Table 2. And, the preparation process and the structure of Device Comparative Example 1 and Device Examples 1-5 are the same, except that the materials of the light-emitting layers are different. The material of the light-emitting layer of OLED Ref is compound A, DMIC-TRZ host, and the phosphorescent sensitizer Ir (mphmq) 2tmd, with a ratio of 2:189:9; The material of the light-emitting layer of OLED-1 is Compound 1-1-1; The material of the light-emitting layer of OLED-2 is Compound 2-1-1; The material of the light-emitting layer of OLED-3 is Compound 1-1-2; The material of the light-emitting layer of OLED-4 is Compound 3-3-2; The material of the light-emitting layer of OLED-5 is Compound 1-1-3.

TABLE 2

| | Material | | | | |
|---|---|---|---|---|---|
| | of the | | | | |
| | light-emitting | | | EQE | LT95 |
| Device | layer | Voltage(V) | CIEx | (%) | (hr) |
| Device | Compound A: | 2.40 | 0.69 | 28 | 33 |
| Comparative | DMIC-TRZ:Ir(mphmq)₂tmd | | | | |
| Example 1 | | | | | |
| Device | Compound 1-1-1 | 2.74 | 0.66 | 34 | 34 |
| Example 1 | | | | | |
| Device | Compound 2-1-1 | 2.74 | 0.68 | 37 | 26 |
| Example 2 | | | | | |
| Device | Compound 1-1-2 | 2.32 | 0.70 | 33 | 71 |
| Example 3 | | | | | |
| Device | Compound 3-3-2 | 2.36 | 0.70 | 35 | 77 |
| Example 4 | | | | | |
| Device | Compound 1-1-3 | 2.40 | 0.69 | 34 | 80 |
| Example 5 | | | | | |

From Table 2, it may be seen that compared to the electroluminescent device prepared in Comparative Example 1, the external quantum efficiency (EQE) and lifetime of the electroluminescent devices prepared in Examples 1-5 of the present application have each been improved. The possible reason is that the embodiments of the present application have introduced different types of heteroatoms or heteroatom groups into the luminescent core of the boron-nitrogen compounds, which improves the luminescence efficiency of the material and reduces exciton dissipation. Meanwhile, the luminescent core plane of the boron-nitrogen compounds was modified with the weak electron donating groups or weak electron withdrawing groups such that the charge transfer characteristics were slightly adjusted to regulate the luminescence spectrum, which in turn improves the efficiency and lifetime of the electroluminescent devices and produces efficient red electroluminescent devices.

In the above embodiments, the description of each embodiment has its own emphasis. For the portions that are not detailed in certain embodiment, please refer to the relevant descriptions of other embodiments.

The above provides a detailed description of a boron-nitrogen compound, an electroluminescent device, and a display device provided in the embodiments of the present application. The above description is only intended to assist in understanding the technical solution and the core idea of the present application: an ordinary skilled in the art may modify or equivalently replace some of the technical features described in the aforementioned embodiments, without departing the essence of the corresponding technical solutions from the scope of the technical solutions of the embodiments of the present application.

What is claimed is:

1. A boron-nitrogen compound, wherein the boron-nitrogen compound has a structural general formula represented by formula (I): 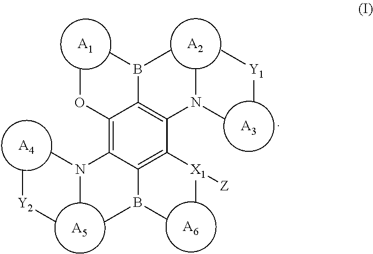
wherein, X₁ is selected from O or N;
when X₁ is selected from O, Z is selected from non-bonding, and one of Y₁ and Y₂ is selected from —O—, —S—, —Se—, —Te—, —C—C—, —C═C—, 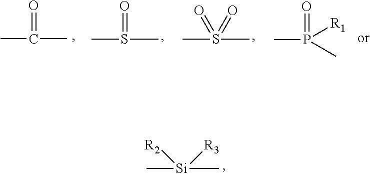
the other is selected from non-bonding, a single bond, —O—, —S—, —Se—, —Te—, —C—C—, —C═C—, 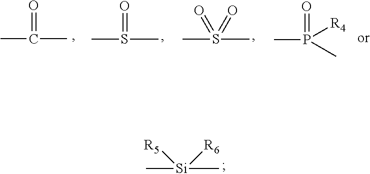
when X₁ is selected from N, Z is selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50, one of Y₁ and Y₂ is selected from —O—, —S—, —Se—, —Te—, —C—C—, —C═C—, 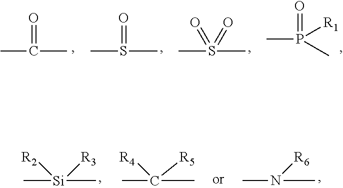
the other is selected from non-bonding, a single bond, —O—, —S—, —Se—, —Te—, —C—C—, —C═C—, 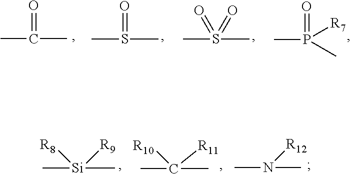
Z and A₆ form a ring or do not form a ring;
R₁ to R₁₂ are each independently selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50;
A₁ to A₆ are each independently selected from an aromatic group or a heterocyclic group having a carbon atom number ranging from 4 to 50, which is unsubstituted or substituted with deuterium, tritium, halogen, an alkyl group having a carbon atom number ranging from 1 to 50, or an alkoxy group having a carbon atom number ranging from 1 to 50.

2. The boron-nitrogen compound according to claim 1, wherein the aromatic group or the heterocyclic group has a carbon atom number of 4-30.

3. The boron-nitrogen compound according to claim 1, wherein the aromatic group or the heterocyclic group, for each occurrence, is independently selected from one of the following structural formulas 1-38: 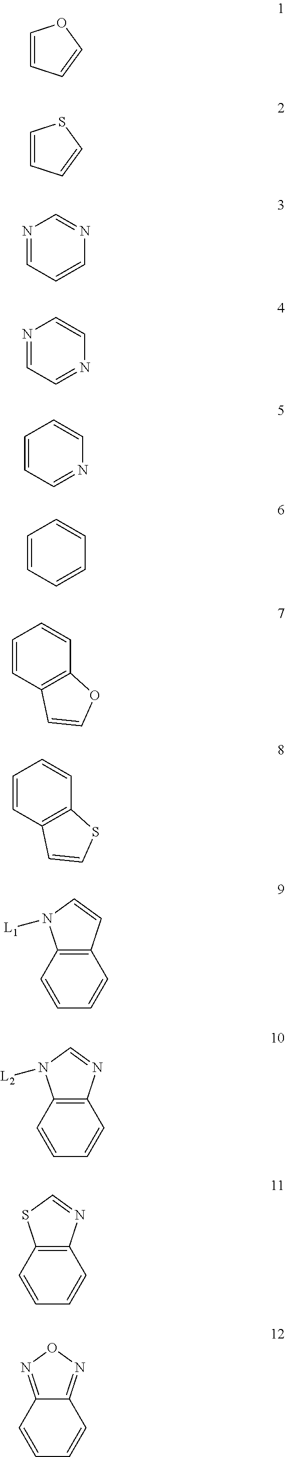 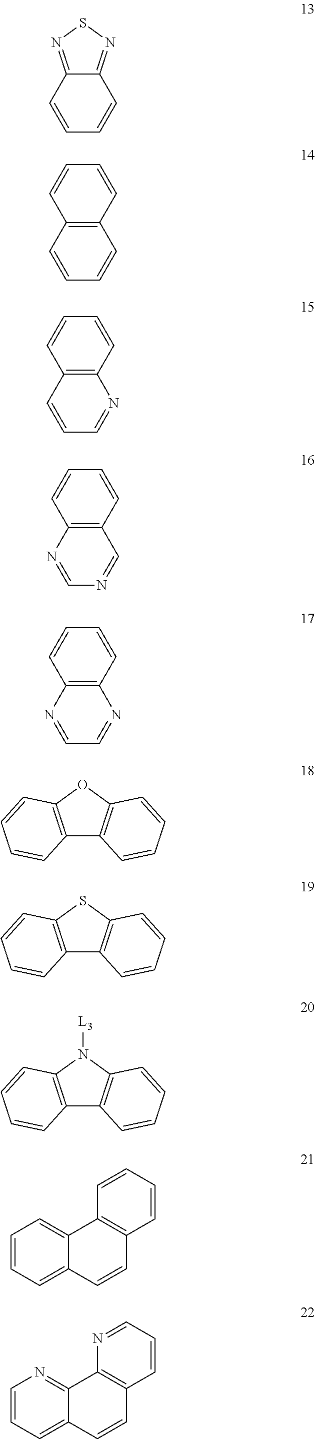 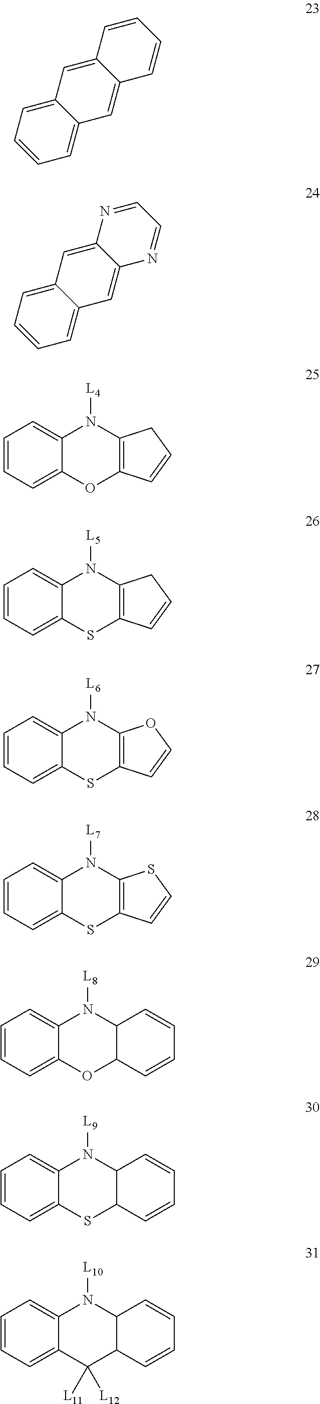 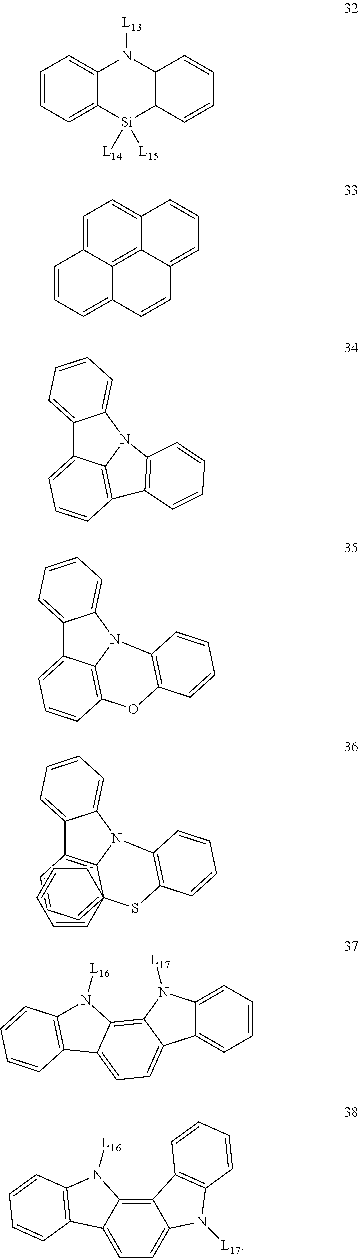
wherein, L₁ to L₁₉ are each independently selected from a linear or branched alkyl group having a carbon atom number ranging from 1 to 50, which is unsubstituted or substituted with deuterium, tritium, halogen, an alkyl group having a carbon atom number ranging from 1 to 50 or an alkoxy group having a carbon atom number ranging from 1 to 50, or an aromatic group or a heterocyclic group having a carbon atom number ranging from 4 to 50, which is unsubstituted or substituted with deuterium, tritium, halogen, an alkyl group having a carbon atom number ranging from 1 to 50 or an alkoxy group having a carbon atom number ranging from 1 to 50;
L₁ to L₁₉ form a ring or do not form a ring between each other.

4. The boron-nitrogen compound according to claim 2, wherein A₁ to A₆ are each independently selected from one of the following groups: 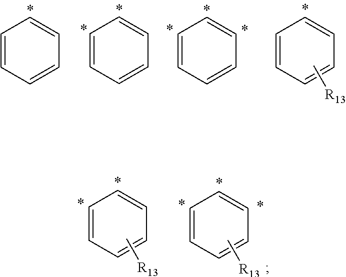
wherein, R₁₃ is selected from tert-butyl;
“*” represents a connection site.

5. The boron-nitrogen compound according to claim 4, wherein,
X₁ is selected from O;
Z is selected from non-bonding;
Y₁ is selected from —O—, —S—, —Se—, —Te—, —C—C—, —C═C—, 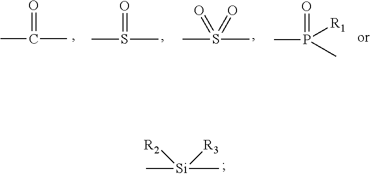
Y₂ is selected from non-bonding, a single bond, —O—, —S—, —Se—, —Te—, —C—C—, —C═C—, 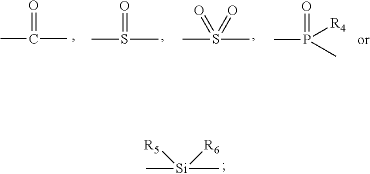
R₁-R₆ are selected from a phenyl group.

6. The boron-nitrogen compound according to claim 5, wherein, the boron-nitrogen compound is selected from one of compounds represented by formulas 1-1-1 to 13-9-1:

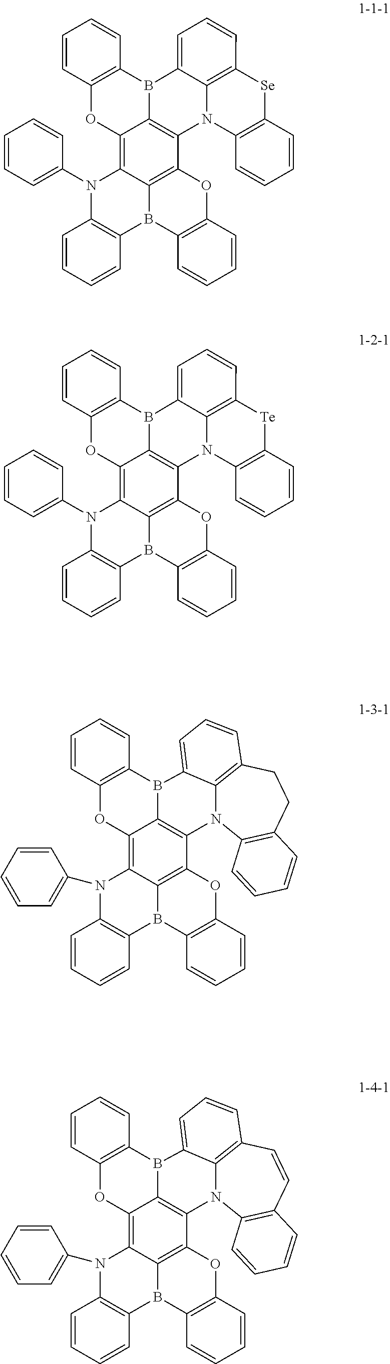

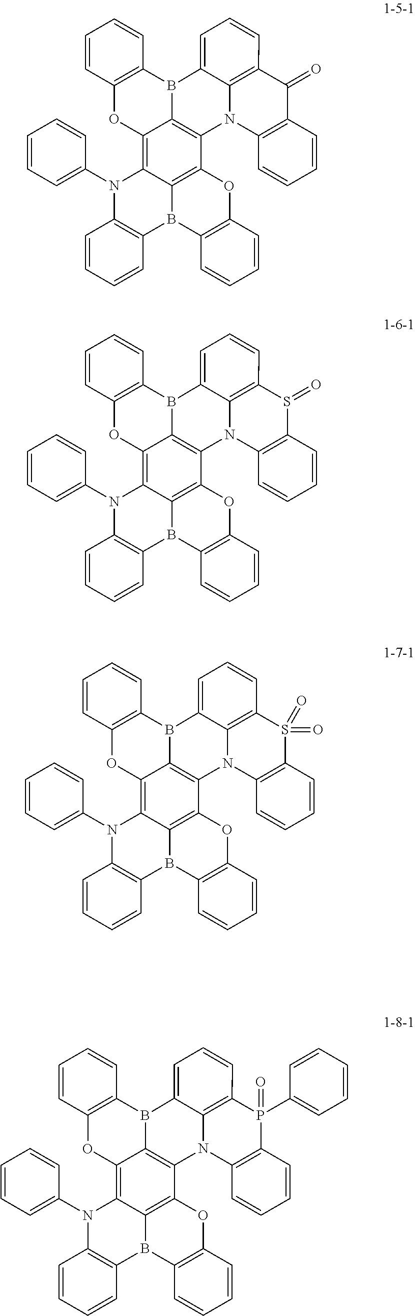 [SMILES: O=c1c2ccccc2n2c3c(cccc13)B1c3ccccc3Oc3c1c-2c1c2c3N(c3ccccc3)c3ccccc3B2c2ccccc2O1 ; O=S1c2ccccc2N2c3c(cccc31)B1c3ccccc3Oc3c1c2c1c2c3N(c3ccccc3)c3ccccc3B2c2ccccc2O1 ; O=S1(=O)c2ccccc2N2c3c(cccc31)B1c3ccccc3Oc3c1c2c1c2c3N(c3ccccc3)c3ccccc3B2c2ccccc2O1 ; O=P1(c2ccccc2)c2ccccc2N2c3c(cccc31)B1c3ccccc3Oc3c1c2c1c2c3N(c3ccccc3)c3ccccc3B2c2ccccc2O1]

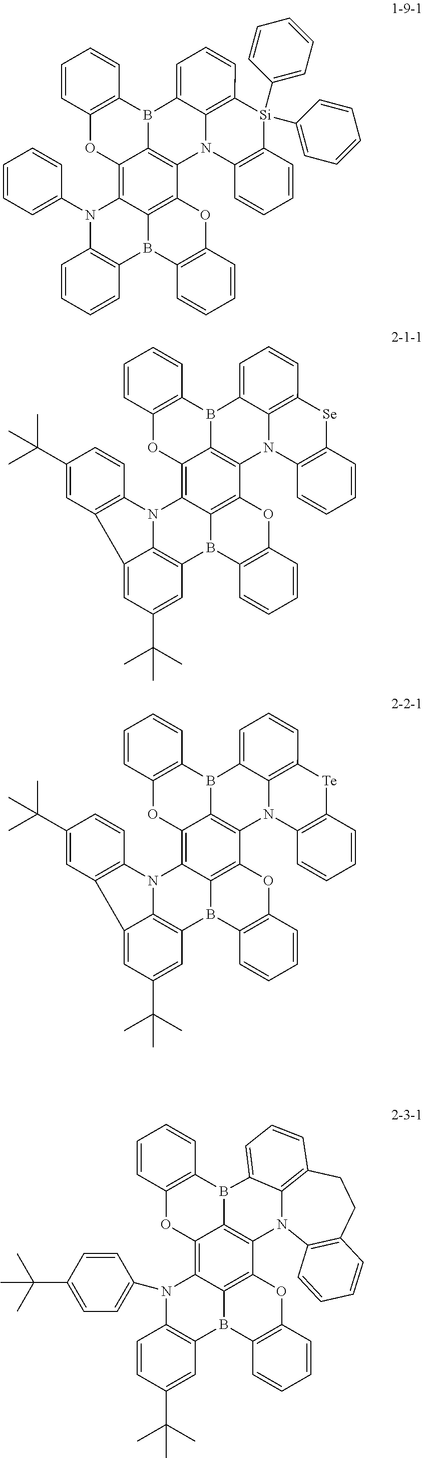

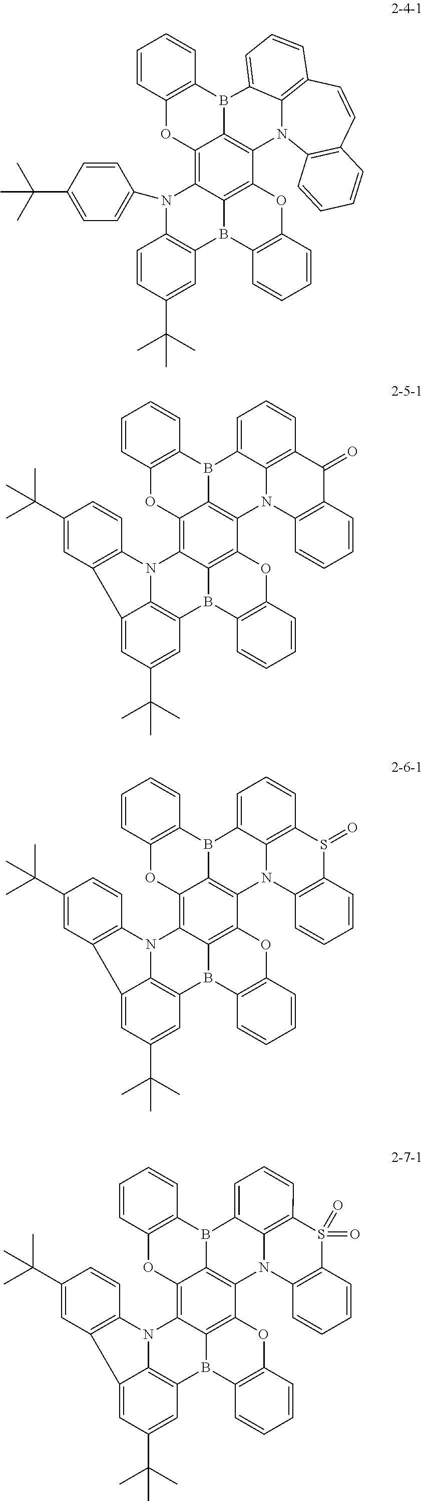

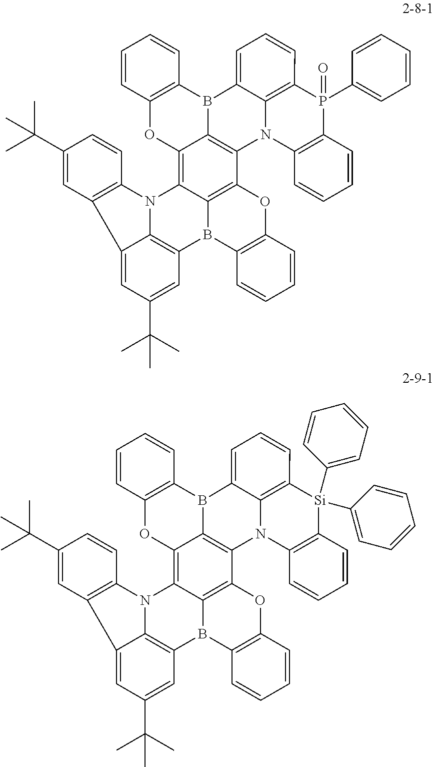 [SMILES: CC(C)(C)c1ccc2c(c1)c1cc(C(C)(C)C)cc3c1n2-c1c2c4c(c5c1B3c1ccccc1O5)N1c3ccccc3P(=O)(c3ccccc3)c3cccc(c31)B4c1ccccc1O2 ; CC(C)(C)c1ccc2c(c1)c1cc(C(C)(C)C)cc3c1n2-c1c2c4c(c5c1B3c1ccccc1O5)N1c3ccccc3[Si](c3ccccc3)(c3ccccc3)c3cccc(c31)B4c1ccccc1O2]

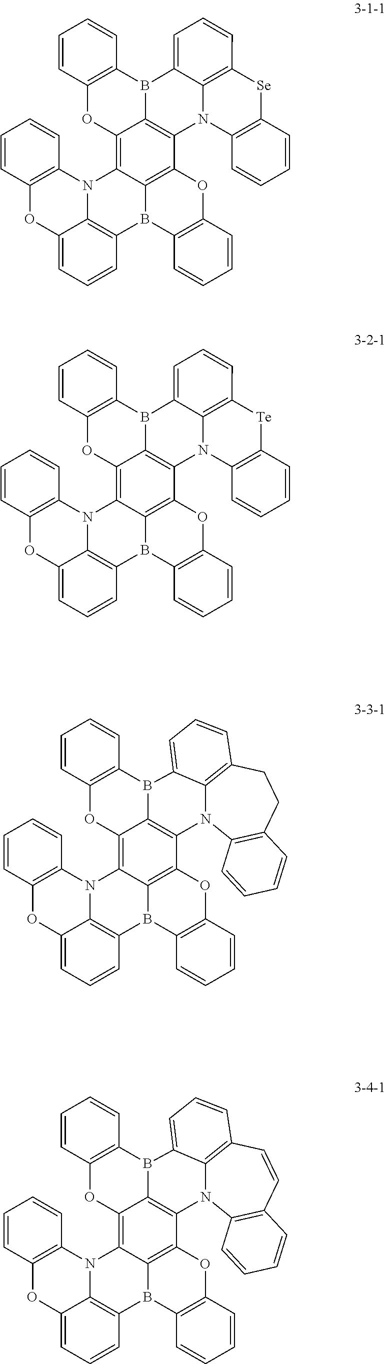

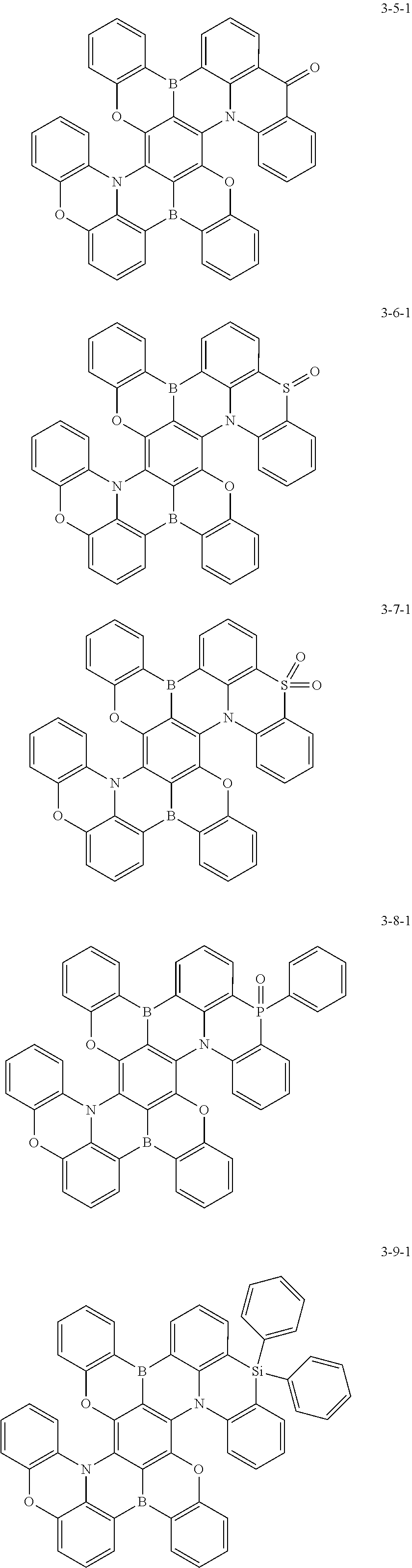

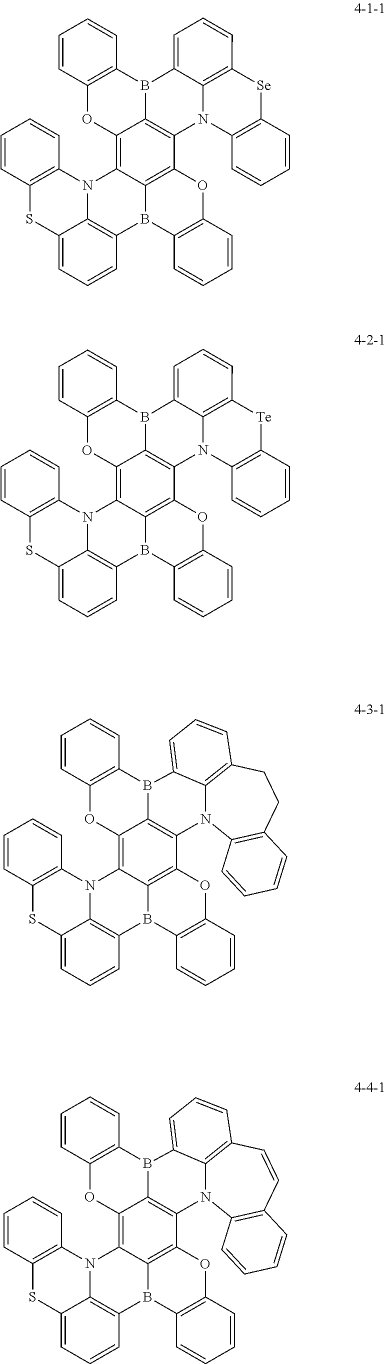

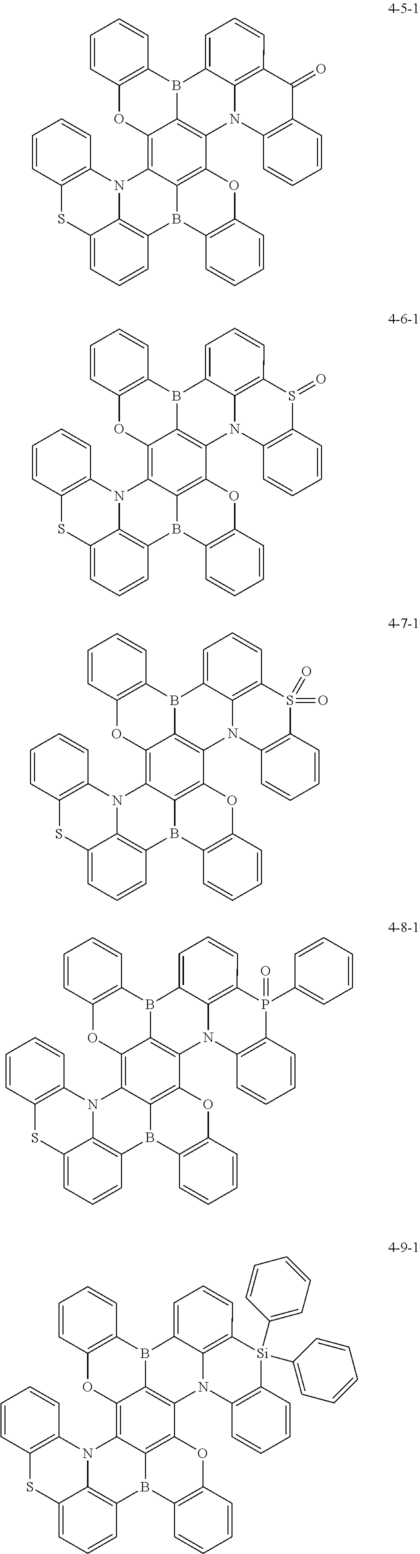

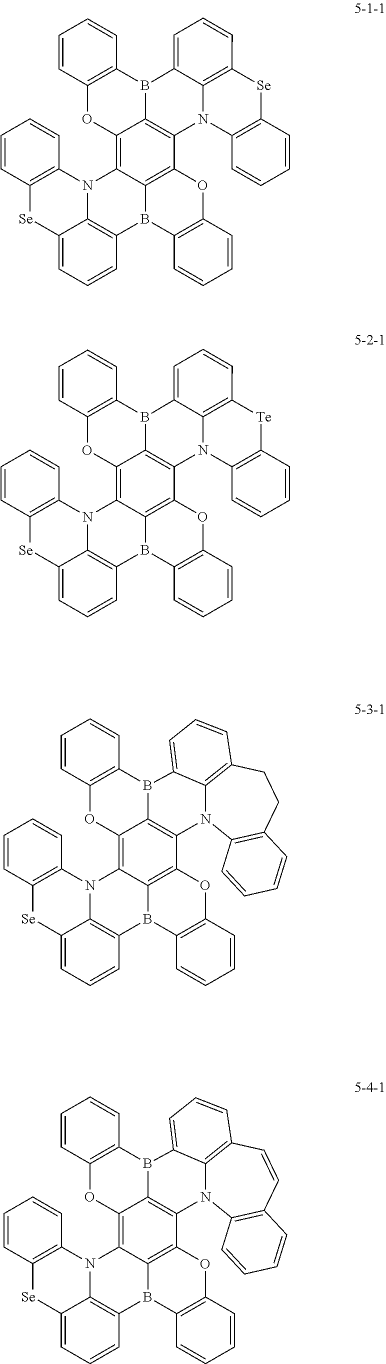

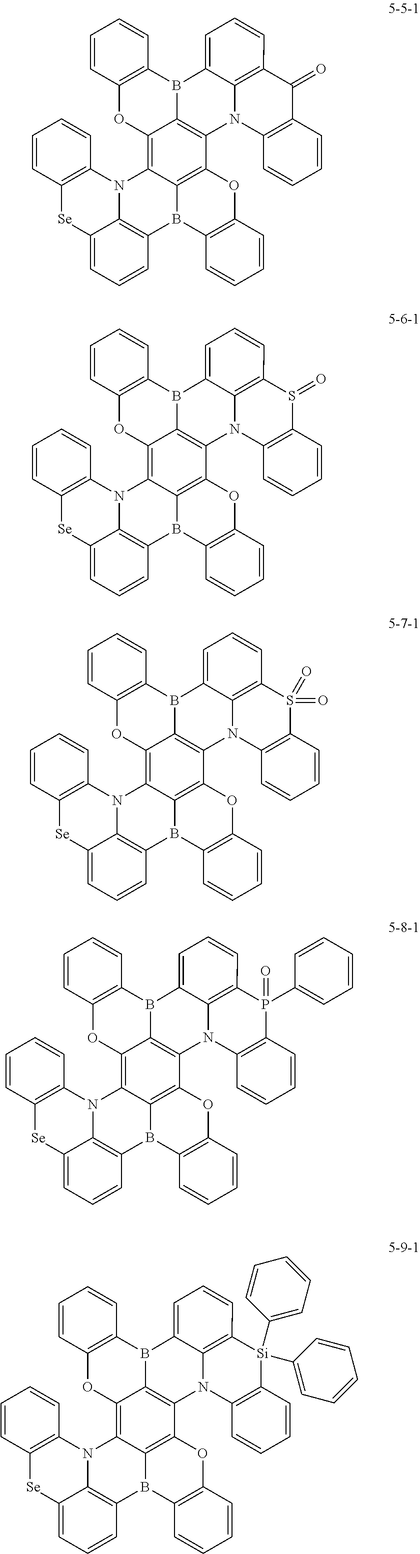

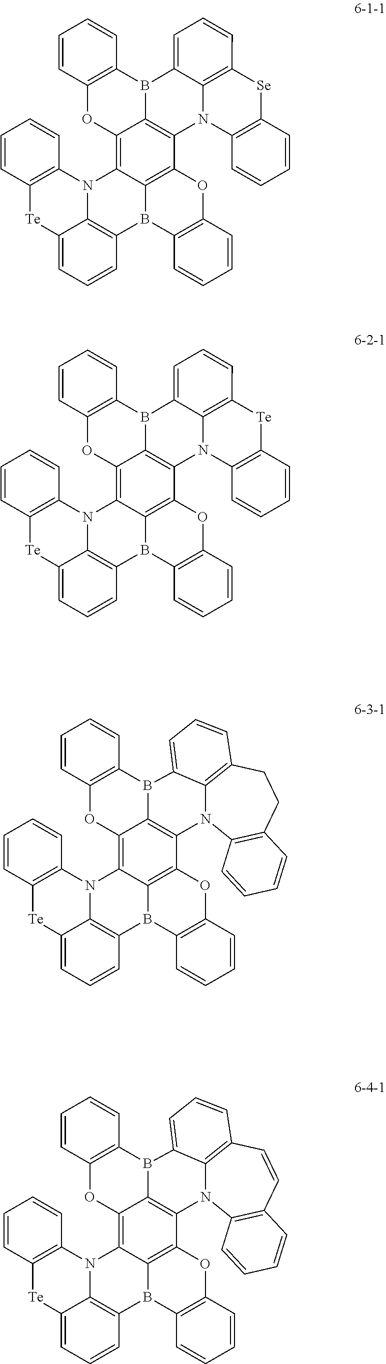

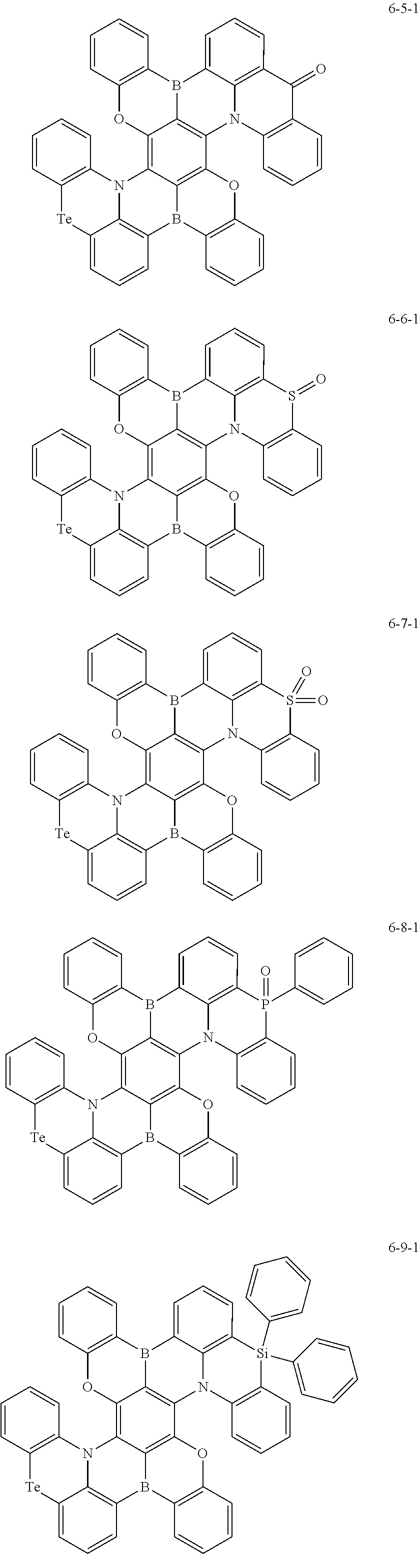

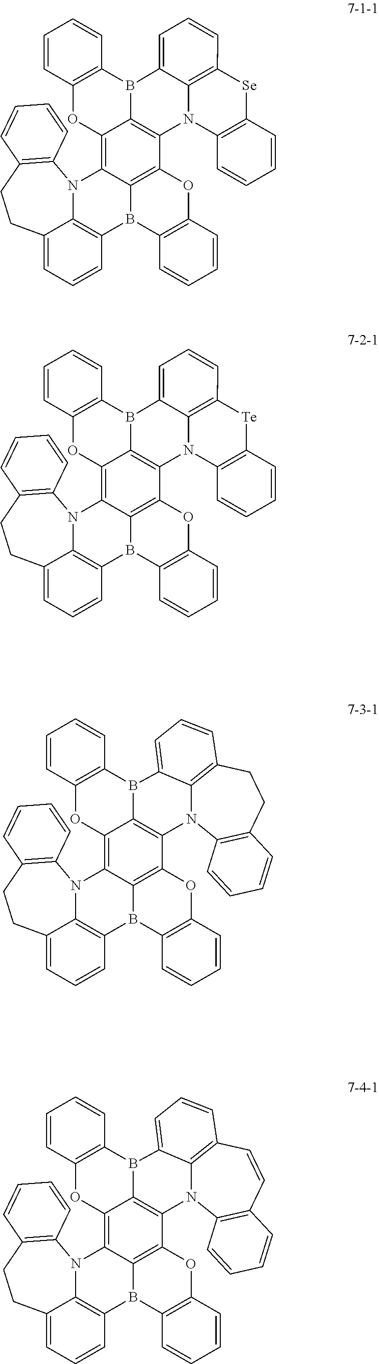

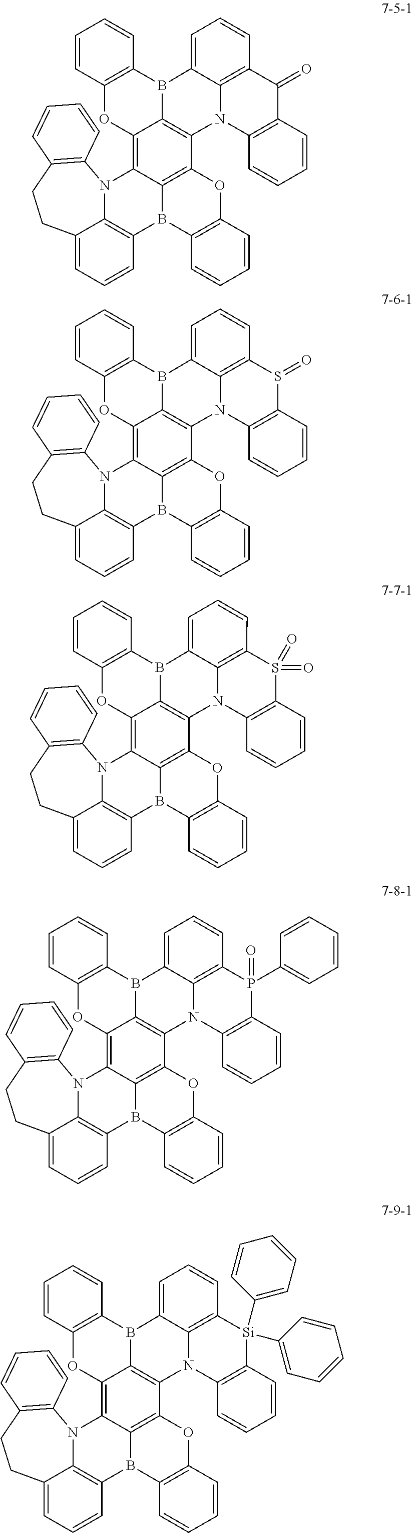

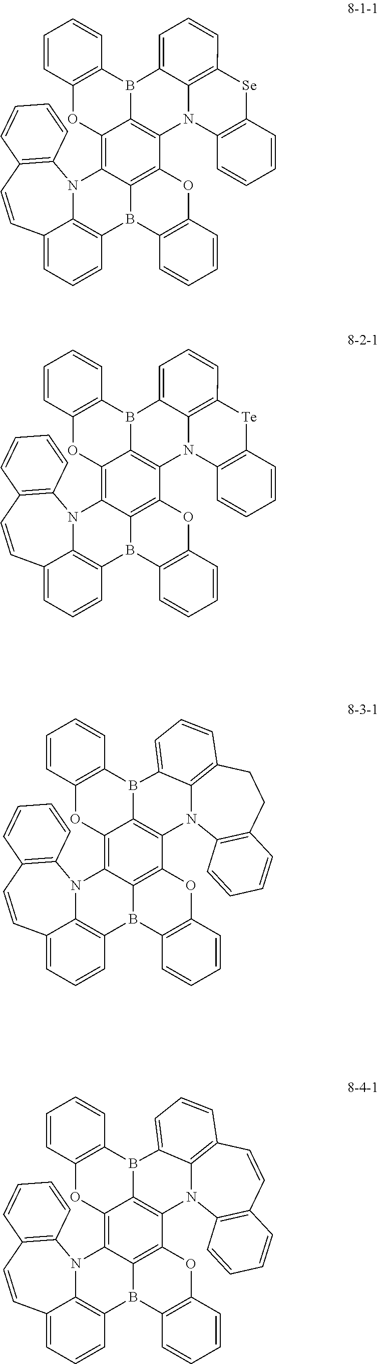

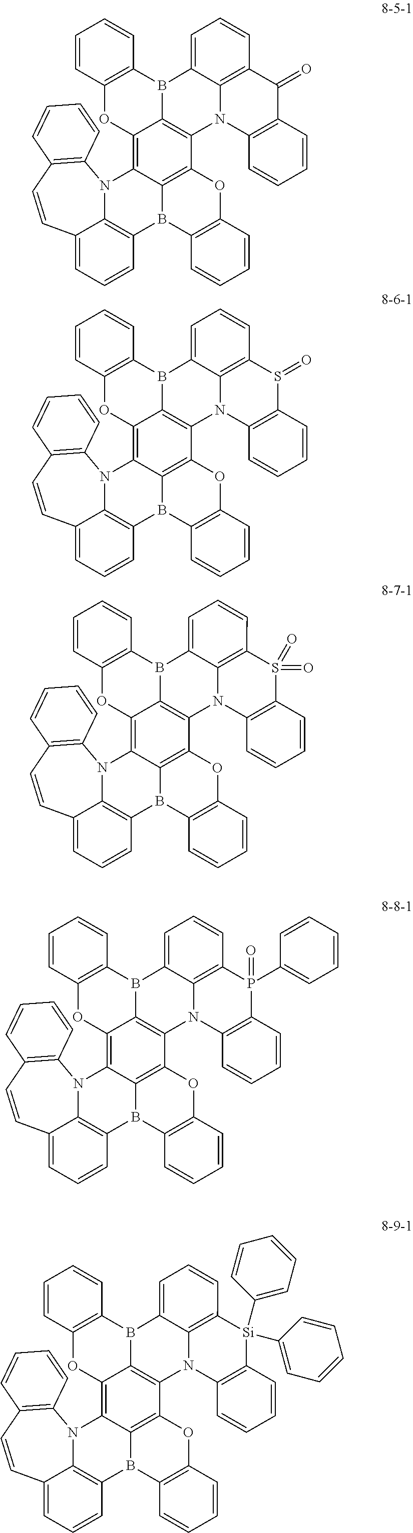

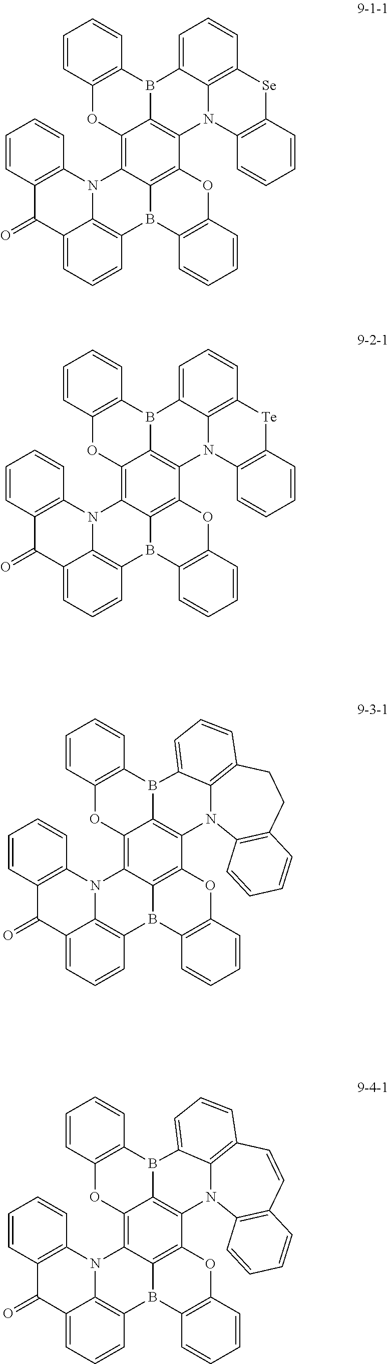

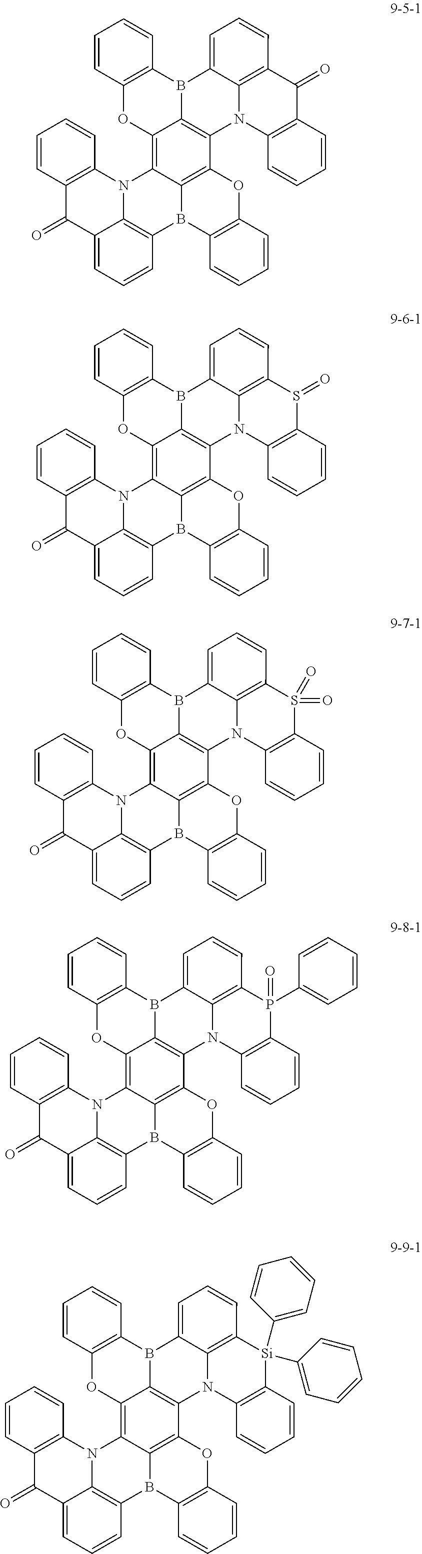

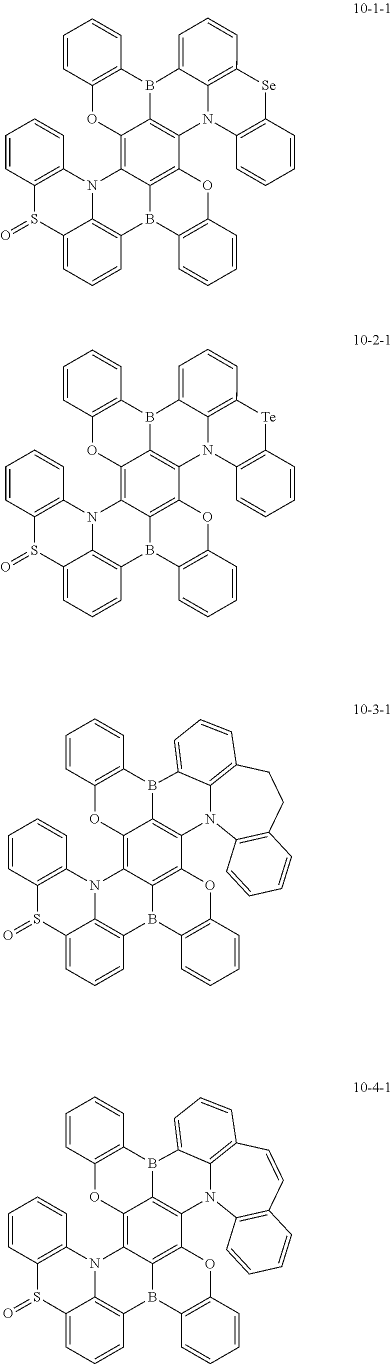

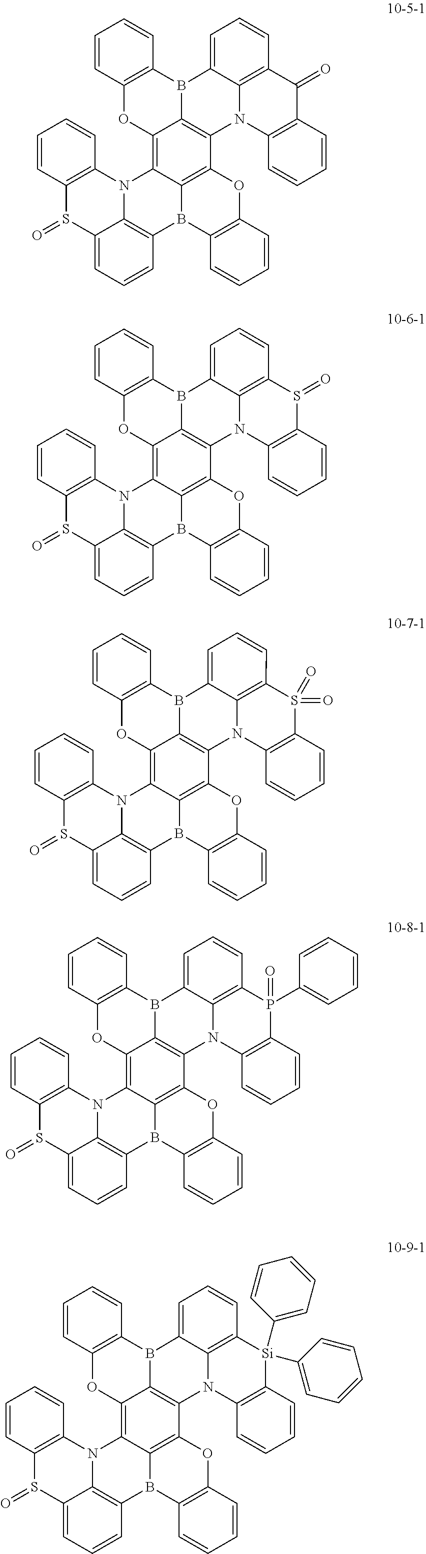

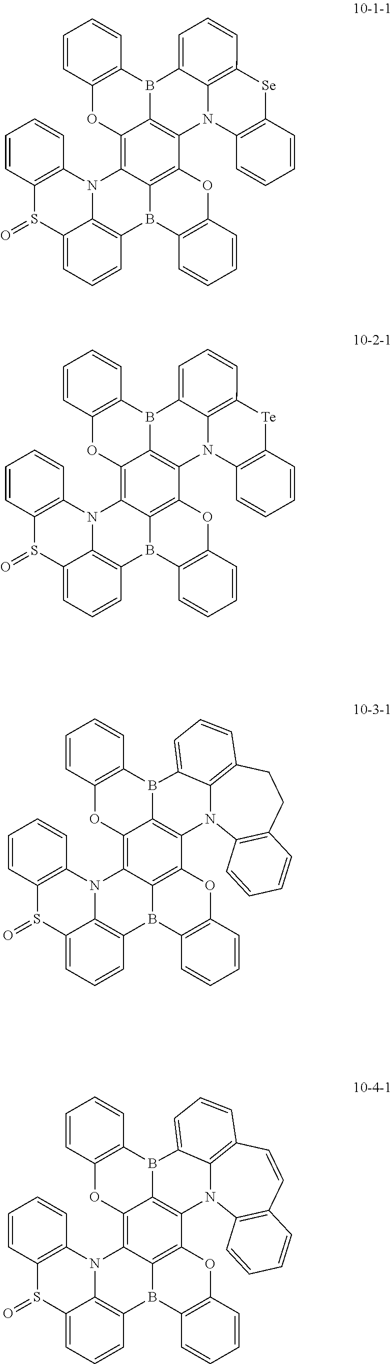

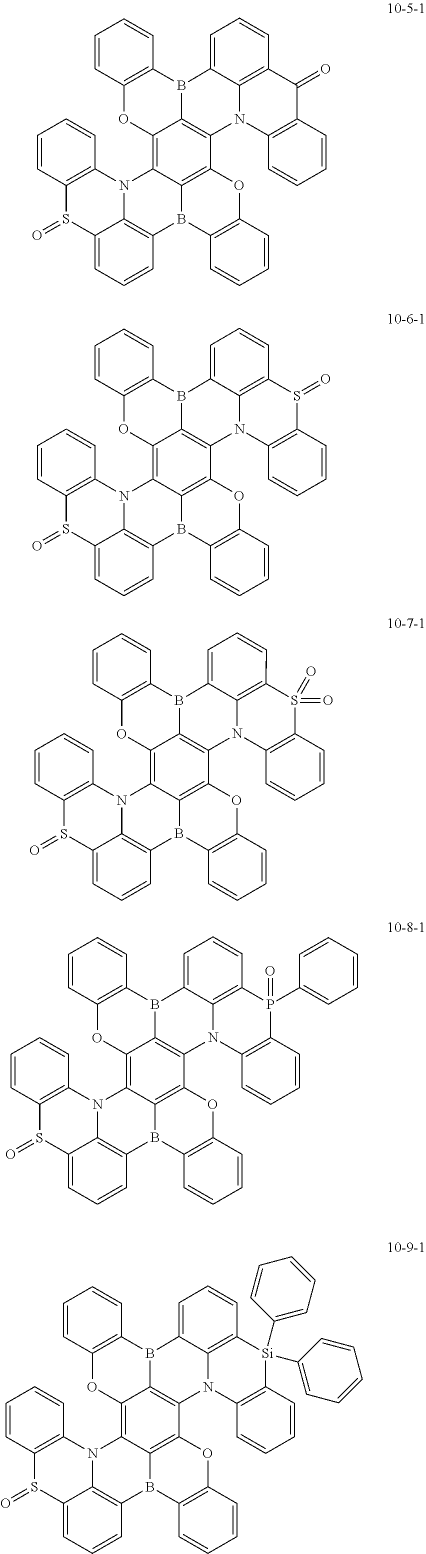

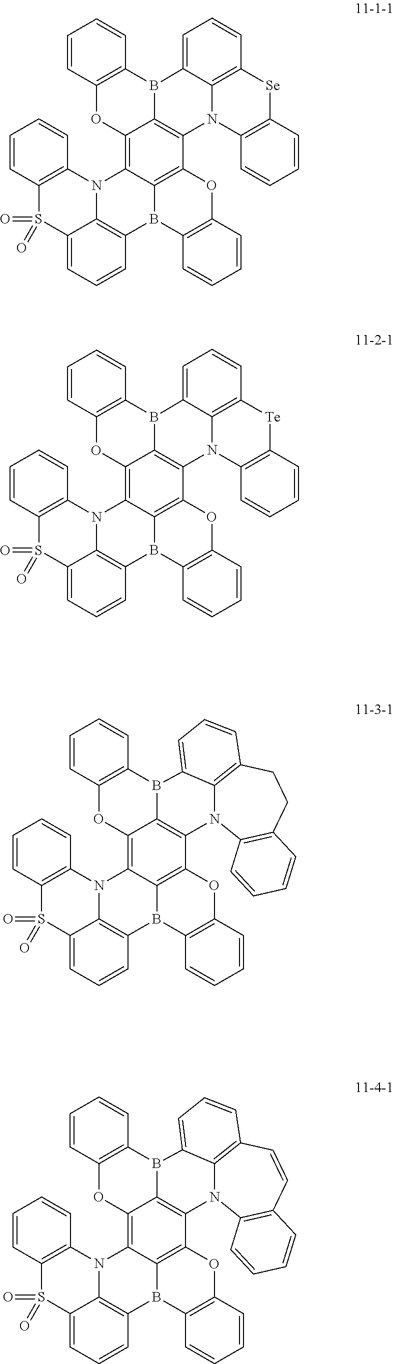

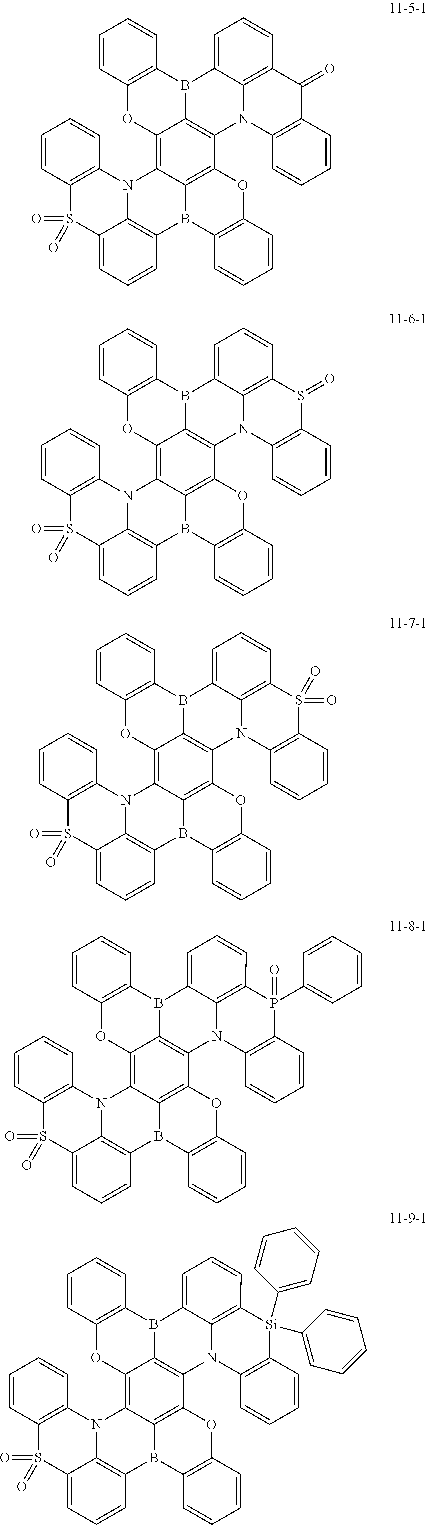

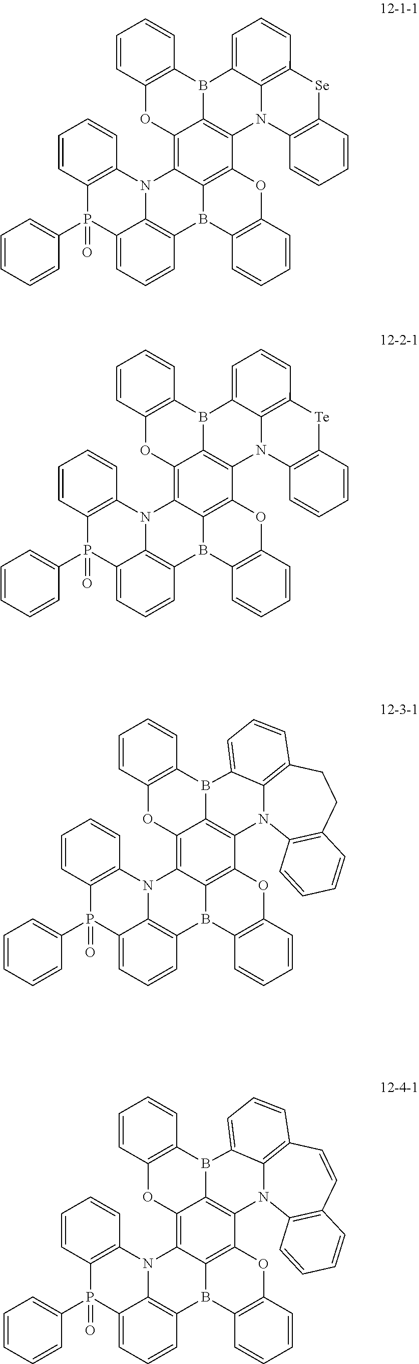

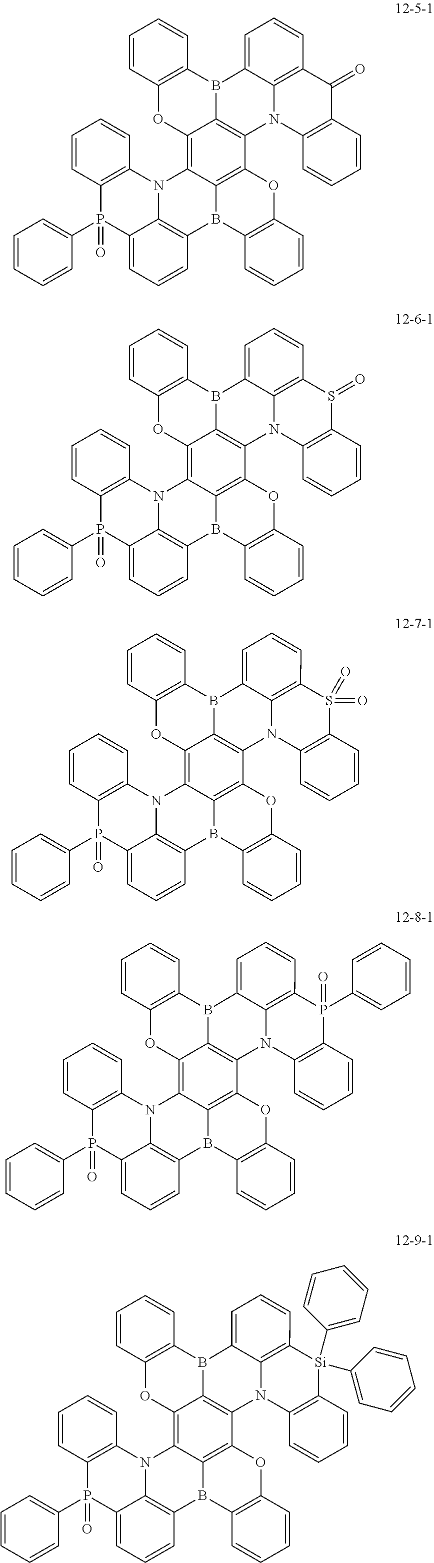

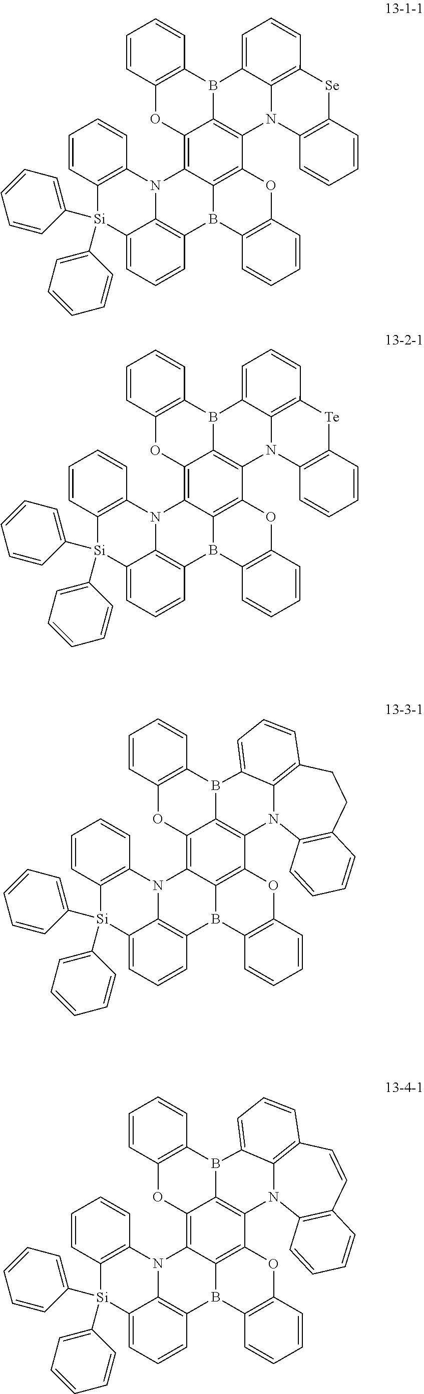

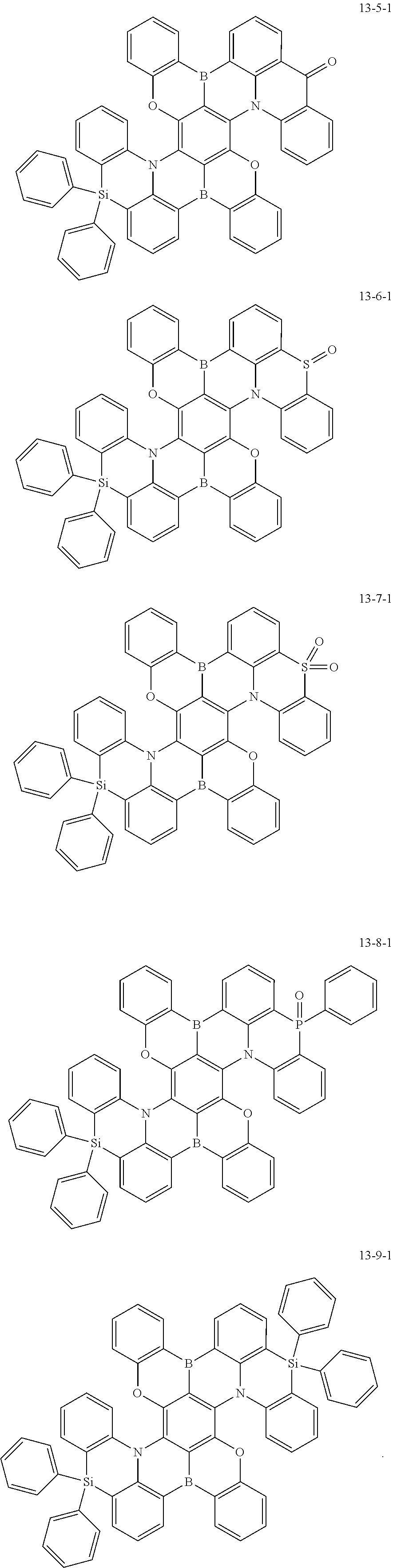

7. The boron-nitrogen compound according to claim 4, wherein,
X₁ is selected from N;
Z is selected from p-tert-butylphenyl;
Y₁ and Y₂ are independently selected from —O—, —S—, —Se—, —Te—;
Z and A₆ form a ring or do not form a ring.

8. The boron-nitrogen compound according to claim 7, wherein the boron-nitrogen compound is selected from one of compounds represented by formulas 1-1-2 to 4-4-2 and 1-1-3 to 4-4-3:

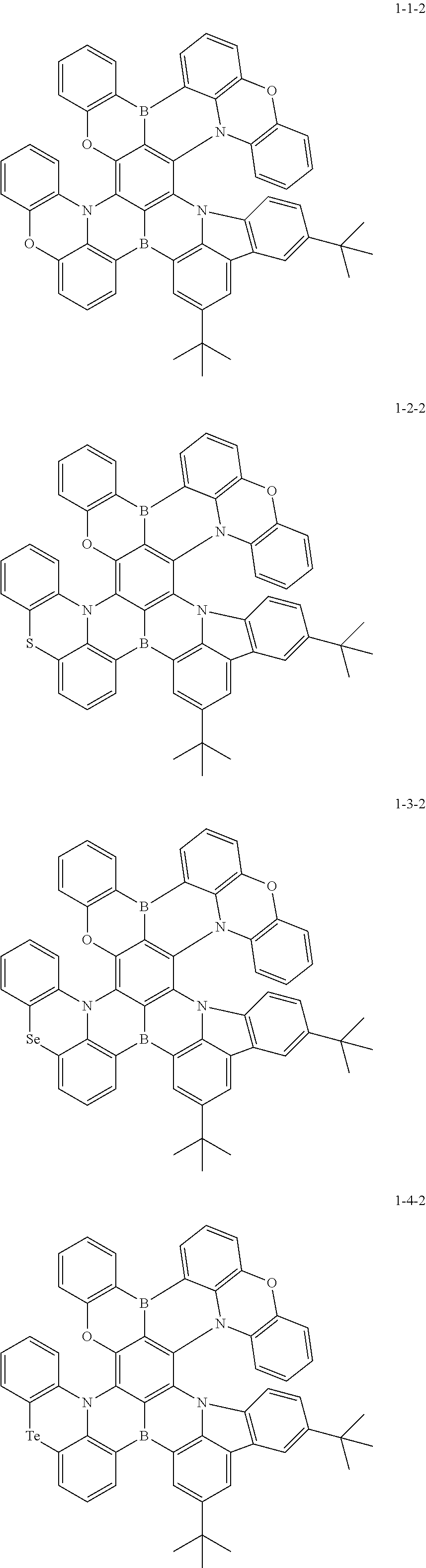

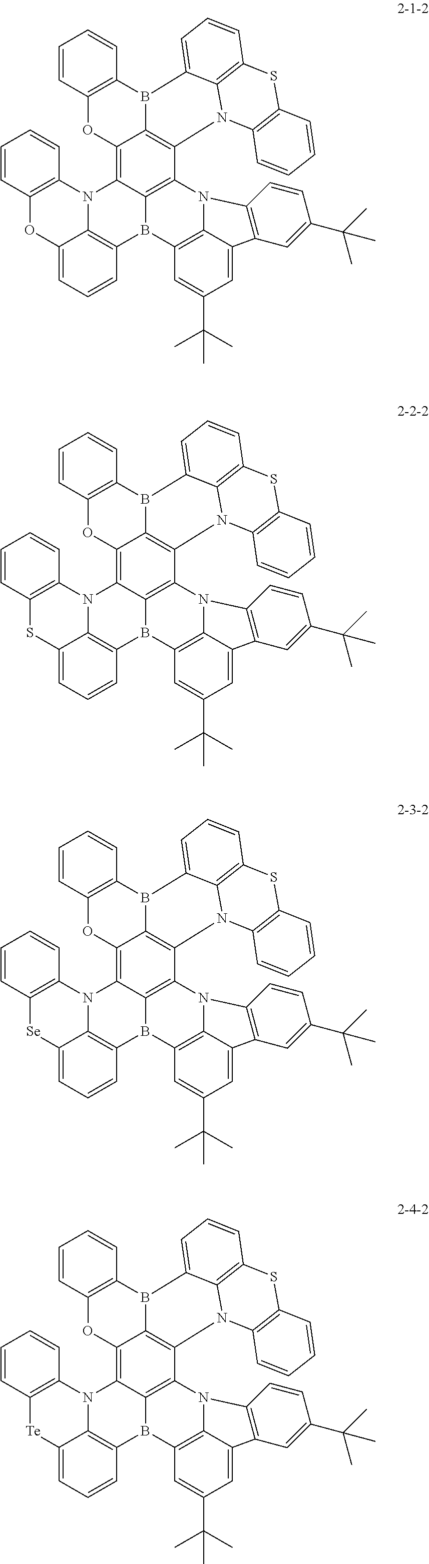

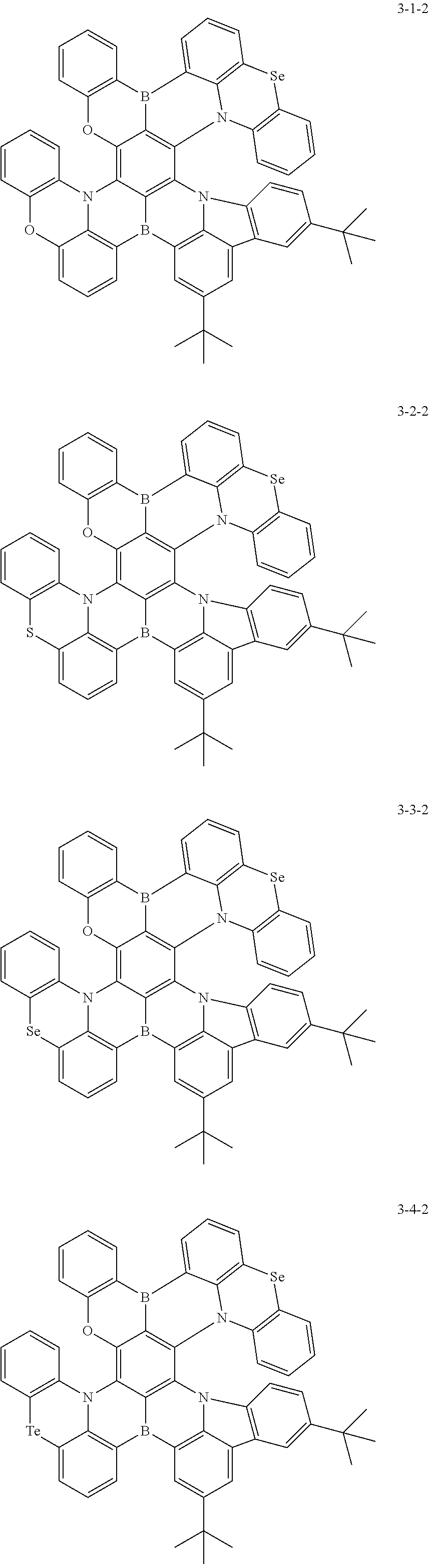

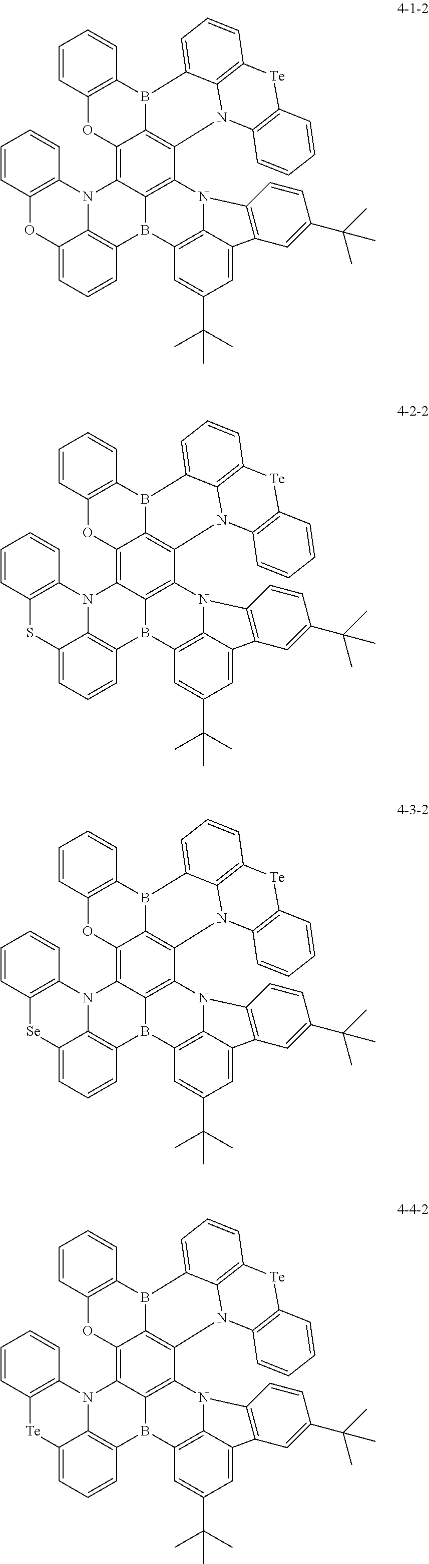

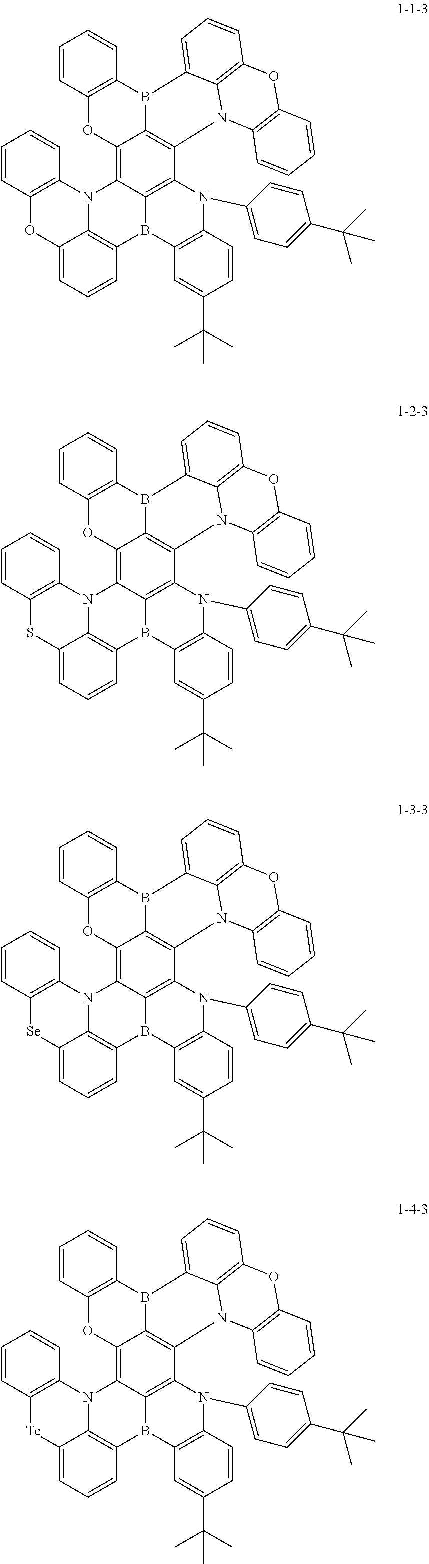

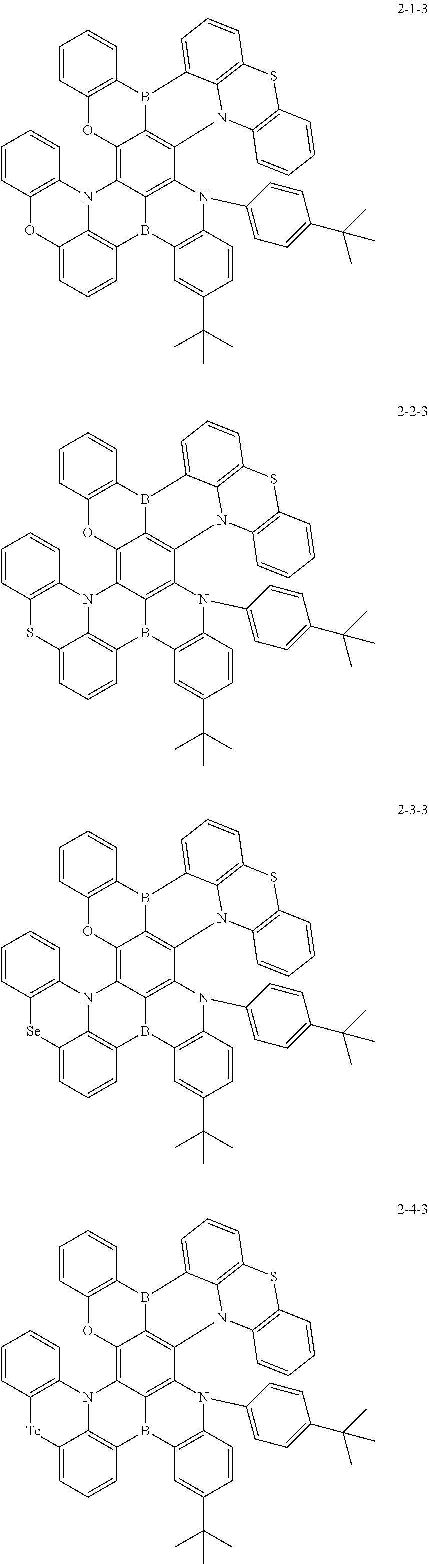

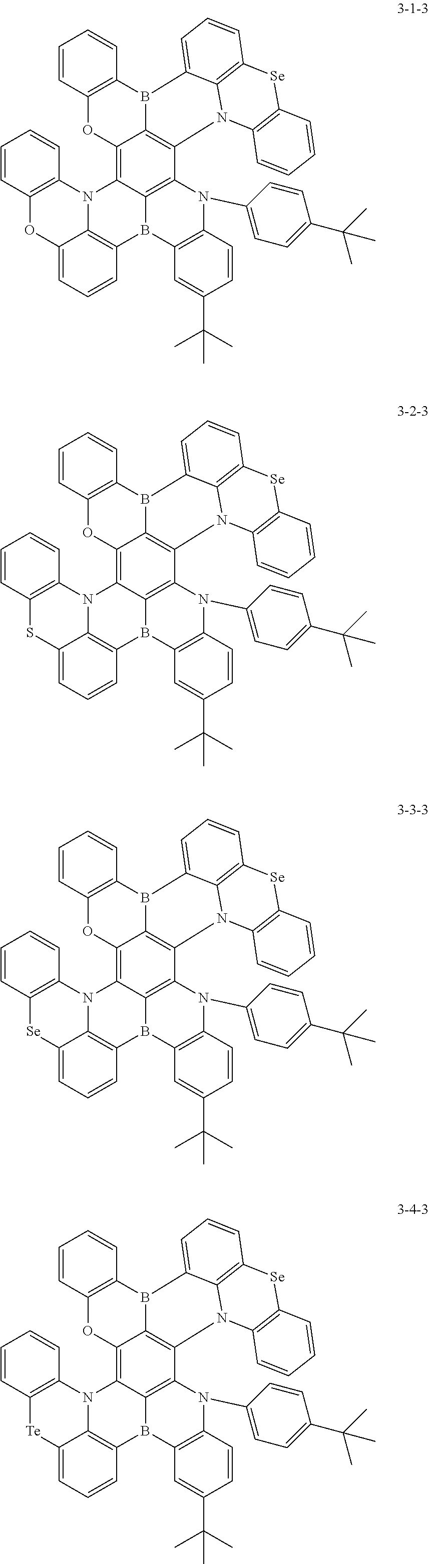

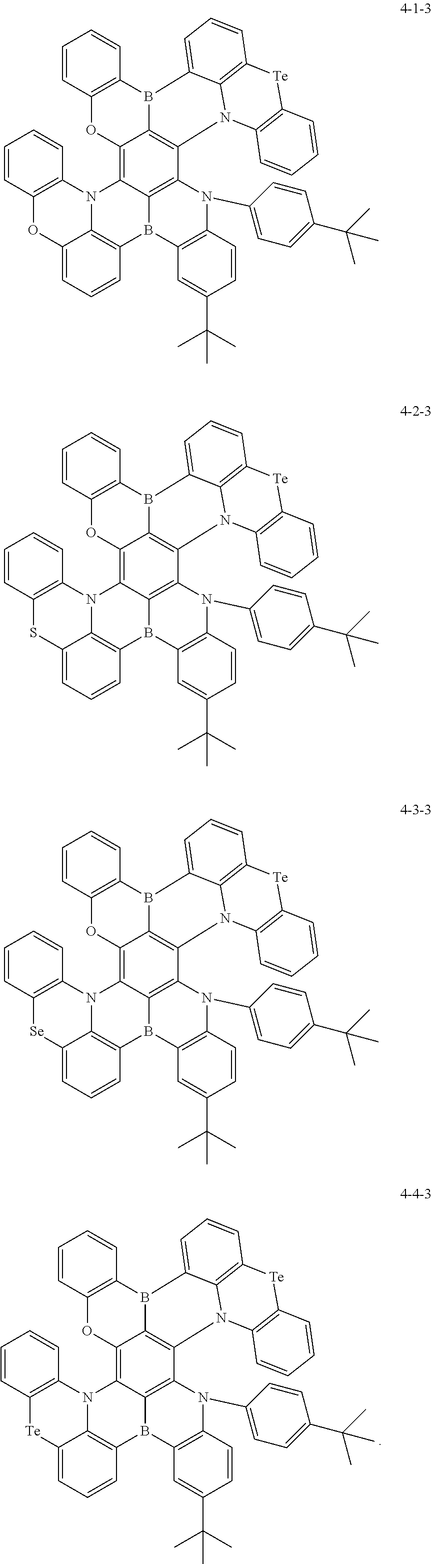

9. An electroluminescent device comprising an anode and a cathode, and a light-emitting layer located between the anode and the cathode, the light-emitting layer comprises a boron-nitrogen compound, wherein the boron-nitrogen compound has a structural formula represented by formula (I): 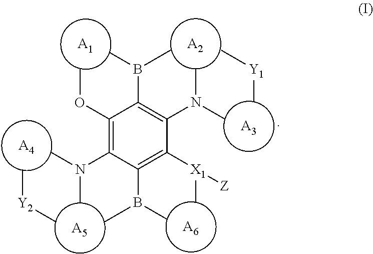
wherein, X₁ is selected from O or N;
when X₁ is selected from O, Z is selected from non-bonding, and one of Y₁ and Y₂ is selected from —O—, —S—, —Se—, —Te—, —C—C—, —C═C—, 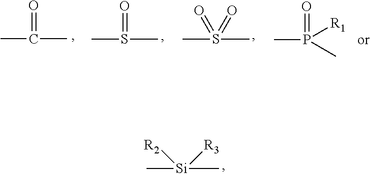
the other is selected from non-bonding, a single bond, —O—, —S—, —Se—, —Te—, —C—C—, —C═C—, 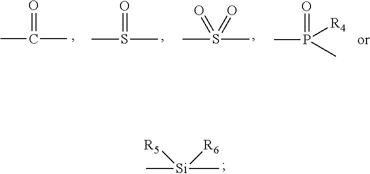
when X₁ is selected from N, Z is selected from an aromatic group or a heterocyclic group having a carbon atom number ranging from 4 to 50, which are unsubstituted or substituted with deuterium, tritium, halogen, an alkyl group having a carbon atom number ranging from 1 to 50, or an alkoxy group having a carbon atom number ranging from 1 to 50, one of Y₁ and Y₂ is selected from —O—, —S—, —Se—, —Te—, —C—C—, —C═C—, 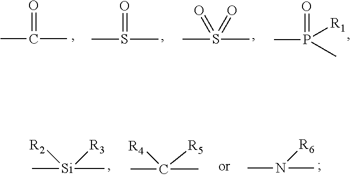
the other is selected from non-bonding, a single bond, —O—, —S—, —Se—, —Te—, —C—C—, —C═C—, 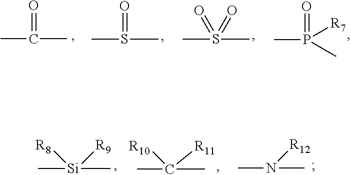
Z and A₆ form a ring or do not form a ring;
R₁ to R₁₂ are each independently selected from an aromatic group or a heterocyclic group having a carbon atom number ranging from 4 to 50, which are unsubstituted or substituted with deuterium, tritium, halogen, an alkyl group having a carbon atom number ranging from 1 to 50, or an alkoxy group having a carbon atom number ranging from 1 to 50;
A₁ to A₆ are each independently selected from an aromatic group or a heterocyclic group having a carbon atom number ranging from 4 to 50, which are unsubstituted or substituted with deuterium, tritium, halogen, an alkyl group having a carbon atom number ranging from 1 to 50, or an alkoxy group having a carbon atom number ranging from 1 to 50.

10. The electroluminescent device according to claim 9, wherein the aromatic group or the heterocyclic group has a carbon atom number of 4-30.

11. The electroluminescent device according to claim 9, wherein the aromatic group or a heterocyclic group, for each occurrence, is independently selected from one of the following structural formulas 1-38: 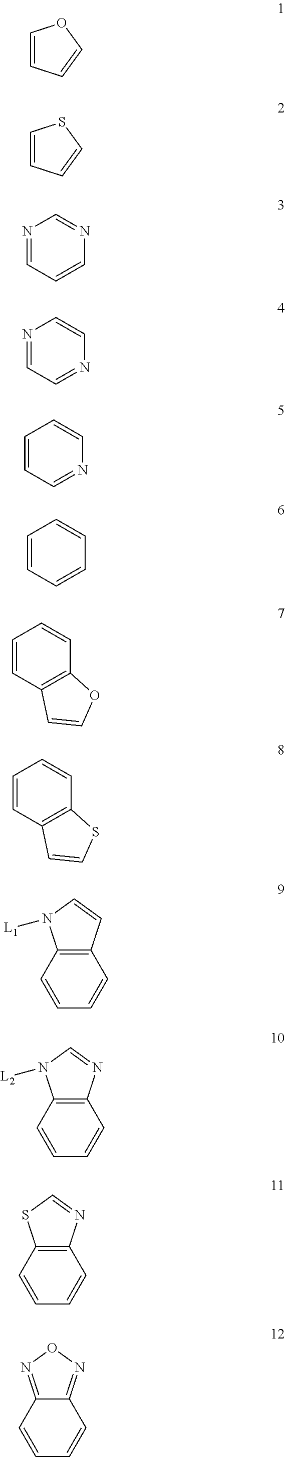 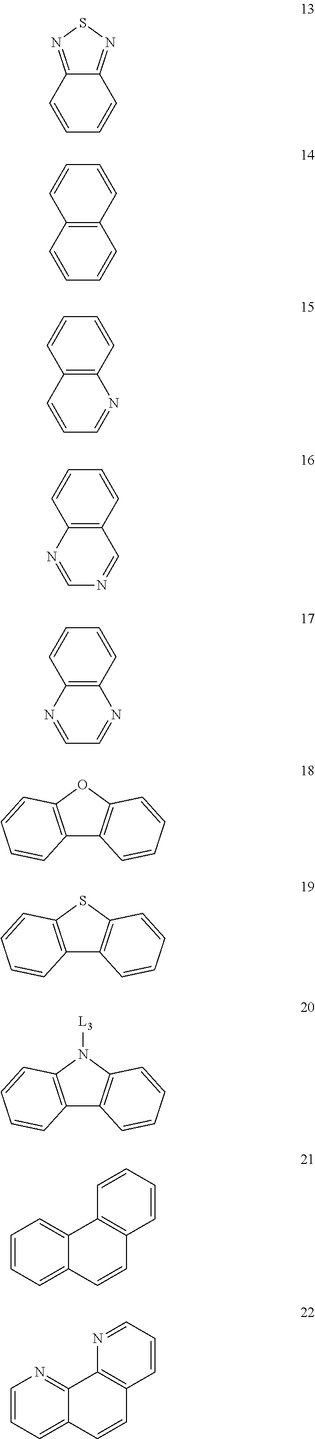 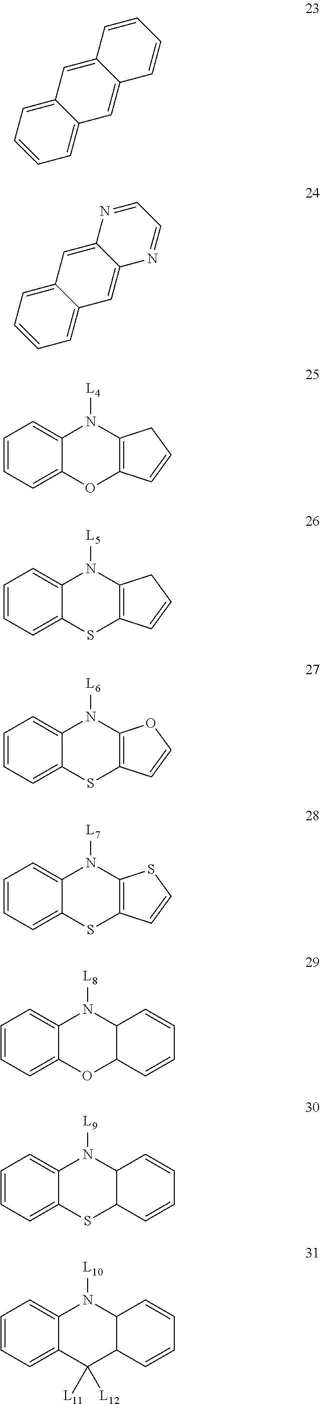 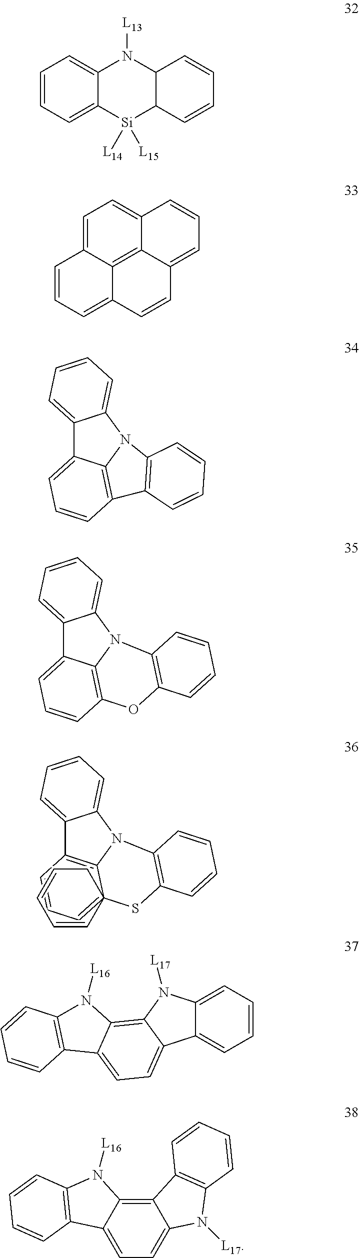
wherein, L₁ to L₁₉ are each independently selected from a linear or branched alkyl group having a carbon atom number ranging from 1 to 50, which is unsubstituted or substituted with deuterium, tritium, halogen, an alkyl group having a carbon atom number ranging from 1 to 50 or an alkoxy group having a carbon atom number ranging from 1 to 50, or an aromatic group or a heterocyclic groups having a carbon atom number ranging from 4 to 50, which is unsubstituted or substituted with deuterium, tritium, halogen, an alkyl group having a carbon atom number ranging from 1 to 50 or an alkoxy group having a carbon atom number ranging from 1 to 50;
L₁ to L₁₉ form a ring or do not form a ring between each other.

12. The electroluminescent device according to claim 10, wherein A₁ to A₆ are each independently selected from one of the following groups: 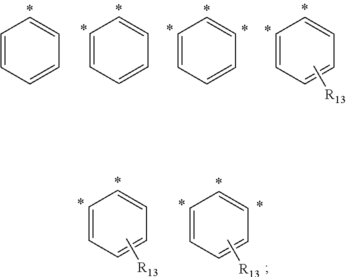
wherein, R₁₃ is selected from tert-butyl;
“*” represents a connection site.

13. The electroluminescent device according to claim 12, wherein,
X₁ is selected from O;
Z is selected from non-bonding;
Y₁ is selected from —O—, —S—, —Se—, —Te—, —C—C—, —C═C—, 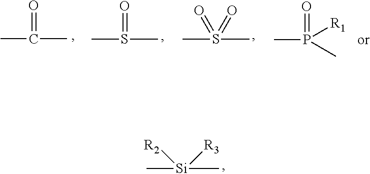
or;
Y₂ is selected from non-bonding, a single bond, —O—, —S—, —Se—, —Te—, —C—C—, —C═C—, 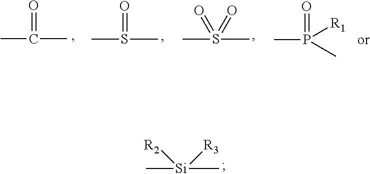
R₁ to R₆ are selected from phenyl.

14. The electroluminescent device according to claim 13, wherein the boron-nitrogen compound is selected from one of compounds represented by formulas 1-1-1 to 13-9-1:

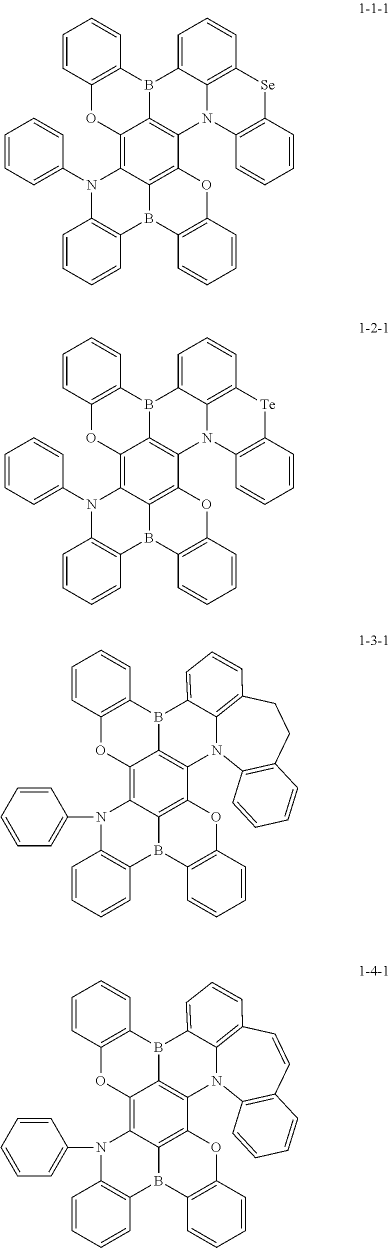

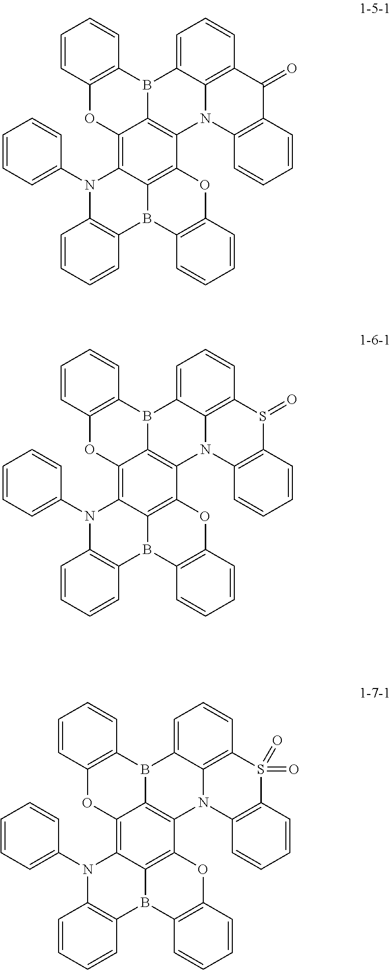 [SMILES: O=c1c2ccccc2n2c3c(cccc13)B1c3ccccc3Oc3c1c-2c1c2c3N(c3ccccc3)c3ccccc3B2c2ccccc2O1 ; O=S1c2ccccc2N2c3c(cccc31)B1c3ccccc3Oc3c1c2c1c2c3N(c3ccccc3)c3ccccc3B2c2ccccc2O1 ; O=S1(=O)c2ccccc2N2c3c(cccc31)B1c3ccccc3Oc3c1c2c1c2c3N(c3ccccc3)c3ccccc3B2c2ccccc2O1]

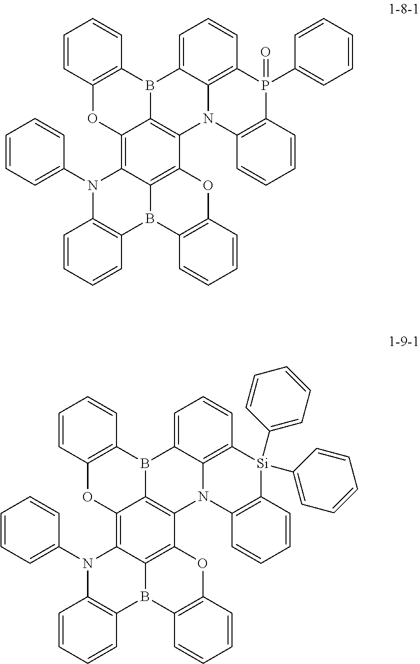 [SMILES: O=P1(c2ccccc2)c2ccccc2N2c3c(cccc31)B1c3ccccc3Oc3c1c2c1c2c3N(c3ccccc3)c3ccccc3B2c2ccccc2O1 ; c1ccc(N2c3ccccc3B3c4ccccc4Oc4c3c2c2c3c4N4c5ccccc5[Si](c5ccccc5)(c5ccccc5)c5cccc(c54)B3c3ccccc3O2)cc1]

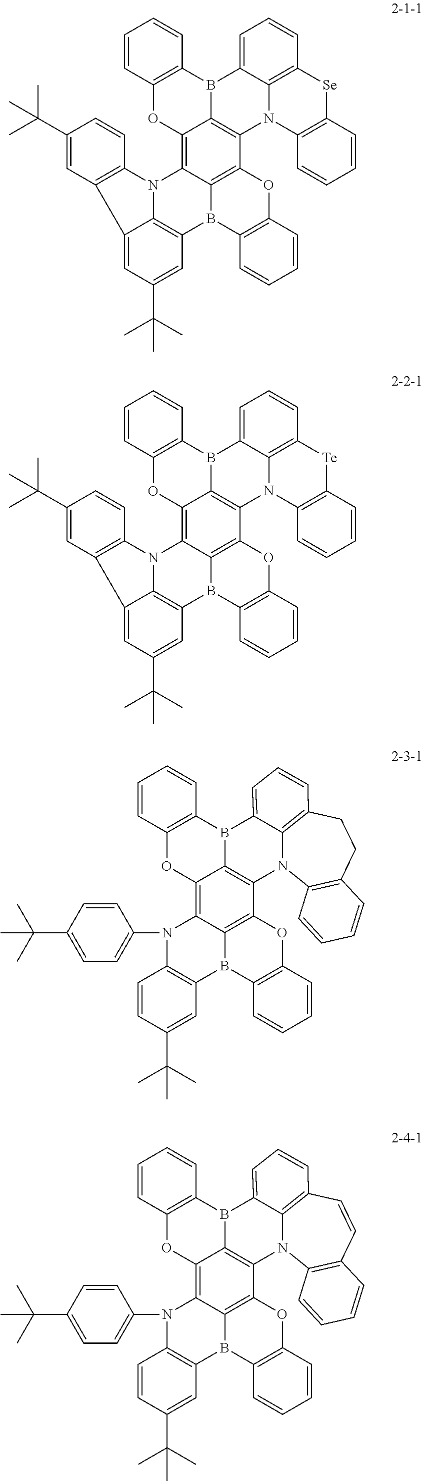

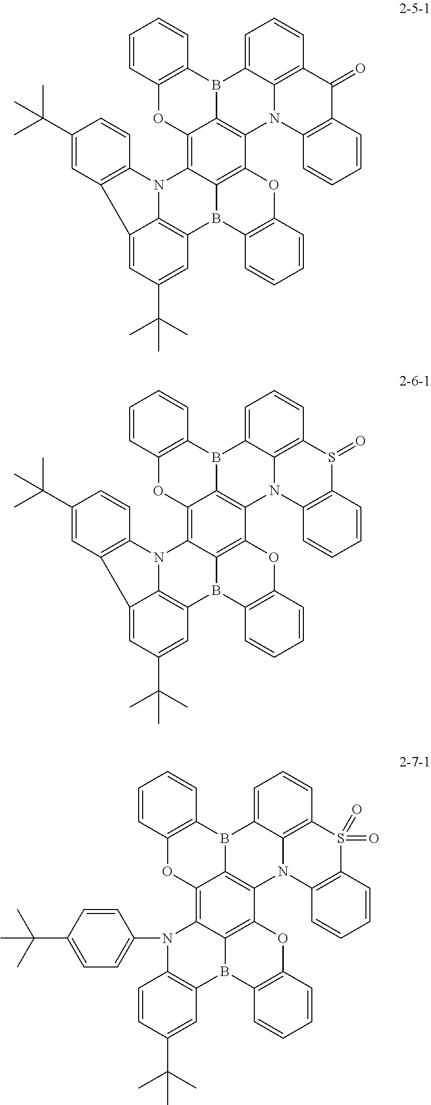

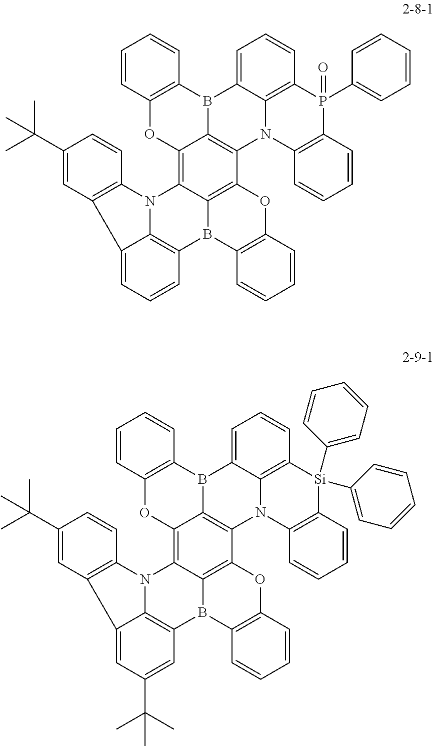 [SMILES: CC(C)(C)c1ccc2c(c1)c1cccc3c1n2-c1c2c4c(c5c1B3c1ccccc1O5)N1c3ccccc3P(=O)(c3ccccc3)c3cccc(c31)B4c1ccccc1O2 ; CC(C)(C)c1ccc2c(c1)c1cc(C(C)(C)C)cc3c1n2-c1c2c4c(c5c1B3c1ccccc1O5)N1c3ccccc3[Si](c3ccccc3)(c3ccccc3)c3cccc(c31)B4c1ccccc1O2]

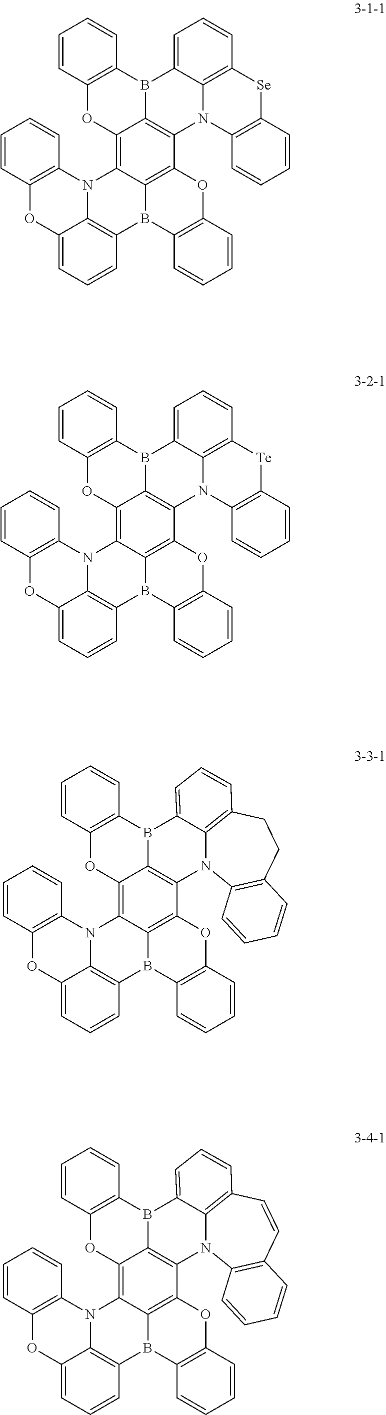

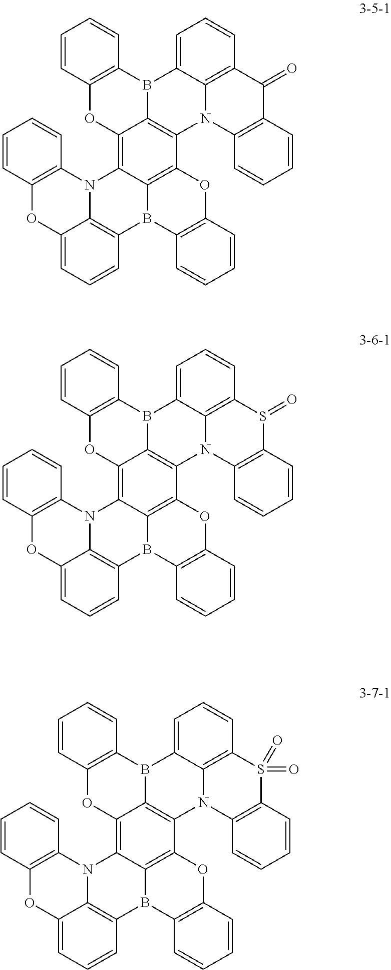 [SMILES: O=c1c2ccccc2n2c3c(cccc13)B1c3ccccc3Oc3c1c-2c1c2c3N3c4ccccc4Oc4cccc(c43)B2c2ccccc2O1 ; O=S1c2ccccc2N2c3c(cccc31)B1c3ccccc3Oc3c1c2c1c2c3N3c4ccccc4Oc4cccc(c43)B2c2ccccc2O1 ; O=S1(=O)c2ccccc2N2c3c(cccc31)B1c3ccccc3Oc3c1c2c1c2c3N3c4ccccc4Oc4cccc(c43)B2c2ccccc2O1]

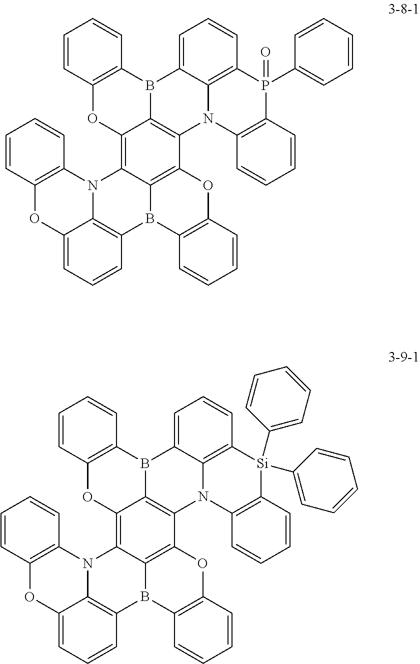 [SMILES: O=P1(c2ccccc2)c2ccccc2N2c3c(cccc31)B1c3ccccc3Oc3c1c2c1c2c3N3c4ccccc4Oc4cccc(c43)B2c2ccccc2O1 ; c1ccc([Si]2(c3ccccc3)c3ccccc3N3c4c(cccc42)B2c4ccccc4Oc4c2c3c2c3c4N4c5ccccc5Oc5cccc(c54)B3c3ccccc3O2)cc1]

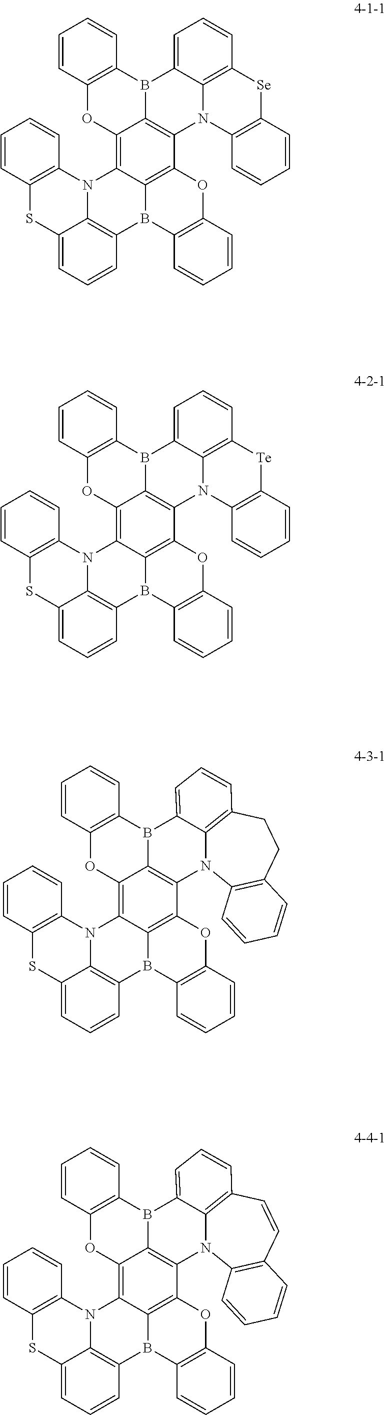

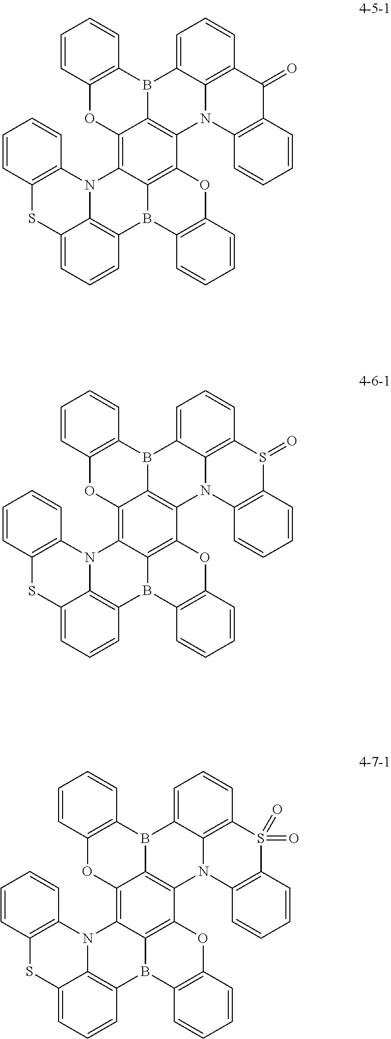 [SMILES: O=c1c2ccccc2n2c3c(cccc13)B1c3ccccc3Oc3c1c-2c1c2c3N3c4ccccc4Sc4cccc(c43)B2c2ccccc2O1 ; O=S1c2ccccc2N2c3c(cccc31)B1c3ccccc3Oc3c1c2c1c2c3N3c4ccccc4Sc4cccc(c43)B2c2ccccc2O1 ; O=S1(=O)c2ccccc2N2c3c(cccc31)B1c3ccccc3Oc3c1c2c1c2c3N3c4ccccc4Sc4cccc(c43)B2c2ccccc2O1]

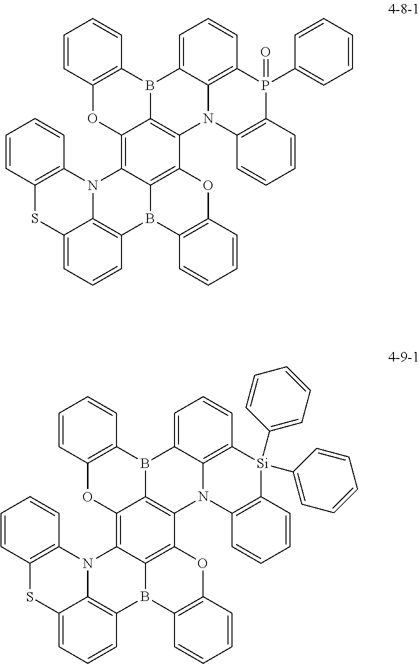 [SMILES: O=P1(c2ccccc2)c2ccccc2N2c3c(cccc31)B1c3ccccc3Oc3c1c2c1c2c3N3c4ccccc4Sc4cccc(c43)B2c2ccccc2O1 ; c1ccc([Si]2(c3ccccc3)c3ccccc3N3c4c(cccc42)B2c4ccccc4Oc4c2c3c2c3c4N4c5ccccc5Sc5cccc(c54)B3c3ccccc3O2)cc1]

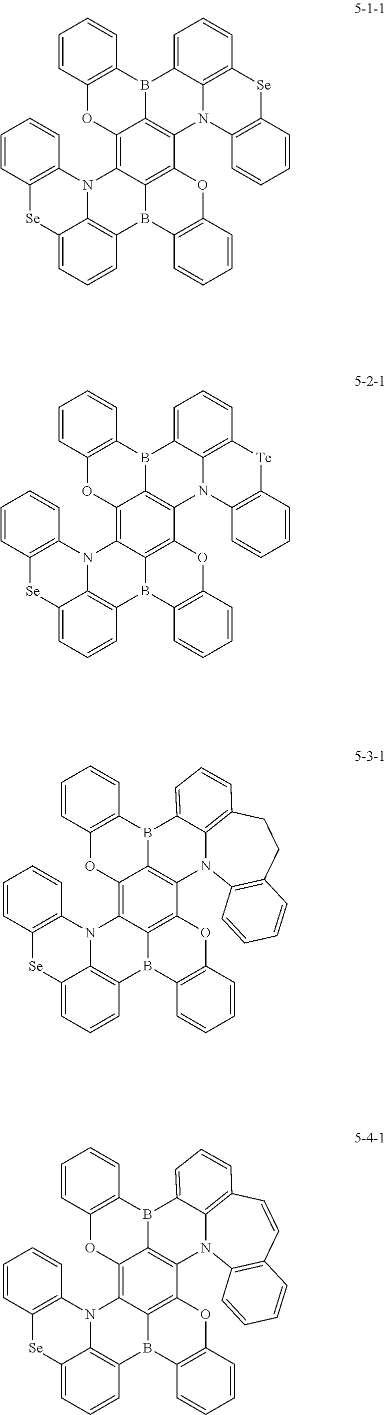

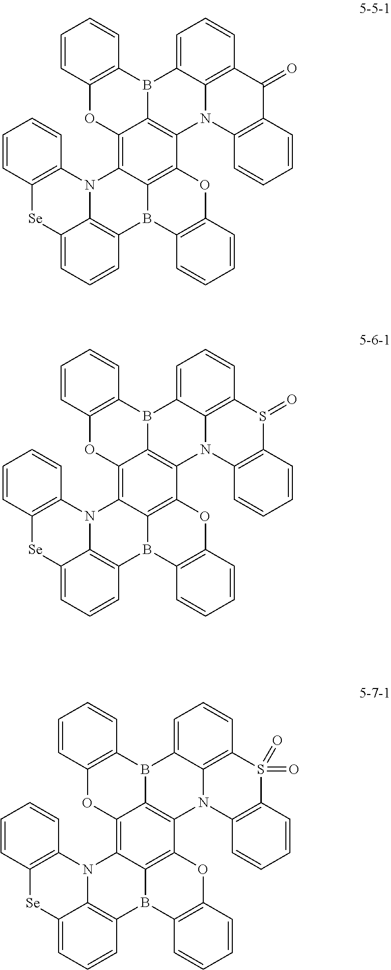 [SMILES: O=c1c2ccccc2n2c3c(cccc13)B1c3ccccc3Oc3c1c-2c1c2c3N3c4ccccc4[Se]c4cccc(c43)B2c2ccccc2O1 ; O=S1c2ccccc2N2c3c(cccc31)B1c3ccccc3Oc3c1c2c1c2c3N3c4ccccc4[Se]c4cccc(c43)B2c2ccccc2O1 ; O=S1(=O)c2ccccc2N2c3c(cccc31)B1c3ccccc3Oc3c1c2c1c2c3N3c4ccccc4[Se]c4cccc(c43)B2c2ccccc2O1]

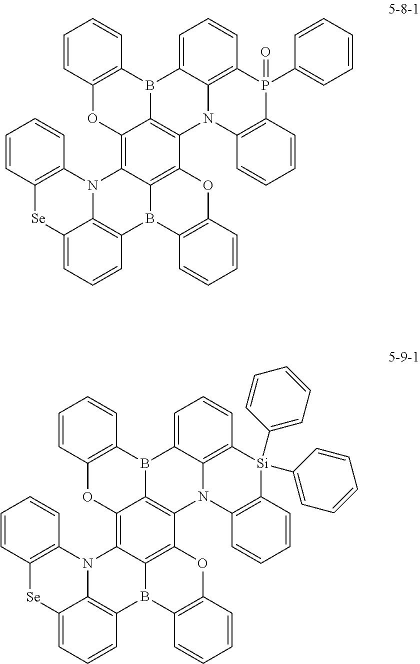 [SMILES: O=P1(c2ccccc2)c2ccccc2N2c3c(cccc31)B1c3ccccc3Oc3c1c2c1c2c3N3c4ccccc4[Se]c4cccc(c43)B2c2ccccc2O1 ; c1ccc([Si]2(c3ccccc3)c3ccccc3N3c4c(cccc42)B2c4ccccc4Oc4c2c3c2c3c4N4c5ccccc5[Se]c5cccc(c54)B3c3ccccc3O2)cc1]

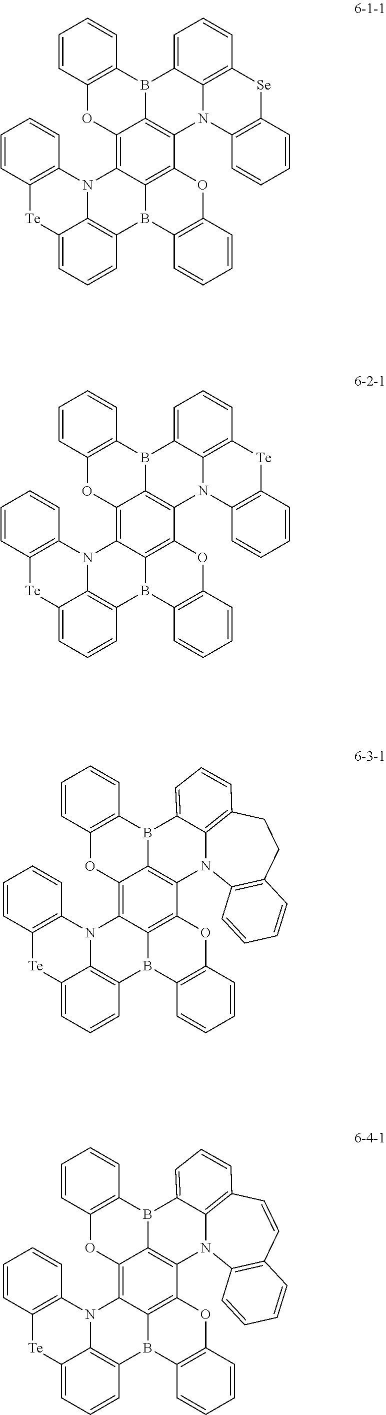

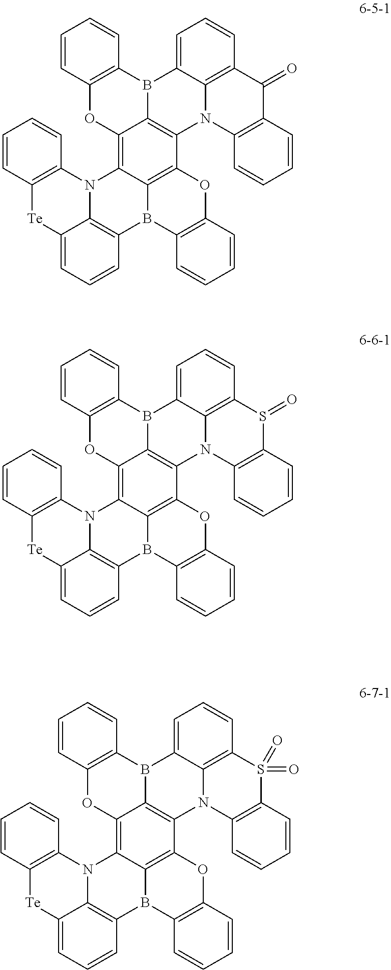

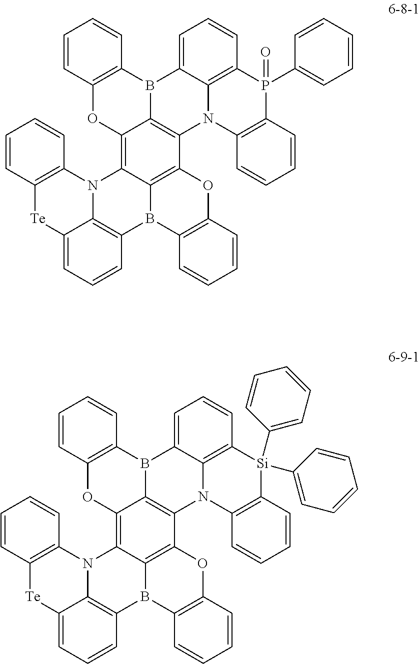

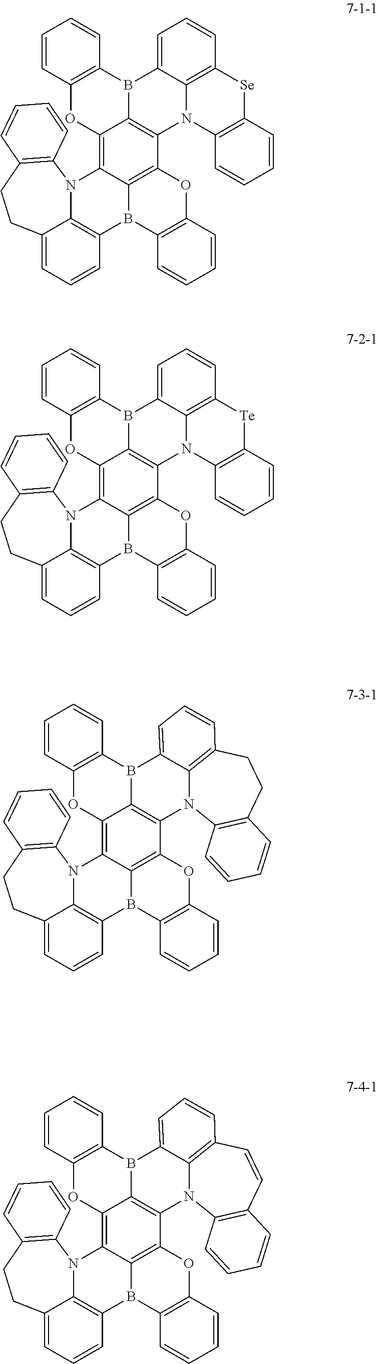

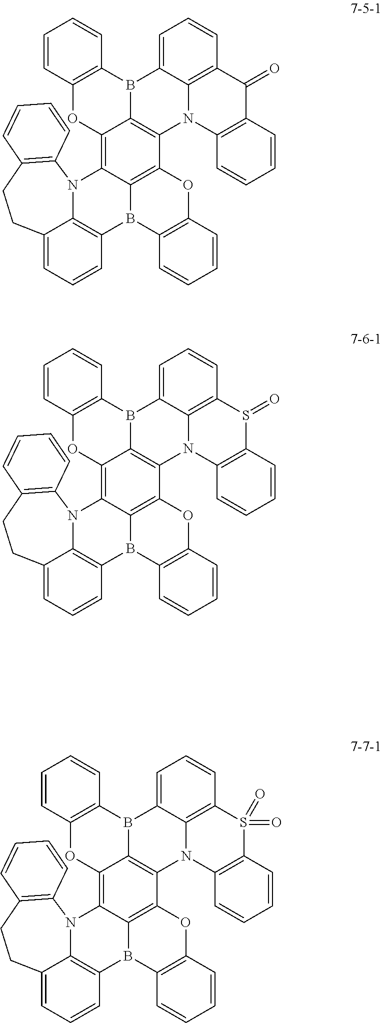 [SMILES: O=c1c2ccccc2n2c3c(cccc13)B1c3ccccc3Oc3c1c-2c1c2c3N3c4ccccc4CCc4cccc(c43)B2c2ccccc2O1 ; O=S1c2ccccc2N2c3c(cccc31)B1c3ccccc3Oc3c1c2c1c2c3N3c4ccccc4CCc4cccc(c43)B2c2ccccc2O1 ; O=S1(=O)c2ccccc2N2c3c(cccc31)B1c3ccccc3Oc3c1c2c1c2c3N3c4ccccc4CCc4cccc(c43)B2c2ccccc2O1]

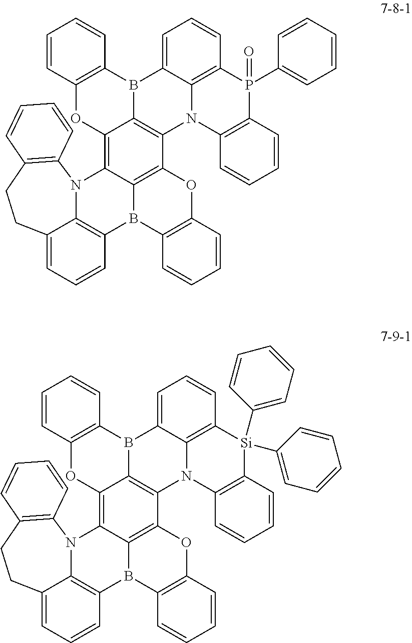 [SMILES: O=P1(c2ccccc2)c2ccccc2N2c3c(cccc31)B1c3ccccc3Oc3c1c2c1c2c3N3c4ccccc4CCc4cccc(c43)B2c2ccccc2O1 ; c1ccc([Si]2(c3ccccc3)c3ccccc3N3c4c(cccc42)B2c4ccccc4Oc4c2c3c2c3c4N4c5ccccc5CCc5cccc(c54)B3c3ccccc3O2)cc1]

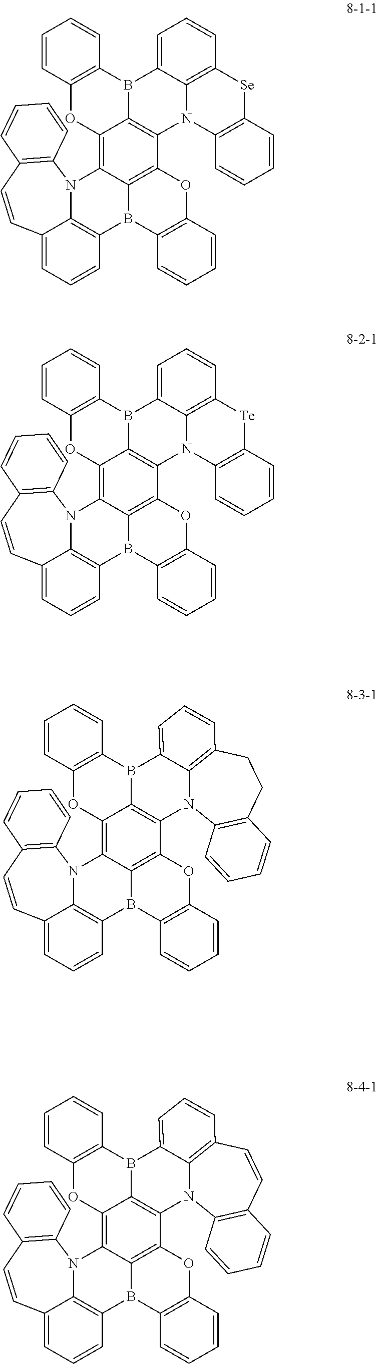

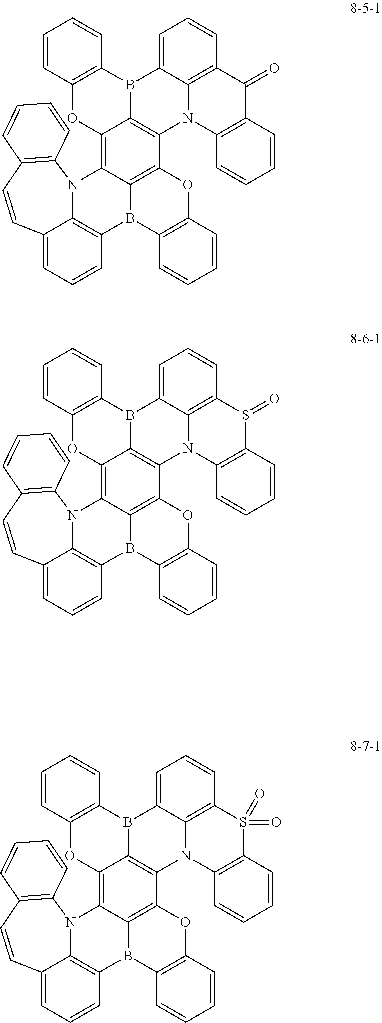 [SMILES: O=c1c2ccccc2n2c3c(cccc13)B1c3ccccc3Oc3c1c-2c1c2c3N3c4ccccc4C=Cc4cccc(c43)B2c2ccccc2O1 ; O=S1c2ccccc2N2c3c(cccc31)B1c3ccccc3Oc3c1c2c1c2c3N3c4ccccc4C=Cc4cccc(c43)B2c2ccccc2O1 ; O=S1(=O)c2ccccc2N2c3c(cccc31)B1c3ccccc3Oc3c1c2c1c2c3N3c4ccccc4C=Cc4cccc(c43)B2c2ccccc2O1]

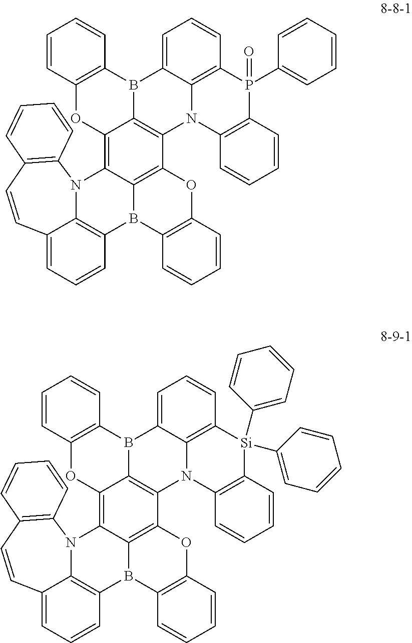 [SMILES: O=P1(c2ccccc2)c2ccccc2N2c3c(cccc31)B1c3ccccc3Oc3c1c2c1c2c3N3c4ccccc4C=Cc4cccc(c43)B2c2ccccc2O1 ; C1=Cc2cccc3c2N(c2ccccc21)c1c2c4c(c5c1B3c1ccccc1O5)N1c3ccccc3[Si](c3ccccc3)(c3ccccc3)c3cccc(c31)B4c1ccccc1O2]

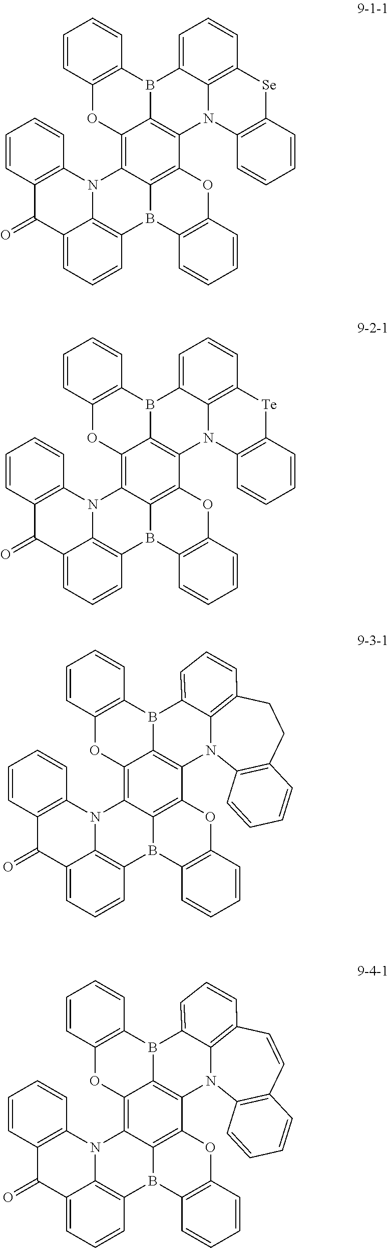

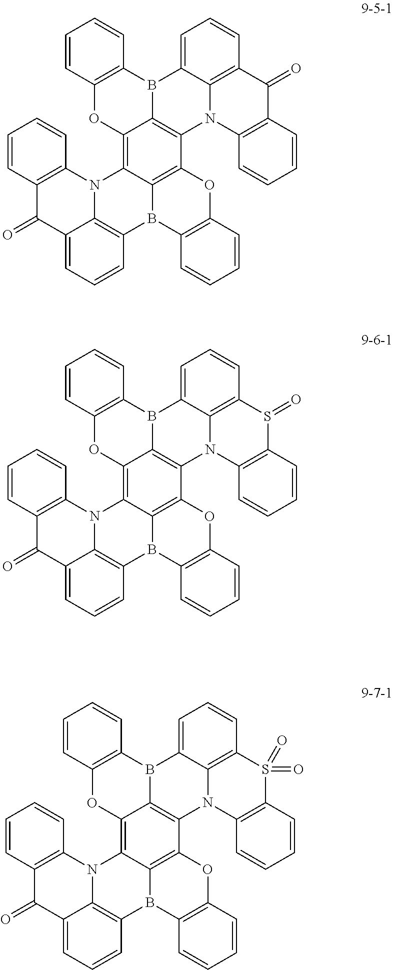 [SMILES: O=c1c2ccccc2n2c3c(cccc13)B1c3ccccc3Oc3c1c-2c1c2c3-n3c4ccccc4c(=O)c4cccc(c43)B2c2ccccc2O1 ; O=c1c2ccccc2n2c3c(cccc13)B1c3ccccc3Oc3c1c-2c1c2c3N3c4ccccc4S(=O)c4cccc(c43)B2c2ccccc2O1 ; O=c1c2ccccc2n2c3c(cccc13)B1c3ccccc3Oc3c1c-2c1c2c3N3c4ccccc4S(=O)(=O)c4cccc(c43)B2c2ccccc2O1]

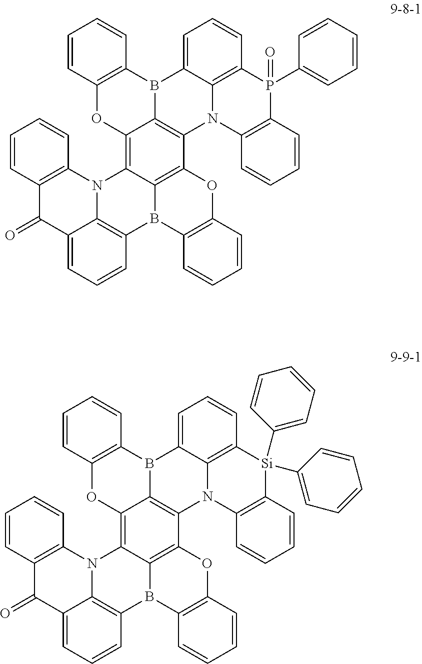 [SMILES: O=c1c2ccccc2n2c3c(cccc13)B1c3ccccc3Oc3c1c-2c1c2c3N3c4ccccc4P(=O)(c4ccccc4)c4cccc(c43)B2c2ccccc2O1 ; O=c1c2ccccc2n2c3c(cccc13)B1c3ccccc3Oc3c1c-2c1c2c3N3c4ccccc4[Si](c4ccccc4)(c4ccccc4)c4cccc(c43)B2c2ccccc2O1]

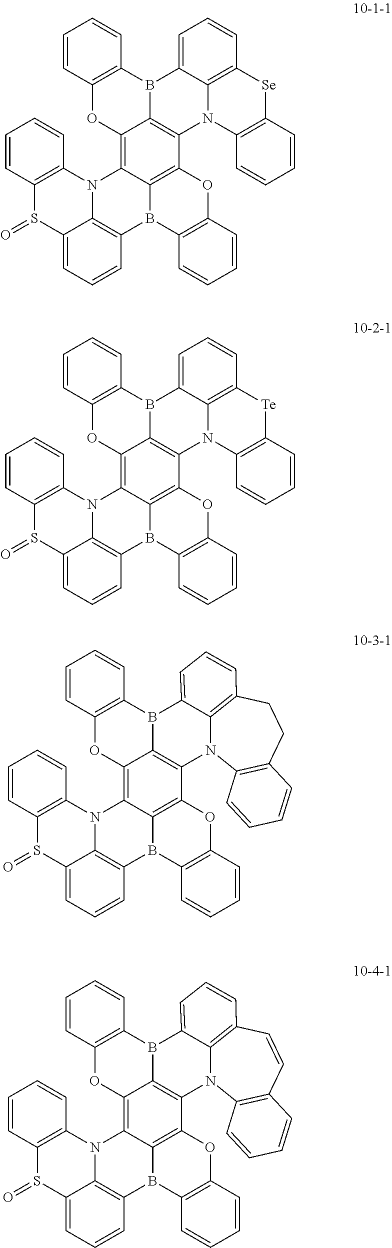

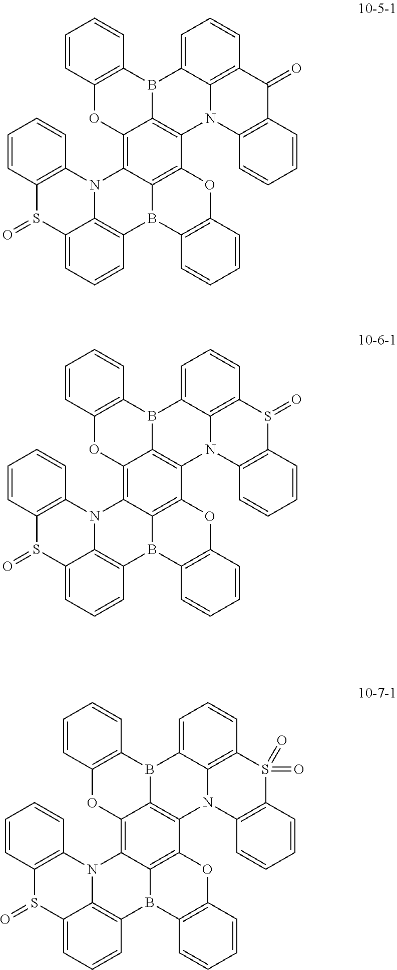 [SMILES: O=c1c2ccccc2n2c3c(cccc13)B1c3ccccc3Oc3c1c-2c1c2c3N3c4ccccc4S(=O)c4cccc(c43)B2c2ccccc2O1 ; O=S1c2ccccc2N2c3c(cccc31)B1c3ccccc3Oc3c1c2c1c2c3N3c4ccccc4S(=O)c4cccc(c43)B2c2ccccc2O1 ; O=S1c2ccccc2N2c3c(cccc31)B1c3ccccc3Oc3c1c2c1c2c3N3c4ccccc4S(=O)(=O)c4cccc(c43)B2c2ccccc2O1]

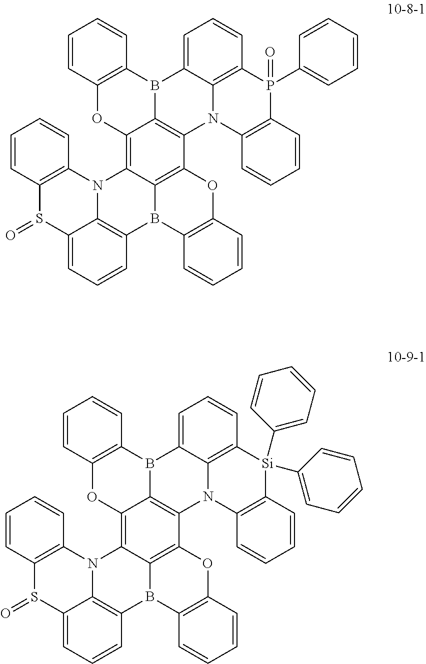 [SMILES: O=S1c2ccccc2N2c3c(cccc31)B1c3ccccc3Oc3c1c2c1c2c3N3c4ccccc4P(=O)(c4ccccc4)c4cccc(c43)B2c2ccccc2O1 ; O=S1c2ccccc2N2c3c(cccc31)B1c3ccccc3Oc3c1c2c1c2c3N3c4ccccc4[Si](c4ccccc4)(c4ccccc4)c4cccc(c43)B2c2ccccc2O1]

15. The electroluminescent device according to claim 12, wherein,
X₁ is selected from N;
Z is selected from p-tert-butylphenyl;
Y₁ and Y₂ are each independently selected from —O—, —S—, —Se—, —Te—;
Z and A₆ form a ring or do not form a ring.

16. The electroluminescent device according to claim 15, wherein the boron-nitrogen compound is selected from one of the compounds represented by formulas 1-1-2 to 4-4-2 and 1-1-3 to 4-4-3:

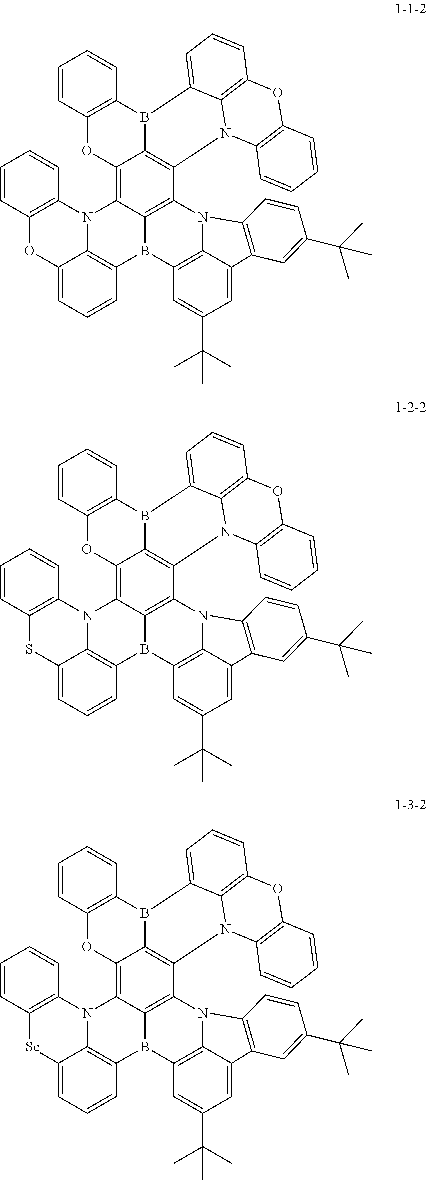 [SMILES: CC(C)(C)c1ccc2c(c1)c1cc(C(C)(C)C)cc3c1n2-c1c2c(c4c5c1N1c6ccccc6Oc6cccc(c61)B5c1ccccc1O4)N1c4ccccc4Oc4cccc(c41)B23 ; CC(C)(C)c1ccc2c(c1)c1cc(C(C)(C)C)cc3c1n2-c1c2c(c4c5c1N1c6ccccc6Oc6cccc(c61)B5c1ccccc1O4)N1c4ccccc4Sc4cccc(c41)B23 ; CC(C)(C)c1ccc2c(c1)c1cc(C(C)(C)C)cc3c1n2-c1c2c(c4c5c1N1c6ccccc6Oc6cccc(c61)B5c1ccccc1O4)N1c4ccccc4[Se]c4cccc(c41)B23]

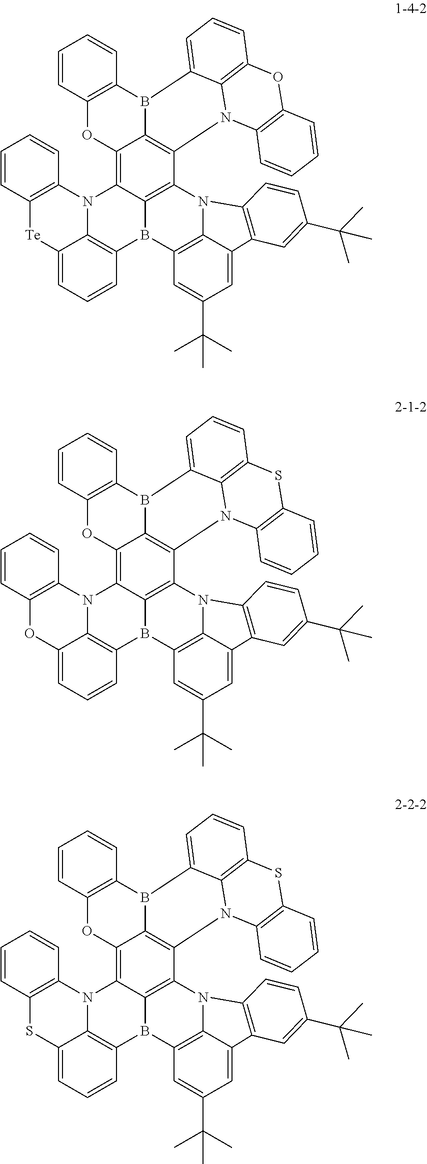

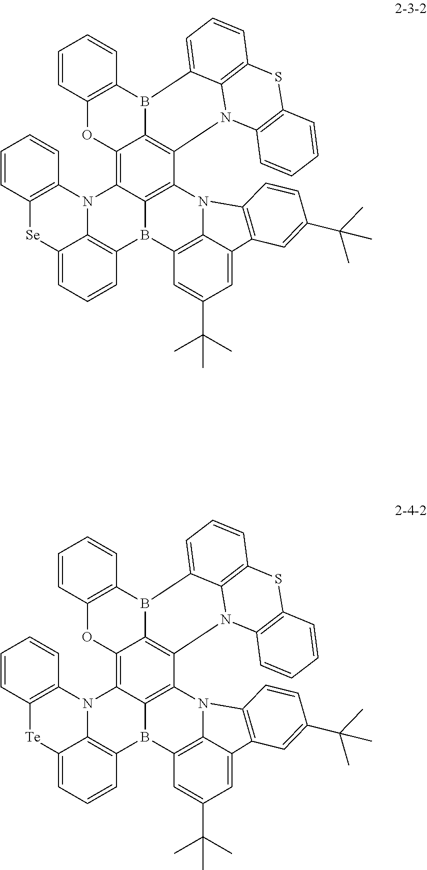

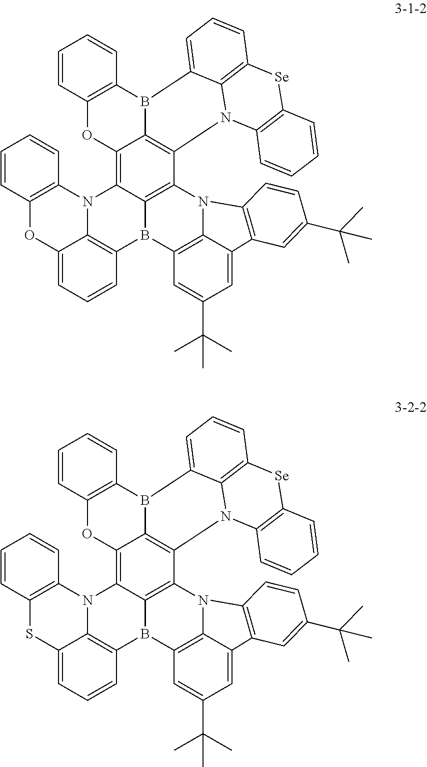 [SMILES: CC(C)(C)c1ccc2c(c1)c1cc(C(C)(C)C)cc3c1n2-c1c2c(c4c5c1N1c6ccccc6[Se]c6cccc(c61)B5c1ccccc1O4)N1c4ccccc4Oc4cccc(c41)B23 ; CC(C)(C)c1ccc2c(c1)c1cc(C(C)(C)C)cc3c1n2-c1c2c(c4c5c1N1c6ccccc6[Se]c6cccc(c61)B5c1ccccc1O4)N1c4ccccc4Sc4cccc(c41)B23]

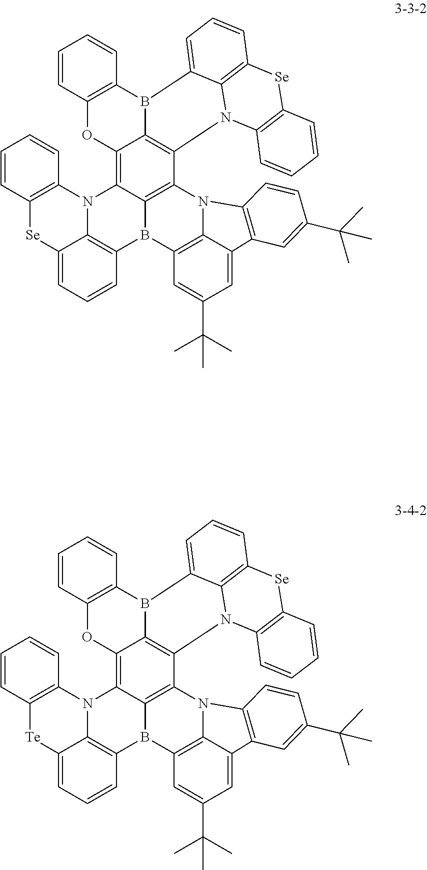

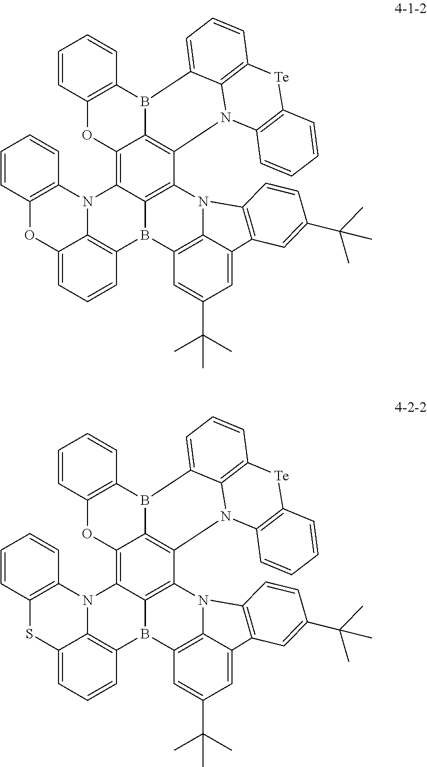

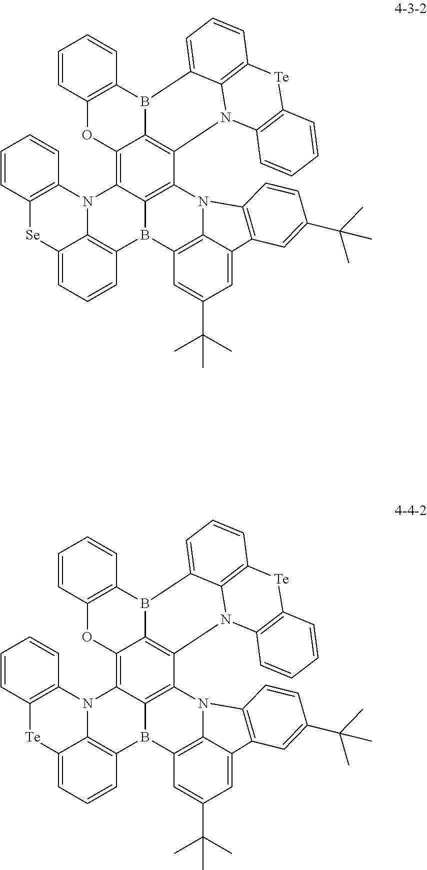

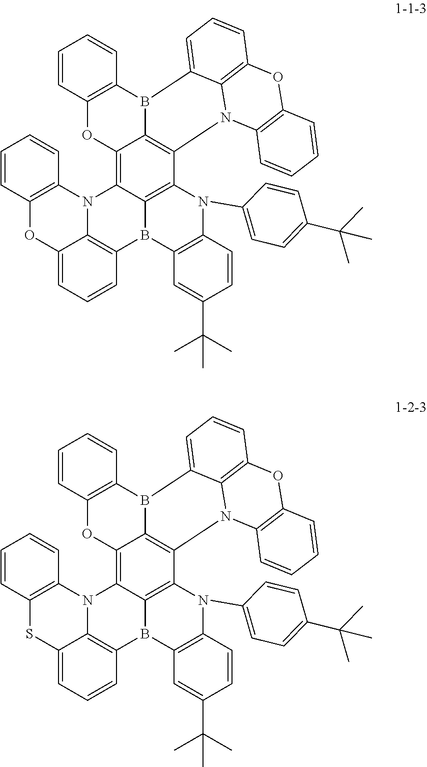 [SMILES: CC(C)(C)c1ccc(N2c3ccc(C(C)(C)C)cc3B3c4cccc5c4N(c4ccccc4O5)c4c5c6c(c2c43)N2c3ccccc3Oc3cccc(c32)B6c2ccccc2O5)cc1 ; CC(C)(C)c1ccc(N2c3ccc(C(C)(C)C)cc3B3c4cccc5c4N(c4ccccc4S5)c4c5c6c(c2c43)N2c3ccccc3Oc3cccc(c32)B6c2ccccc2O5)cc1]

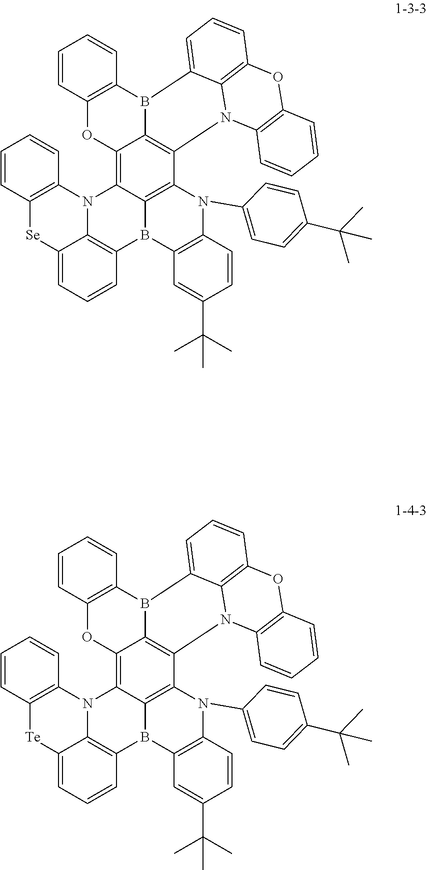

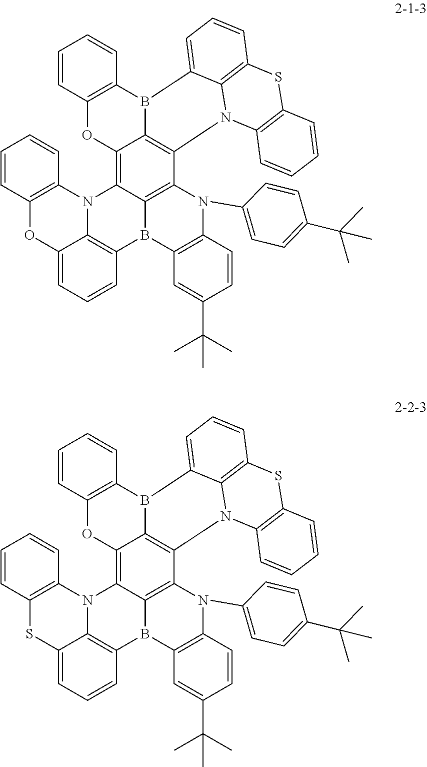 [SMILES: CC(C)(C)c1ccc(N2c3ccc(C(C)(C)C)cc3B3c4cccc5c4N(c4ccccc4O5)c4c5c6c(c2c43)N2c3ccccc3Sc3cccc(c32)B6c2ccccc2O5)cc1 ; CC(C)(C)c1ccc(N2c3ccc(C(C)(C)C)cc3B3c4cccc5c4N(c4ccccc4S5)c4c5c6c(c2c43)N2c3ccccc3Sc3cccc(c32)B6c2ccccc2O5)cc1]

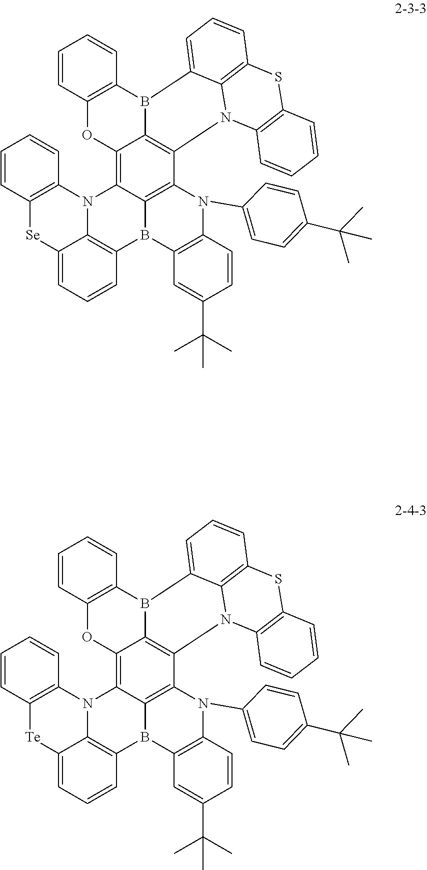

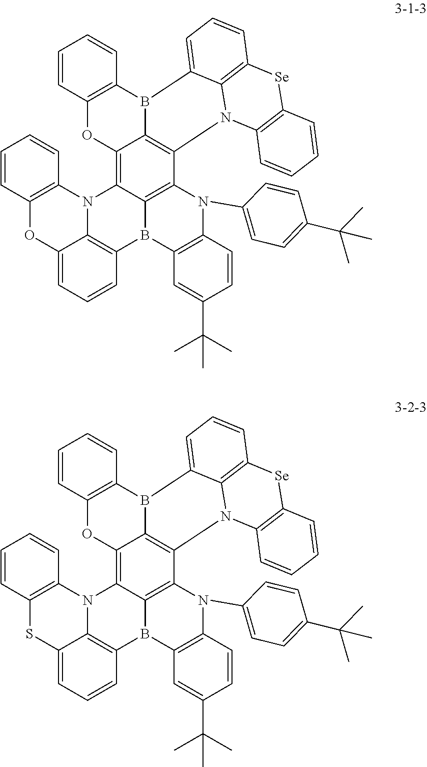 [SMILES: CC(C)(C)c1ccc(N2c3ccc(C(C)(C)C)cc3B3c4cccc5c4N(c4ccccc4O5)c4c5c6c(c2c43)N2c3ccccc3[Se]c3cccc(c32)B6c2ccccc2O5)cc1 ; CC(C)(C)c1ccc(N2c3ccc(C(C)(C)C)cc3B3c4cccc5c4N(c4ccccc4S5)c4c5c6c(c2c43)N2c3ccccc3[Se]c3cccc(c32)B6c2ccccc2O5)cc1]

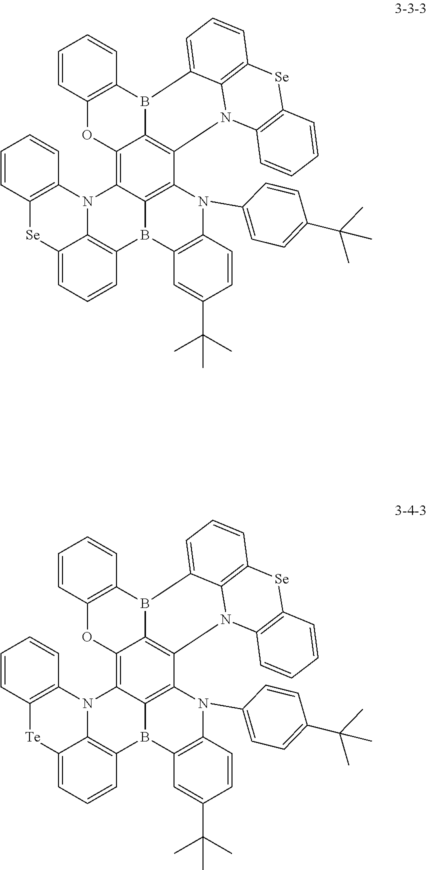

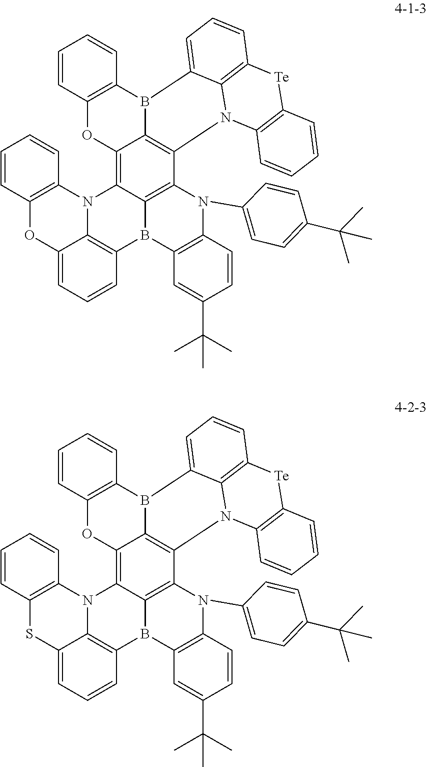

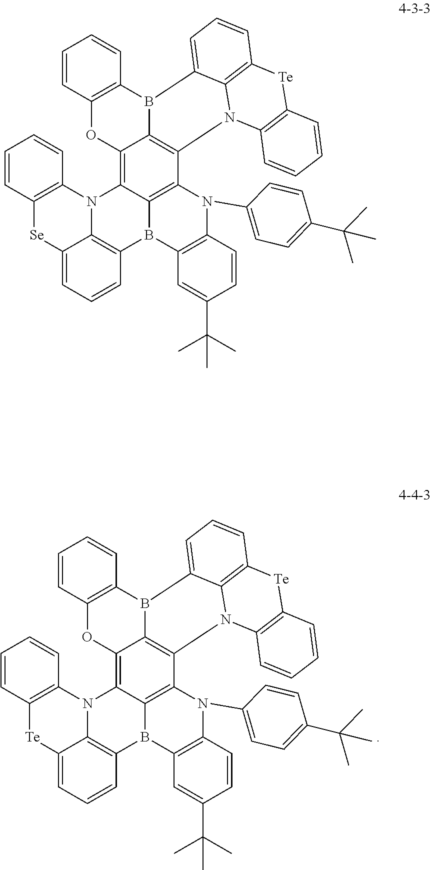

17. A display device comprising an electroluminescent device, wherein the electroluminescent device comprises an anode and a cathode, and a light-emitting layer located between the anode and the cathode, wherein the light-emitting layer comprises a boron-nitrogen compound, wherein the boron-nitrogen compound has a structural formula represented by a formula (I): 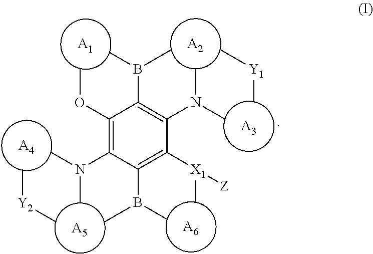
wherein, X₁ is selected from O or N;
when X₁ is selected from O, Z is selected from non-bonding, and one of Y₁ and Y₂ is selected from —O—, —S—, —Se—, —Te—, —C—C—, —C═C—, 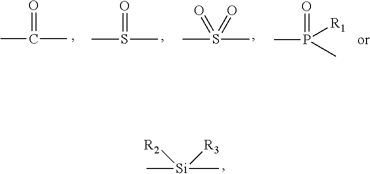
the other is selected from non-bonding, a single bond, —O—, —S—, —Se—, —Te—, —C—C—, —C═C—, 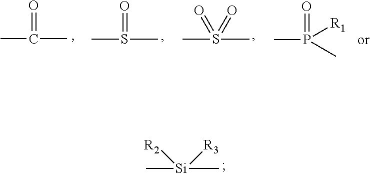
when X₁ is selected from N, Z is selected from an aromatic group or a heterocyclic group having a carbon atom number ranging from 4 to 50, which are unsubstituted or substituted with deuterium, tritium, halogen, an alkyl group having a carbon atom number ranging from 1 to 50, or an alkoxy group having a carbon atom number ranging from 1 to 50, one of Y₁ and Y₂ is selected from —O—, —S—, —Se—, —Te—, —C—C—, —C═C—, 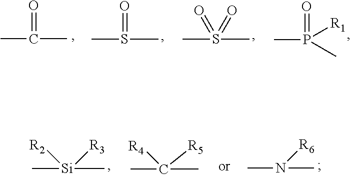
the other is selected from non-bonding, a single bond, —O—, —S—, —Se—, —Te—, —C—C—, —C═C—, 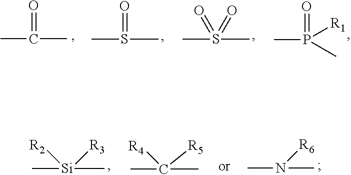
Z and A6 form a ring or do not form a ring;
R₁ to R₁₂ are each independently selected from an aromatic group or a heterocyclic group having a carbon atom number ranging from 4 to 50, which are unsubstituted or substituted with deuterium, tritium, halogen, an alkyl group having a carbon atom number ranging from 1 to 50, or an alkoxy group having a carbon atom number ranging from 1 to 50;
A₁ to A₆ are each independently selected from an aromatic group or a heterocyclic group having a carbon atom number ranging from 4 to 50, which are unsubstituted or substituted with deuterium, tritium, halogen, an alkyl group having a carbon atom number ranging from 1 to 50, or an alkoxy group having a carbon atom number ranging from 1 to 50.

18. The display device according to claim 17, wherein the aromatic group or the heterocyclic group, for each occurrence, is independently selected from any one of the following structural formulas 1-38: 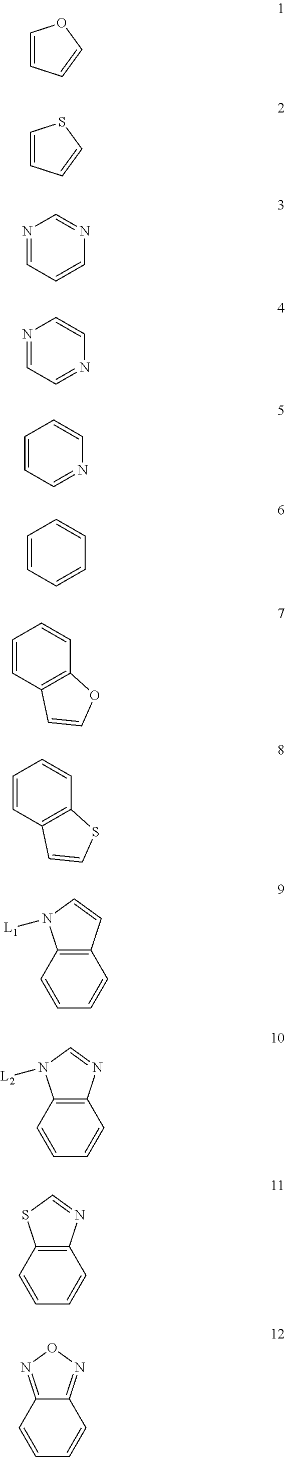 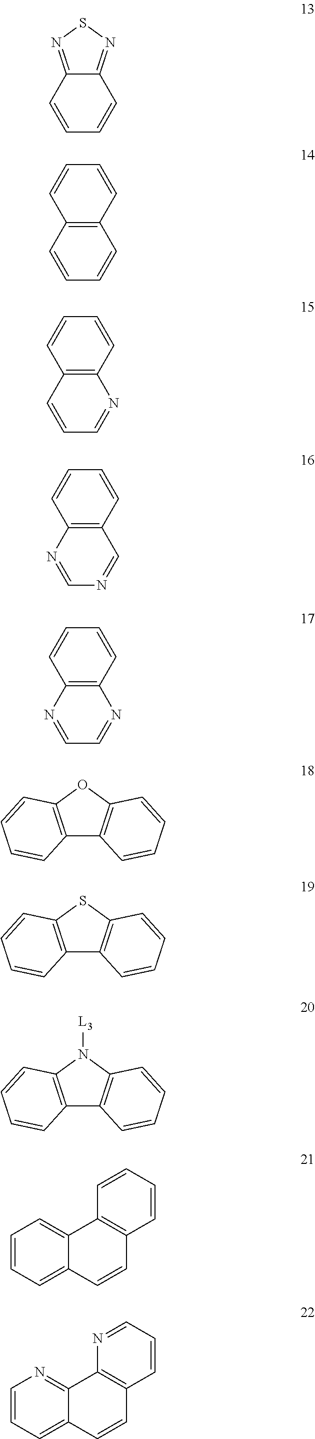 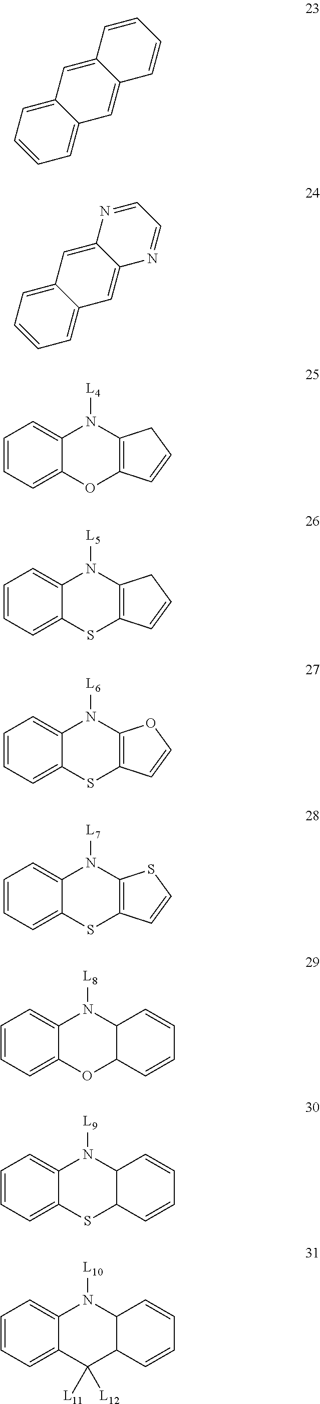 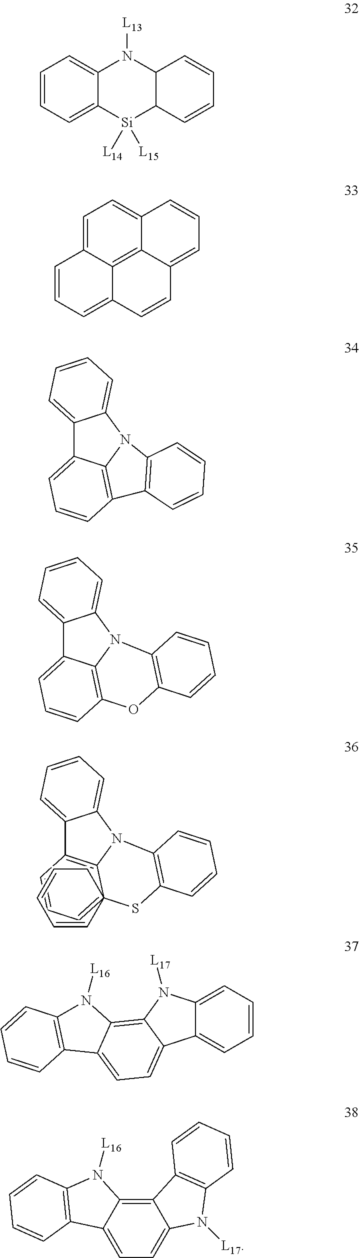
wherein, L₁ to L₁₉ are each independently selected from a linear or branched an alkyl group having a carbon atom number ranging from 1 to 50, which is unsubstituted or substituted with deuterium, tritium, halogen, an alkyl group having a carbon atom number ranging from 1 to 50 or an alkoxy group having a carbon atom number ranging from 1 to 50, or an aromatic group or a heterocyclic group having a carbon atom number ranging from 4 to 50, which is unsubstituted or substituted with deuterium, tritium, halogen, an alkyl group having a carbon atom number ranging from 1 to 50 or an alkoxy group having a carbon atom number ranging from 1 to 50;
L₁ to L₁₉ form a ring or do not form a ring between each other.

19. The display device according to claim 17, wherein A₁ to A₆ are each independently selected from one of the following groups: 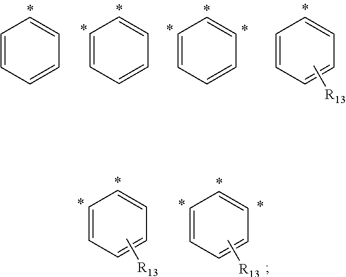
wherein, R₁₃ is selected from tert-butyl;
“*” represents a connection site.

20. The display device according to claim 17, wherein,
X₁ is selected from O; Z is selected from non-bonding; Y₁ is selected from selected from —O—, —S—, —Se—, —Te—, —C—C—, —C═C—, 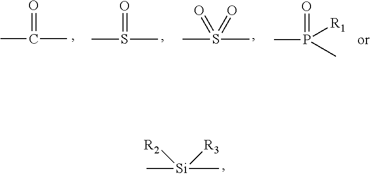
Y₂ is selected from non-bonding, a single bond, —O—, —S—, —Se—, —Te—, —C—C—, —C═C—, 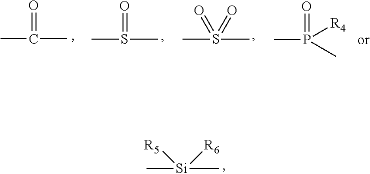
R₁-R₆ is selected from phenyl; and/or
X₁ is selected from N; Z is selected from p-tert-butylphenyl; Y₁ and Y₂ are each independently selected from —O—, —S—, —Se—, —Te—;
Z and A₆ form a ring or do not form a ring.
